(19) United States
(12) Patent Application Publication
(10) Pub. No.: US 2026/0198292 A1
(43) Pub. Date: Jul. 9, 2026

(54) SEMICONDUCTOR DEVICE

(71) Applicant: Kioxia Corporation, Tokyo (JP)

(72) Inventor: Shinya Arai, Yokkaichi Mie (JP)

(73) Assignee: Kioxia Corporation, Tokyo (JP)

(21) Appl. No.: 19/239,596

(22) Filed: Jun. 16, 2025

(30) Foreign Application Priority Data
Jan. 8, 2025 (JP) 2025-002992

(51) Int. Cl. H01L 23/528; H01L 21/768; H01L 23/00; H01L 25/065; H10B 41/27; H10B 43/27; H10B 80/00

(52) U.S. Cl. CPC H10W 20/43; H10W 20/435; H10W 90/00; H10B 41/27; H10B 43/27; H10B 80/00; H10W 20/033; H10W 20/069; H10W 80/312; H10W 80/327; H10W 90/20; H10W 90/792

(57) ABSTRACT

According to an embodiment, a semiconductor device includes a first chip and a second chip. The first chip includes a first interconnect layer extending in a first direction and a first electrode including a first contact plug provided on the first interconnect layer and a first pad. The second chip includes a second interconnect layer extending in a second direction intersecting the first direction and a second electrode including a second contact plug provided on the second interconnect layer and a second pad bonded to the first pad. A first length of the first contact plug in the first direction is longer than a second length of the first contact plug in the second direction. A third length of the second contact plug in the second direction is longer than a fourth length of the second contact plug in the first direction.

### CROSS-REFERENCE TO RELATED APPLICATIONS

This application is based upon and claims the benefit of priority from Japanese Patent Application No. 2025-002992, filed Jan. 8, 2025, the entire contents of which are incorporated herein by reference.

### FIELD

Embodiments described herein relate generally to a semiconductor device.

### BACKGROUND

A NAND flash memory is known as one type of semiconductor memory device.

### BRIEF DESCRIPTION OF THE DRAWINGS

FIG. 1 is a block diagram showing an overall configuration of a semiconductor device according to a first embodiment.

FIG. 2 is a circuit diagram of a memory cell array included in the semiconductor device according to the first embodiment.

FIG. 3 is a perspective view showing an outline of a bonding structure of the semiconductor device according to the first embodiment.

FIG. 4 is a diagram showing an example of a planar layout of the memory cell array included in the semiconductor device according to the first embodiment.

FIG. 5 is a cross-sectional view showing an example of a cross-sectional structure of the semiconductor device taken along line IV-IV in FIG. 4.

FIG. 6 is a cross-sectional view showing an example of the cross-sectional structure of the memory cell array included in the semiconductor device according to the first embodiment.

FIG. 7 is a cross-sectional view taken along line V-V in FIG. 6.

FIG. 8 is a perspective view showing an example of the structure of an M1 interconnect layer, electrodes 108 and 210, and a D2 interconnect layer included in the semiconductor device according to the first embodiment.

FIG. 9 is a diagram showing an example of a plan view of the electrode 108 and M1 interconnect layer and a plan view of an insulating layer 127 included in the semiconductor device according to the first embodiment.

FIG. 10 is a diagram showing an example of a plan view of the electrode 210 and D2 interconnect layer and a plan view of an insulating layer 214 included in the semiconductor device according to the first embodiment.

FIG. 11 is a cross-sectional view taken along line VI-VI in FIGS. 9 and 10.

FIG. 12 is a cross-sectional view taken along line VII-VII in FIGS. 9 and 10.

FIG. 13 is a diagram showing an example of the positional relationship between the opening region of the insulating layer 214 and the electrode 210 (bonding pad DB) included in the semiconductor device according to the first embodiment.

FIG. 14 is a diagram showing bonding of a wafer WF1 on which a plurality of array chips are formed and a wafer WF2 on which a plurality of circuit chips are formed.

FIG. 15 is a perspective view schematically showing warpage of the wafer WF1 on which a plurality of array chips are formed.

FIG. 16 is a diagram schematically showing directions of position deviation of the array chips on the wafer WF1.

FIG. 17 is a plan view of the M1 interconnect layer and the electrode 108 showing an example of how the position deviation of the electrode 108 in the X direction is corrected in the semiconductor device according to the first embodiment.

FIG. 18 is a plan view of the D2 interconnect layer and the electrode 210 showing an example of how the position deviation of the electrode 210 in the Y direction is corrected in the semiconductor device according to the first embodiment.

FIG. 19 is a diagram showing a manufacturing process of the electrode 210 included in the semiconductor device according to the first embodiment.

FIG. 20 is a diagram showing a manufacturing process of the electrode 210 included in the semiconductor device according to the first embodiment.

FIG. 21 is a diagram showing a manufacturing process of the electrode 210 included in the semiconductor device according to the first embodiment.

FIG. 22 is a diagram showing a manufacturing process of the electrode 210 included in the semiconductor device according to the first embodiment.

FIG. 23 is a diagram showing a manufacturing process of the electrode 210 included in the semiconductor device according to the first embodiment.

FIG. 24 is a diagram showing a manufacturing process of the electrode 210 included in the semiconductor device according to the first embodiment.

FIG. 25 is a diagram showing an example of a plan view of an electrode 108 and an M1 interconnect layer and a plan view of an insulating layer 127 included in a semiconductor device according to a second embodiment.

FIG. 26 is a diagram showing an example of a plan view of an electrode 210 and an D2 interconnect layer and a plan view of an insulating layer 214 included in the semiconductor device according to the second embodiment.

FIG. 27 is a cross-sectional view taken along line VI-VI in FIGS. 25 and 26.

FIG. 28 is a cross-sectional view taken along line VII-VII in FIGS. 25 and 26.

FIG. 29 is a diagram showing a manufacturing process of the electrode 210 included in the semiconductor device according to the second embodiment.

FIG. 30 is a diagram showing a manufacturing process of the electrode 210 included in the semiconductor device according to the second embodiment.

FIG. 31 is a diagram showing a manufacturing process of the electrode 210 included in the semiconductor device according to the second embodiment.

FIG. 32 is a diagram showing a manufacturing process of the electrode 210 included in the semiconductor device according to the second embodiment.

FIG. 33 is a diagram showing a manufacturing process of the electrode 210 included in the semiconductor device according to the second embodiment.

FIG. 34 is a diagram showing a manufacturing process of the electrode 210 included in the semiconductor device according to the second embodiment.

FIG. 35 is a cross-sectional view showing an example of a cross-sectional configuration of a semiconductor device according to a third embodiment.

FIG. 36 is a perspective view showing an example of the structure of an M1 interconnect layer, electrodes 108 and 210, and a D2 interconnect layer included in the semiconductor device according to the third embodiment.

FIG. 37 is a diagram showing an example of a plan view of the electrode 108 and M1 interconnect layer included in the semiconductor device according to the third embodiment.

FIG. 38 is a diagram showing an example of a plan view of the electrode 210 and D2 interconnect layer included in the semiconductor device according to the third embodiment.

FIG. 39 is a cross-sectional view taken along line VI-VI in FIGS. 37 and 38.

FIG. 40 is a cross-sectional view taken along line VII-VII in FIGS. 37 and 38.

FIG. 41 is a diagram showing a manufacturing process of the electrode 210 included in the semiconductor device according to the third embodiment.

FIG. 42 is a diagram showing a manufacturing process of the electrode 210 included in the semiconductor device according to the third embodiment.

FIG. 43 is a diagram showing a manufacturing process of the electrode 210 included in the semiconductor device according to the third embodiment.

FIG. 44 is a diagram showing a manufacturing process of the electrode 210 included in the semiconductor device according to the third embodiment.

FIG. 45 is a diagram showing a manufacturing process of the electrode 210 included in the semiconductor device according to the third embodiment.

FIG. 46 is a cross-sectional view showing an example of a cross-sectional structure of a semiconductor device according to a fourth embodiment.

FIG. 47 is a perspective view showing an example of the structure of an M1 interconnect layer, electrodes 108 and 210, and a D2 interconnect layer included in the semiconductor device according to the fourth embodiment.

FIG. 48 is a diagram showing an example of a plan view of the electrode 108 and M1 interconnect layer included in the semiconductor device according to the fourth embodiment.

FIG. 49 is a diagram showing an example of a plan view of the electrode 210 and D2 interconnect layer included in the semiconductor device according to the fourth embodiment.

FIG. 50 is a cross-sectional view taken along line VI-VI in FIGS. 48 and 49.

FIG. 51 is a cross-sectional view taken along line VII-VII in FIGS. 48 and 49.

### DETAILED DESCRIPTION

In general, according to one embodiment, a semiconductor memory device includes a first chip and a second chip. The first chip includes a first interconnect layer extending in a first direction and a first electrode including a first contact plug provided on the first interconnect layer and a first pad provided on the first contact plug. The second chip includes a second interconnect layer extending in a second direction intersecting the first direction and a second electrode including a second contact plug provided on the second interconnect layer and a second pad provided on the second contact plug and bonded to the first pad. A first length of an upper surface of the first contact plug in the first direction is longer than a second length of the upper surface of the first contact plug in the second direction. A third length of an upper surface of the second contact plug in the second direction is longer than a fourth length of the upper surface of the second contact plug in the first direction.

Embodiments will be described with reference to the accompanying drawings. In the descriptions below, structural elements having similar functions and configurations will be denoted by the same reference symbols. To distinguish a plurality of structural elements having common reference numerals, suffixes will be attached to the common reference numerals. If the structural elements do not have to be distinguished particularly, only the common reference numerals will be used, and no suffixes will be attached. The suffixes are not limited to subscripts or superscripts, but include, for example, lower case English letters added at the end of reference numerals, and indices or the like indicating sequences.

### 1. First Embodiment

A semiconductor device according to the first embodiment will be described. In the descriptions below, a three-dimensional stacked NAND flash memory formed by bonding a plurality of chips together will be described as an example of the semiconductor device. It should be noted that the semiconductor device is not limited to a NAND flash memory. The present embodiment is applicable to any semiconductor device as long as it has a bonded structure in which a plurality of chips are bonded together.

### 1.1 Configuration

### 1.1.1 Overall Configuration of Semiconductor Device

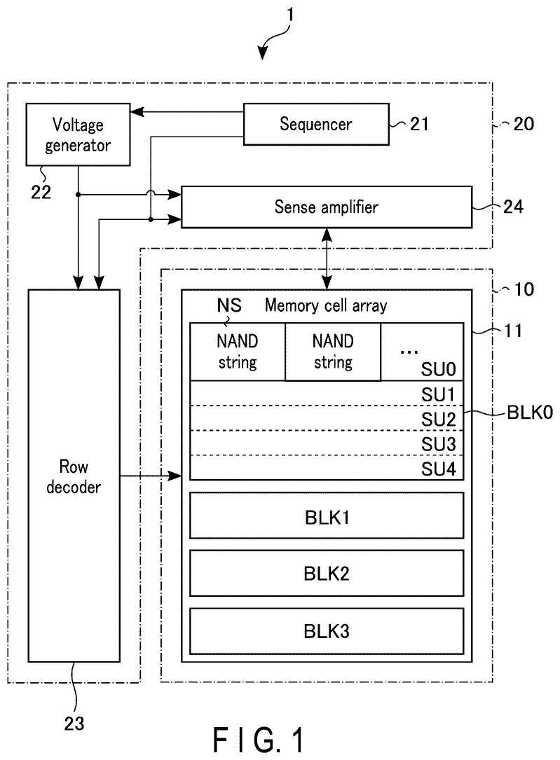

First, an example of the overall configuration of a semiconductor device 1 will be described with reference to FIG. 1. FIG. 1 is a block diagram showing the overall configuration of the semiconductor device 1. It is noted that in FIG. 1, some of the couplings between the components are indicated by arrows, but the couplings between the components are not limited to these.

The semiconductor device 1 is, for example, a three-dimensional stacked NAND flash memory. The three-dimensional stacked NAND flash memory includes a plurality of non-volatile memory cell transistors arranged in three dimensions above a semiconductor substrate.

As shown in FIG. 1, the semiconductor device 1 includes an array chip 10 and a circuit chip 20.

The array chip 10 is provided with a memory cell array 11 including non-volatile memory cell transistors. The circuit chip 20 is provided with circuits for controlling the array chip 10. The semiconductor device 1 of the present embodiment has a structure in which the array chip 10 and the circuit chip 20 are bonded together (hereinafter, referred to as a “bonded structure”). In the description below, when neither the array chip 10 nor the circuit chip 20 is subject to any limitation, it will be simply referred to as a “chip.” The semiconductor device 1 may include a plurality of array chips 10 or a plurality of circuit chips 20.

The array chip 10 includes one or a plurality of memory cell arrays 11. The memory cell arrays 11 are regions in which non-volatile memory cell transistors (also referred to as “memory cells” in the descriptions below) are arranged in three dimensions. In the example shown in FIG. 1, the array chip 10 includes one memory cell array 11.

The circuit chip 20 includes a sequencer 21, a voltage generator 22, a row decoder 23, and a sense amplifier 24.

The sequencer 21 is a control circuit for the semiconductor device 1. For example, the sequencer 21 is coupled to the voltage generator 22, the row decoder 23, and the sense amplifier 24. The sequencer 21 controls the voltage generator 22, the row decoder 23, and the sense amplifier 24. The sequencer 21 also controls the overall operation of the semiconductor device 1 under the control of an external controller. More specifically, the sequencer 21 executes a write operation, a read operation, an erase operation, etc.

The voltage generator 22 is a circuit that generates voltages used for the write operation, read operation, erase operation, etc. For example, the voltage generator 22 is coupled to the row decoder 23 and the sense amplifier 24. The voltage generator 22 supplies the generated voltages to the row decoder 23, the sense amplifier 24, etc.

The row decoder 23 is a circuit that decodes a row address. The row address is an address signal that specifies an interconnect in the row direction of the memory cell array 11. Based on the decoding result of the row address, the row decoder 23 supplies the voltages applied from the voltage generator 22 to the memory cell array 11.

The sense amplifier 24 is a circuit that writes and reads data. The sense amplifier 24 senses data read from the memory cell array 11 during the read operation. The sense amplifier 24 also supplies voltages corresponding to the write data to the memory cell array 11 during the write operation.

Next, the internal configuration of the memory cell array 11 will be described. The memory cell array 11 has a plurality of blocks BLK. Each block BLK is, for example, a collection of a plurality of memory cell transistors in which data is erased collectively. The plurality of memory cell transistors in the block BLK are associated with rows and columns. In the example shown in FIG. 1, the memory cell array 11 includes blocks BLK0, BLK1, BLK2, and BLK3.

Each block BLK includes a plurality of string units SU. Each string unit SU is, for example, a collection of a plurality of NAND strings that are selected collectively in the write operation or the read operation. The NAND string includes a collection of a plurality of memory cell transistors coupled in series. In the example shown in FIG. 1, each block BLK includes five string units SU0 to SU4. The number of blocks BLK in the memory cell array 11 and the number of string units SU in one block BLK can be set arbitrarily.

### 1.1.2 Circuit Configuration of Memory Cell Array

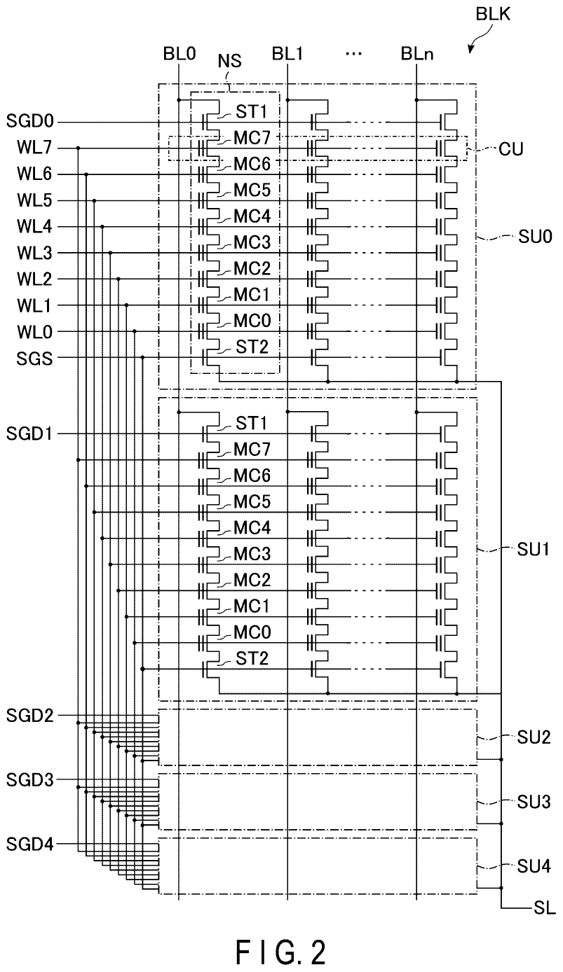

Next, an example of the circuit configuration of the memory cell array 11 will be described with reference to FIG. 2. FIG. 2 is a circuit diagram of the memory cell array 11. The example in FIG. 2 shows the circuit configuration of one block BLK.

As shown in FIG. 2, the string unit SU includes a plurality of NAND strings NS.

Each NAND string NS includes a plurality of memory cell transistors MC and select transistors ST1 and ST2. In the example shown in FIG. 2, the NAND string NS includes eight memory cell transistors MC0 to MC7. The number of memory cell transistors MC included in the NAND string NS can be set arbitrarily.

Each memory cell transistor MC is a memory element that stores data in a non-volatile manner. The memory cell transistor MC includes a control gate and a charge storage film. The memory cell transistor MC may be either a metal-oxide-nitride-oxide-silicon (MONOS) type or a floating gate (FG) type. The MONOS type uses an insulating layer for the charge storage film. The FG type uses a conductor layer for the charge storage film. In the description below, the case where the memory cell transistor MC is of the MONOS type will be mentioned.

The select transistors ST1 and ST2 are switching elements. The select transistors ST1 and ST2 are used for selecting a string unit SU during various operations. The number of select transistors ST1 and ST2 included in the NAND string NS can be set arbitrarily. It is sufficient for the NAND string NS to include at least one select transistor ST1 and at least one select transistor ST2.

In the NAND string NS, the current paths of the select transistor ST2, the memory cell transistors MC0 to MC7, and the select transistor ST1 are coupled in series. The drain of the select transistor ST1 is coupled to a bit line BL. The source of the select transistor ST2 is coupled to a source line SL.

The control gates of the memory cell transistors MC0 to MC7 in the same block BLK are commonly coupled to the word lines WL0 to WL7, respectively. More specifically, for example, the block BLK includes five string units SU0 to SU4. The string units SU each include a plurality of memory cell transistors MC0. The control gates of the plurality of memory cell transistors MC0 in the block BLK are commonly coupled to one word line WL0. The same applies to the other memory cells MC1 to MC7.

The gates of the plurality of select transistors ST1 in each string unit SU are commonly coupled to one select gate line SGD. More specifically, the gates of the plurality of select transistors ST1 in the string unit SU0 are commonly coupled to a select gate line SGD0. The gates of the plurality of select transistors ST1 in the string unit SU1 are commonly coupled to a select gate line SGD1. The gates of the plurality of select transistors ST1 in the string unit SU2 are commonly coupled to a select gate line SGD2. The gates of the plurality of select transistors ST1 in the string unit SU3 are commonly coupled to a select gate line SGD3. The gates of the plurality of select transistors ST1 in the string unit SU4 are commonly coupled to a select gate line SGD4.

The gates of the plurality of select transistors ST2 in the block BLK are commonly coupled to a select gate line SGS. Similarly to the select gate line SGD, a different select gate line SGS may be provided for each string unit SU.

The word lines WL0 to WL7, the select gate lines SGD0 to SGD4, and the select gate line SGS are coupled to the row decoder 23.

Bit lines BL are commonly coupled to one NAND string NS in each string unit SU of each block BLK. The same column address is assigned to a plurality of NAND strings NS coupled to one bit line BL. Each bit line BL is coupled to the sense amplifier 24.

The source line SL is shared, for example, by the plurality of blocks BLK.

A collection of a plurality of memory cell transistors MC coupled to a common word line WL in one string unit SU is referred to, for example, as a “cell unit CU.” For example, the write operation and the read operation are performed in units of the cell unit CU.

### 1.1.3 Bonding Structure of Semiconductor Device

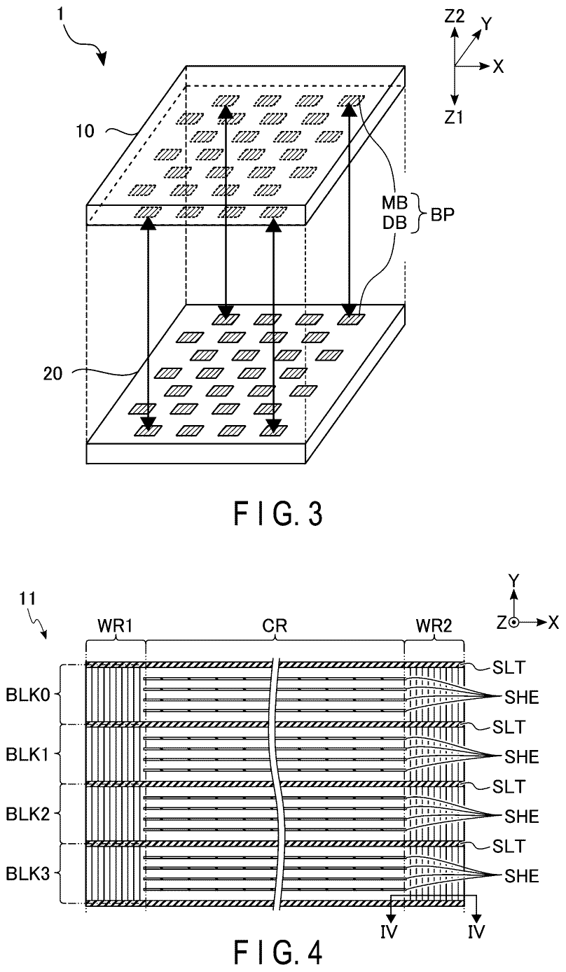

Next, an outline of the bonding structure of the semiconductor device 1 will be described with reference to FIG. 3. FIG. 3 is a perspective view showing an outline of the bonding structure of the semiconductor device 1.

As shown in FIG. 3, the array chip 10 includes a plurality of bonding pads MB provided on the surface facing the circuit chip 20. The circuit chip 20 includes a plurality of bonding pads DB that are provided on the surface facing the array chip 10 so as to face the bonding pads MB. In the bonding structure, one bonding pad MB of the array chip 10 and one bonding pad DB of the circuit chip 20 are bonded together to form one bonding pad BP. In other words, the bonding pad BP is formed by bonding the electrode (conductor) constituting the bonding pad MB provided on the array chip 10 and the electrode (conductor) constituting the bonding pad DB provided on the circuit chip 20.

In the description below, the surface where the array chip 10 and the circuit chip 20 are bonded (hereinafter referred to as the “bonding surface”) is defined as an XY plane. The directions that are perpendicular to each other in the XY plane is defined as an X direction and a Y direction. The direction that is approximately perpendicular to the XY plane and extends from the array chip 10 toward the circuit chip 20 is defined as a Z1 direction. The direction that is approximately perpendicular to the XY plane and extends from the circuit chip 20 toward the array chip 10 is defined as a Z2 direction. In a case where the Z1 direction and the Z2 direction do not have to be discriminated from each other, they will be referred to as a Z direction. In the array chip 10, the Z1 direction is defined as “upward,” while the Z2 direction is defined as “downward.” In contrast, in the circuit chip 20, the Z2 direction is defined as “upward,” while the Z1 direction is defined as “downward.”

### 1.1.4 Planar Layout of Memory Cell Array

Next, an example of the planar layout of the memory cell array 11 will be described with reference to FIG. 4. FIG. 4 is a plan view showing an example of the planar layout of the memory cell array 11. The example in FIG. 4 shows a region corresponding to four blocks BLK0 to BLK3 included in the memory cell array 11. It is noted that in the example in FIG. 4, the interlayer insulating films are omitted.

As shown in FIG. 4, the memory cell array 11 includes a WL region WR1, a cell region CR, and a WL region WR2. In a case where the WL regions WR1 and WR2 do not have to be discriminated from each other, they will be expressed as a “WL region WR” in the description below.

The cell region CR is a region in which the memory cell transistors MC are arranged.

The WL region WR is a region where the word lines WL and the select gate lines SGD and SGS are coupled to the plurality of corresponding contact plugs. The WL regions WR1 and WR2 are provided at respective ends of the cell region CR in the X direction. The WL region WR may be provided in the cell region CR. In the WL region WR, the end portions of the word lines WL and of the select gate lines SGD and SGS, which extend in the X direction, are hooked up in such a manner as to form a staircase structure. In the WL region WR, the word lines WL and the select gate lines SGD and SGS do not have to be hooked up to form the staircase structure. Even in this case, it is possible to form a contact plug that is electrically coupled to the target interconnect layer and that is not electrically coupled to the other interconnect layers.

In addition, the memory cell array 11 includes, for example, a plurality of slits SLT and a plurality of slits SHE.

The slits SLT extend in the X direction and cross the WL region WR1, the cell region CR, and the WL region WR2. The slits SLT are arranged in the Y direction. The slits SLT have a structure in which, for example, an insulator is embedded. The slits SLT may include a conductor coupled to a source line SL. Each slit SLT separates adjacent interconnects (e.g., word lines WL0 to WL7 and select gate lines SGD and SGS), which are adjacent to each other via the slit SLT. In the memory cell array 11, each of the regions separated by the slits SLT corresponds to one block BLK.

The slits SHE extend in the X direction and cross the cell region CR. The slits SHE are arranged in the Y direction. In the present embodiment, four slits SHE are arranged between the two slits SLT that are adjacent to each other in the Y direction. Each slit SHE has, for example, a structure in which an insulator is embedded. Each slit SHE divides interconnects (at least the select gate line SGD), which are adjacent to each other with the slit SHE interposed. In the memory cell array 11, each of the regions partitioned by the slits SLT and SHE corresponds to one string unit SU.

The number of slits SHE arranged between the two adjacent slits SLT can be arbitrarily designed. The number of string units SU provided in each block BLK can be changed based on the number of slits SHE arranged between the two adjacent slits SLT.

### 1.1.5 Cross-Sectional Structure of Semiconductor Device

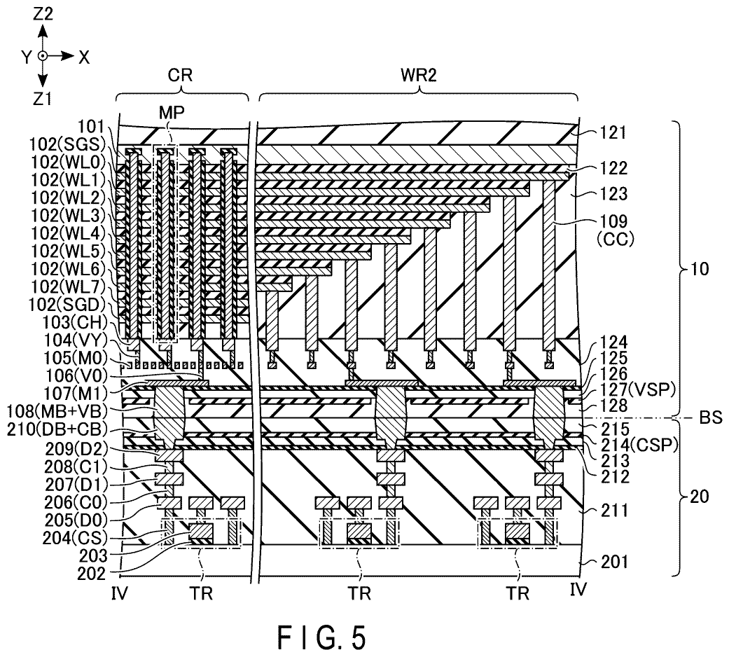

Next, an example of the cross-sectional structure of the semiconductor device 1 will be described with reference to FIG. 5. FIG. 5 is a cross-sectional view showing an example of the cross-sectional structure of the semiconductor device 1 taken along line IV-IV in FIG. 4. The description below will focus on the cross section of the region where the memory cell array 11 is formed in the array chip 10 (hereinafter referred to as the “memory cell array region” as well). Furthermore, the description below will focus on the WL region WR2, but the structure of the WL region WR1 is similar.

As shown in FIG. 5, the semiconductor device 1 has a bonding structure in which the array chip 10 and the circuit chip 20 are bonded together.

The array chip 10 includes a semiconductor layer 101, interconnect layers 102, conductors 103 and 104, an M0 interconnect layer 105, a conductor 106, an M1 interconnect layer 107, an electrode 108, a conductor 109, insulating layers 121 to 128, and a memory pillar MP. The conductor 103 functions as a contact plug CH. The conductor 104 functions as a contact plug VY. The conductor 106 functions as a contact plug V0. The electrode 108 functions as a contact plug VB and a bonding pad MB. The conductor 109 functions as a contact plug CC. The number of interconnect layers 102 provided in the array chip 10 and the number of layers of the multilayer interconnect structure above interconnect layers 102 can be discretionarily designed.

The circuit chip 20 includes a semiconductor substrate 201, a transistor TR, a gate insulating film 202, a gate electrode 203, a conductor 204, a D0 interconnect layer 205, a conductor 206, a D1 interconnect layer 207, a conductor 208, a D2 interconnect layer 209, an electrode 210, and insulating layers 211 to 215. The conductor 204 functions as a contact plug CS. The conductor 206 functions as a contact plug C0. The conductor 208 functions as a contact plug C1. The electrode 210 functions as a contact plug CB and a bonding pad DB. The number of layers in the multilayer interconnect structure provided on the circuit chip 20 can be discretionarily designed.

### 1.1.5.1 Cross-Sectional Structure of Array Chip

Subsequently, the cross-sectional structure of the array chip 10 will be described with reference to FIG. 5.

As shown in FIG. 5, the semiconductor layer 101 is provided on the upper surface facing the Z1 direction of the insulating layer 121. The semiconductor layer 101 extends in the X and Y directions. The semiconductor layer 101 in the memory cell array region functions as a source line SL. For example, the insulating layer 121 contains silicon oxide (SiO) as an insulating material. For example, the semiconductor layer 101 contains silicon.

In the cell region CR, a plurality of insulating layers 122 and a plurality of interconnect layers 102 are alternately stacked one by one on the upper surface facing the Z1 direction of the semiconductor layer 101. In the example shown in FIG. 5, ten insulating layers 122 and ten interconnect layers 102 are alternately stacked one by one. In other words, a plurality of interconnect layers 102 stacked apart from each other in the Z direction are provided between the semiconductor layer 101 and the circuit chip 20. The interconnect layers 102 and the insulating layers 122 extend in the X direction. The insulating layers 122 contain, for example, silicon oxide. The interconnect layers 102 contain, for example, tungsten (W) as a conductive material. In the example shown in FIG. 5, the ten interconnect layers 102 function, in order from the side closest to the semiconductor layer 101, as a select gate line SGS, word lines WL0 to WL7, and a select gate line SGD.

In the WL region WR, the plurality of interconnect layers 102 and the plurality of insulating layers 122 are hooked up in such a manner as to form a staircase structure. The length of the plurality of interconnect layers 102 in the X direction gradually decreases from the side of the semiconductor layer 101 toward the side of the circuit chip 20.

In the cell region CR, a plurality of memory pillars MP are provided. One of the memory pillars MP corresponds to one NAND string NS. Each memory pillar MP has, for example, a columnar shape extending in the Z direction. The memory pillar MP penetrates (passes through) the plurality of insulating layers 122 and the plurality of interconnect layers 102. The end (bottom surface) of the memory pillar MP in the Z2 direction extends into the semiconductor layer 101. Details of the structure of the memory pillar MP will be described later.

An insulating layer 123 is provided so as to cover the insulating layers 122, the interconnect layers 102, and the memory pillars MP.

In the WL region WR, a plurality of conductors 109 are provided. Each conductor 109 functions as a contact plug CC. The conductor 109 has, for example, a columnar shape extending in the Z direction. The conductor 109 contains, for example, tungsten as a conductive material. Each conductor 109 is coupled to one of the interconnect layers 102 and is not electrically coupled to the other interconnect layers 102. For example, the length of each conductor 109 in the Z direction differs depending on the interconnect layer 102 to which it is coupled. For example, among the plurality of conductors 109, the one coupled to the interconnect layer 102 functioning as the select gate line SGS has the greatest length in the Z direction (i.e., the highest plug), while the one coupled to the interconnect layer 102 functioning as the select gate line SGD has the shortest length.

A conductor 103 functioning as a contact plug CH is provided on the upper surface facing the Z1 direction of each memory pillar MP. The conductor 103 has, for example, a columnar shape extending in the Z direction. The conductor 103 contains, for example, tungsten as a conductive material.

A conductor 104 functioning as a contact plug VY is provided on the upper surface facing the Z1 direction of each conductor 103 in the cell region CR and on the upper surface facing the Z1 direction of each conductor 109 in the WL region WR. The conductor 104 has, for example, a columnar shape extending in the Z direction. The conductor 104 contains, for example, tungsten as a conductive material.

An M0 interconnect layer 105 is provided on the upper surface facing the Z1 direction of each conductor 104. For example, a plurality of M0 interconnect layers 105 in the cell region CR each extend in the Y direction and are arranged side by side in the X direction. Each of the plurality of memory pillars MP is electrically coupled to one of the plurality of M0 interconnect layers 105 via the conductor 103 (contact plug CH) and the conductor 104 (contact plug VY). The M0 interconnect layer 105 to which the memory pillar MP is coupled functions as a bit line BL. The M0 interconnect layer 105 contains, for example, copper (Cu) as a conductive material.

A conductor 106 functioning as a contact plug V0 is provided on the upper surface facing the Z1 direction of each M0 interconnect layer 105. The conductor 106 has, for example, a columnar shape extending in the Z direction. The conductor 106 contains, for example, copper or tungsten as a conductive material.

An M1 interconnect layer 107 is provided on the upper surface facing the Z1 direction of each conductor 106. In the present embodiment, at least a portion of the M1 interconnect layer 107 extends in the X direction. An electrode 108 is coupled to the portion of the M1 interconnect layer 107 that extends in the X direction. The M1 interconnect layer 107 contains, for example, copper as a conductive material. The conductor 106 and the M1 interconnect layer 107 may be formed by a dual damascene method. In the case of the dual damascene method, the patterns of the conductor 106 (contact plug V0) and the M1 interconnect layer 107 are processed. The bodies of the conductor 106 and the M1 interconnect layer 107 are embedded together using a conductive material (e.g., copper).

An insulating layer 124 is provided on the upper surface facing the Z1 direction of the insulating layer 123. The insulating layer 124 covers the conductors 103 and 104, the M0 interconnect layers 105, the conductors 106, and the M1 interconnect layers 107. For example, the insulating layer 124 contains silicon oxide.

An insulating layer 125 is provided on the upper surfaces facing the Z1 direction of the insulating layer 124 and the M1 interconnect layers 107. The insulating layer 125 functions as a cap insulating layer (anti-oxidation layer) for the M1 interconnect layer 107. The insulating layer 125 contains silicon (Si) and at least one of nitrogen or carbon. More specifically, the insulating layer 125 contains, for example, silicon nitride (SiN), silicon carbonitride (SiCN), or silicon carbide (SiC). For example, in a case where the M1 interconnect layer 107 is formed of a material having an oxidation resistance, the insulating layer 125 may be omitted.

An insulating layer 126 made of a different material from the insulating layer 125 is provided on the upper surface facing the Z1 direction of the insulating layer 125. The insulating layer 126 contains, for example, silicon oxide.

An insulating layer 127 made of a different material from the insulating layer 126 is provided on the upper surface facing the Z1 direction of the insulating layer 126. The insulating layer 127 functions as an etching stopper VSP when the electrode 108 is formed by the dual damascene method. The insulating layer 127 contains, for example, silicon nitride (SiN), silicon carbonitride (SiCN), or silicon carbide (SiC). It suffices that the insulating layer 127 is made of an insulating material with which the etching select ratio to the insulating layers 126 and 128 can be sufficiently achieved in the etching process of the dual damascene method.

An insulating layer 128 made of a different material from the insulating layer 127 is provided on the upper surface facing the Z1 direction of the insulating layer 127. The insulating layer 128 contains, for example, silicon oxide. The upper surface facing the Z1 direction of the insulating layer 128 and the upper surface facing the Z1 direction of the electrode 108 are flattened. The upper surface of the insulating layer 128 is in contact with the insulating layer 215 of the circuit chip 20. The surface where the insulating layer 128 and the insulating layer 215 are in contact with each other is the bonding surface BS.

The electrode 108 is provided on the upper surface facing the Z1 direction of each M1 interconnect layer 107. The electrode 108 contains, for example, copper as a conductive material. The electrode 108 includes a bonding pad MB and a contact plug VB that couples the bonding pad MB and the M1 interconnect layer 107. The contact plug VB is provided on the upper surface of the M1 interconnect layer 107. The bonding pad MB is provided on the upper surface facing the Z1 direction of the contact plug VB. At the bonding surface BS, the upper surface facing the Z1 direction of the bonding pad MB is in contact with the bonding pad DB provided on the circuit chip 20.

The electrode 108 is formed, for example, by a dual damascene method. In a case where the electrode 108 is formed by the dual damascene method, the insulating layer 127 functions as an etching stopper VSP of the bonding pad MB. The use of the insulating layer 127 improves the controllability of the heights of the bonding pad MB and the contact plug VB. Details of the structure of the electrode 108 will be described later.

### 1.1.5.2 Cross-Sectional Structure of Circuit Chip

Subsequently, the cross-sectional structure of the circuit chip 20 will be described with reference to FIG. 5.

As shown in FIG. 5, a plurality of transistors TR are provided on the upper surface facing the Z2 direction of the semiconductor substrate 201. Each transistor TR includes a gate insulating film 202, a gate electrode 203, and a source and a drain (neither is shown) formed on the semiconductor substrate 201. The gate insulating film 202 is provided on the upper surface of the semiconductor substrate 201. The gate electrode 203 is provided on the upper surface facing the Z2 direction of the gate insulating film 202. For example, a row decoder 23 or a sense amplifier 24 is configured by the plurality of transistors TR. The row decoder 23 is electrically coupled to the interconnect layer 102 of the array chip 10 via a bonding pad BP. The sense amplifier 24 is electrically coupled to the memory pillar MP of the array chip 10 via a bonding pad BP.

A plurality of conductors 204 each functioning as a contact plug CS are provided on the gate electrodes 203 and the upper surface of the semiconductor substrate 201. The conductor 204 contains, for example, tungsten. The conductor 204 has, for example, a columnar shape extending in the Z direction.

A D0 interconnect layer 205 is provided on the upper surface facing the Z2 direction of each conductor 204. The D0 interconnect layer 205 contains, for example, tungsten as a conductive material.

A conductor 206 functioning as a contact plug C0 is provided on the upper surface facing the Z2 direction of each D0 interconnect layer 205. The conductor 206 contains, for example, tungsten or copper as a conductive material. The conductor 206 has, for example, a columnar shape extending in the Z direction.

A D1 interconnect layer 207 is provided on the upper surface facing the Z2 direction of each conductor 206. The D1 interconnect layer 207 contains, for example, tungsten or copper as a conductive material. The D1 interconnect layer 207 and the conductor 206 may be formed together by a dual damascene method.

A conductor 208 functioning as a contact plug C1 is provided on the upper surface facing the Z2 direction of each D1 interconnect layer 207. The conductor 208 contains, for example, copper as a conductive material. The conductor 208 has, for example, a columnar shape extending in the Z direction.

A D2 interconnect layer 209 is provided on the upper surface facing the Z2 direction of each conductor 208. In the present embodiment, at least a portion of the D2 interconnect layer 209 extends in the Y direction. The portion of the D2 interconnect layer 209 that extends in the Y direction is coupled to the electrode 210. The D2 interconnect layer 209 contains, for example, copper as a conductive material. The D2 interconnect layer 209 and the conductor 208 may be formed together by a dual damascene method.

An insulating layer 211 is provided on the upper surface of the semiconductor substrate 201. The insulating layer 211 covers the transistors TR, the conductors 204, the D0 interconnect layers 205, the conductors 206, the D1 interconnect layers 207, the conductors 208, and the D2 interconnect layers 209. The insulating layer 211 contains, for example, silicon oxide.

An insulating layer 212 is provided on the upper surfaces facing the Z2 direction of the insulating layer 211 and the D2 interconnect layer 209. The insulating layer 212 functions as a cap insulating layer (anti-oxidation layer) for the D2 interconnect layer 209. The insulating layer 212 contains, for example, silicon nitride (SiN), silicon carbonitride (SiCN), or silicon carbide (SiC).

An insulating layer 213 made of a different material from the insulating layer 212 is provided on the upper surface facing the Z2 direction of the insulating layer 212. The insulating layer 213 contains, for example, silicon oxide.

An insulating layer 214 made of a different material from the insulating layer 213 is provided on the upper surface facing the Z2 direction of the insulating layer 213. The insulating layer 214 functions as an etching stopper CSP when the electrode 210 is formed by the dual damascene method. The insulating layer 214 contains, for example, silicon nitride (SiN), silicon carbonitride (SiCN), or silicon carbide (SiC). It suffices that the insulating layer 214 is made of an insulating material with which the etching select ratio to the insulating layers 213 and 215 can be sufficiently achieved in the etching process of the dual damascene method.

An insulating layer 215 made of a different material from the insulating layer 214 is provided on the upper surface facing the Z2 direction of the insulating layer 214. The insulating layer 215 contains, for example, silicon oxide. The surface facing the Z2 direction of the insulating layer 215 and the surface facing the Z2 direction of the electrode 210 are flattened. The upper surface facing the Z2 direction of the insulating layer 215 is in contact with the insulating layer 128 of the array chip 10.

The electrode 210 is provided on the upper surface of each D2 interconnect layer 209. The electrode 210 contains, for example, copper as a conductive material. The electrode 210 includes a bonding pad DB and a contact plug CB that couples the bonding pad DB and the D2 interconnect layer 209. At the bonding surface BS, the bonding pad DB is in contact with the bonding pad MB provided on the array chip 10.

The electrode 210 is formed, for example, by a dual damascene method. In a case where the electrode 210 is formed by the dual damascene method, the insulating layer 214 functions as an etching stopper CSP for the bonding pad DB. The use of the insulating layer 214 improves the controllability of the heights of the bonding pad DB and the contact plug CB. Details of the structure of the electrode 210 will be described later.

The number of layers provided in the multilayer interconnect provided between the transistor TR and the electrode 210 can be set arbitrarily.

### 1.1.6 Cross-Sectional Structure of Memory Cell Array

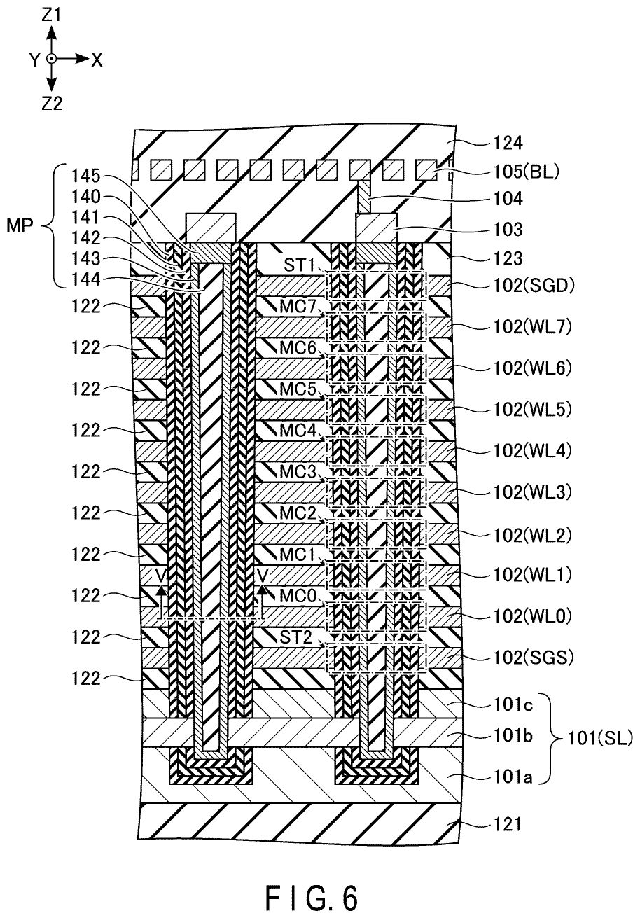

Next, the cross-sectional structure of the memory cell array 11 will be described with reference to FIG. 6. FIG. 6 is a cross-sectional view showing an example of the cross-sectional structure of the memory cell array 11. FIG. 6 shows two memory pillars MP included in the memory cell array 11.

As shown in FIG. 6, the semiconductor layer 101 includes, for example, three semiconductor layers 101a, 101b, and 101c. The semiconductor layer 101b is provided on the upper surface facing the Z1 direction of the semiconductor layer 101a. The semiconductor layer 101c is provided on the upper surface facing the Z1 direction of the semiconductor layer 101b. The semiconductor layer 101b is formed, for example, by replacing a sacrificial layer provided between the semiconductor layer 101a and the semiconductor layer 101c. The semiconductor layers 101a to 101c contain, for example, silicon. The semiconductor layers 101a to 101c contain, for example, phosphorus (P) as semiconductor impurities.

Ten insulating layers 122 and ten interconnect layers 102 are alternately stacked one by one on the upper surface facing the Z1 direction of the semiconductor layer 101. In the example shown in FIG. 6, the ten interconnect layers 102 function, in order from the side closest to the semiconductor layer 101, as a select gate line SGS, word lines WL0 to WL7, and a select gate line SGD. It is noted that a plurality of interconnect layers 102 respectively functioning as the select gate line SGS and the select gate line SGD may be provided. As the conductive material of the interconnect layers 102, for example, a stacked structure of titanium nitride (TiN) and tungsten (W) may be used. In this case, the titanium nitride is formed in such a manner as to cover the tungsten. When tungsten is deposited, for example, by a chemical vapor deposition (CVD), the titanium nitride functions as a barrier layer for suppressing oxidation of tungsten or as an adhesion layer for improving the adhesion of tungsten. The interconnect layers 102 may also include a high dielectric constant material such as aluminum oxide (AlO). In this case, the high dielectric constant material is formed in such a manner as to cover the conductive material. For example, in each of the interconnect layers 102, a high dielectric constant material is provided such that it is in contact with the insulating layers 122 provided above and below each interconnect layer 102 and the side surfaces of the memory pillars MP. The titanium nitride is provided such that it is in contact with the high dielectric constant material. The tungsten is provided such that it is in contact with the titanium nitride and fills the inside of the titanium nitride. For example, in a case where aluminum oxide is provided as the high dielectric constant material, the memory cell transistor MC is also referred to as a metal-aluminum-nitride-oxide-silicon (MANOS) type.

An insulating layer 123 is provided on the upper surface facing the Z1 direction of the interconnect layer 102 functioning as the select gate line SGD.

A plurality of memory pillars MP are provided in the memory cell array 11. For example, each memory pillar MP has a substantially columnar shape extending in the Z direction. The memory pillar MP penetrates the ten interconnect layers 102. The bottom surface of the memory pillar MP reaches the semiconductor layer 101. The memory pillar MP may have a structure in which a plurality of pillars are coupled together in the Z direction.

Next, the internal configuration of the memory pillar MP will be described. Each memory pillar MP includes a block insulating film 140, a charge storage film 141, a tunnel insulating film 142, a semiconductor film 143, a core film 144, and a cap film 145.

The block insulating film 140, the charge storage film 141, and the tunnel insulating film 142 are stacked, in this order from the outside, on part of the side surface and the bottom surface facing the Z2 direction of the memory pillar MP. More specifically, the block insulating film 140, the charge storage film 141, and the tunnel insulating film 142 on the side surface of the memory pillar MP are removed in the same layer as the semiconductor layer 101b and in the vicinity thereof. The semiconductor film 143 is provided such that it is in contact with the side surface and bottom surface of the tunnel insulating film 142 and with the semiconductor layer 101b. The semiconductor film 143 is a region in which the channels of the memory cell transistor MC and the select transistors ST1 and ST2 are formed. The inside of the semiconductor film 143 is filled with the core film 144. At the top of the memory pillar MP in the Z1 direction, a cap film 145 is provided on the upper ends of the semiconductor film 143 and the core film 144. The side surface of the cap film 145 is in contact with the tunnel insulating film 142. The cap film 145 contains, for example, silicon. A conductor 103 is provided on the surface facing the Z1 direction of the cap film 145. A conductor 104 is provided on the surface facing the Z1 direction of the conductor 103. The conductor 104 is coupled to the M0 interconnect layer 105 functioning as the bit line BL.

The memory pillar MP and the interconnect layers 102 functioning as the word lines WL0 to WL7 are combined to form the memory cell transistors MC0 to MC7. Similarly, the memory pillar MP and the interconnect layer 102 functioning as the select gate line SGD are combined to form the select transistor ST1. The memory pillar MP and the interconnect layer 102 functioning as the select gate line SGS are combined to form the select transistor ST2. Thus, each memory pillar MP can function as one NAND string NS.

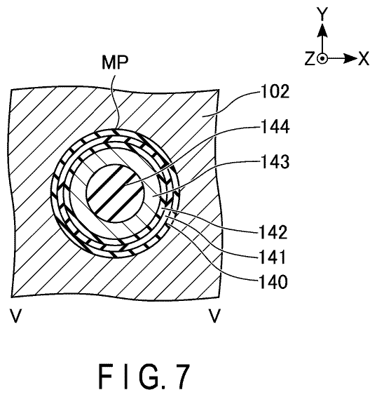

With reference to FIG. 7, an example of the cross-sectional structure of the memory pillar MP along the XY plane will be described. FIG. 7 is a cross-sectional view taken along line V-V in FIG. 6. More specifically, FIG. 7 shows the cross-sectional structure of the memory pillar MP in a layer including the interconnect layer 102.

In the cross section including the interconnect layer 102, the core film 144 is provided, for example, in the center of the memory pillar MP. The semiconductor film 143 surrounds the side surface of the core film 144. The tunnel insulating film 142 surrounds the side surface of the semiconductor film 143. The charge storage film 141 surrounds the side surface of the tunnel insulating film 142. The block insulating film 140 surrounds the side surface of the charge storage film 141. The interconnect layer 102 surrounds the side surface of the block insulating film 140.

The semiconductor film 143 is used as channels (current paths) of the memory cell transistors MC0 to MC7 and the select transistors ST1 and ST2. Each of the tunnel insulating film 142 and the block insulating film 140 contains silicon oxide, for example. The charge storage film 141 has a function of accumulating charges. The charge storage film 141 contains, for example, silicon nitride (SiN).

### 1.1.7 Structure of Bonding Pad

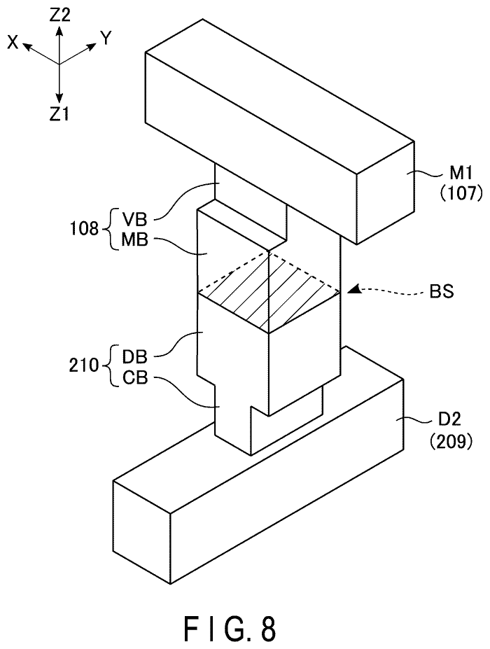

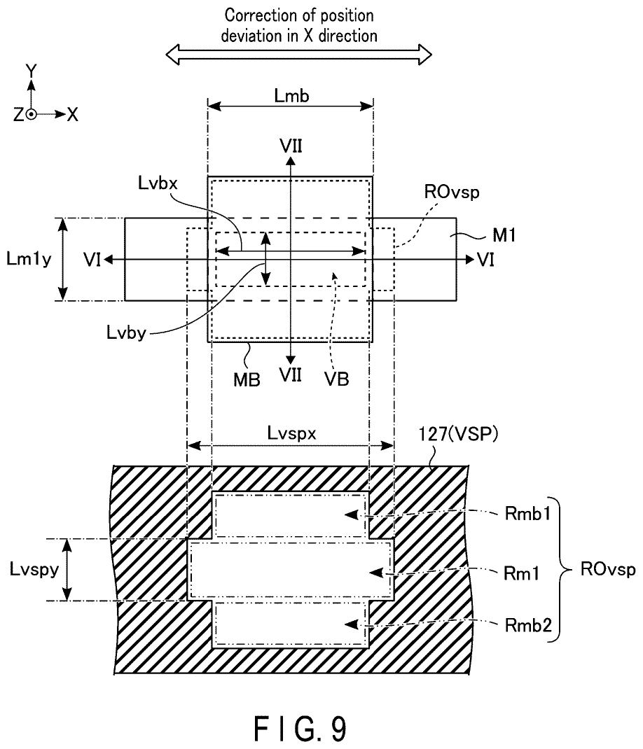

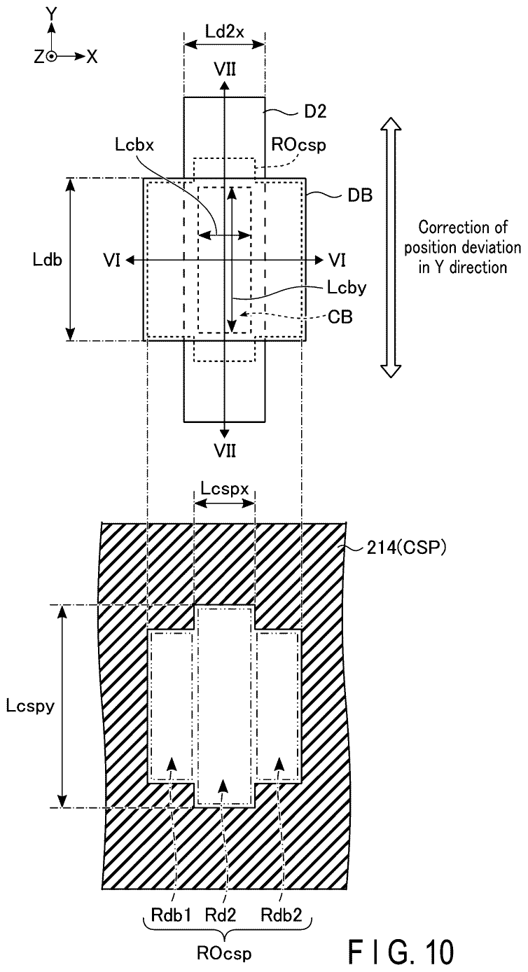

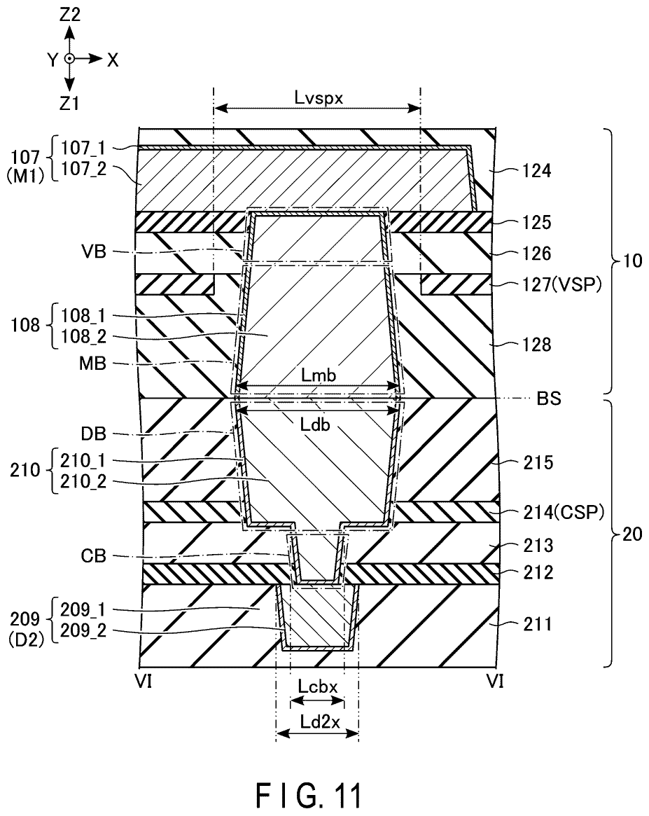

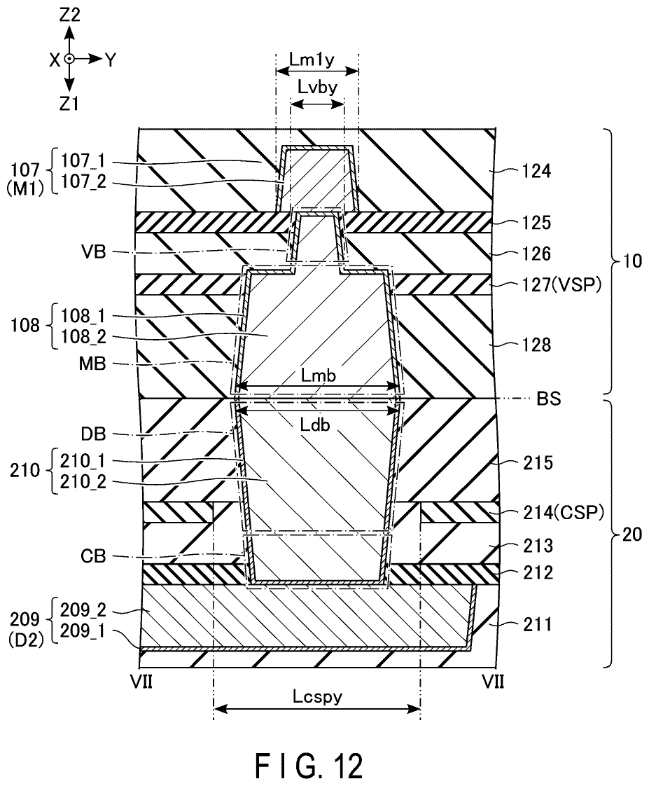

Next, the structure of the bonding pad BP will be described with reference to FIGS. 8 to 12. FIG. 8 is a perspective view showing an example of the structure of the M1 interconnect layer 107, the electrodes 108 and 210, and the D2 interconnect layer 209. FIG. 9 shows an example of a plan view of the electrode 108 and the M1 interconnect layer 107 and a plan view of the insulating layer 127. FIG. 10 shows an example of a plan view of the electrode 210 and the D2 interconnect layer 209 and a plan view of the insulating layer 214. FIG. 11 is a cross-sectional view taken along line VI-VI in FIGS. 9 and 10. FIG. 12 is a cross-sectional view taken along line VII-VII in FIGS. 9 and 10.

It is noted that the insulating layers are omitted in the perspective view in FIG. 8, the plan view in FIG. 9 showing the electrode 108 and the M1 interconnect layer 107, and the plan view in FIG. 10 showing the electrode 210 and the D2 interconnect layer 209. In the plan view in FIG. 9 showing the insulating layer 127 and the plan view in FIG. 10 showing the insulating layer 214, other conductors and insulating layers are omitted. In FIG. 8, the contact surface between the bonding pad MB and the bonding pad DB is indicated by hatching to enhance visibility.

As shown in FIG. 8, the M1 interconnect layer 107 of the array chip 10 has a portion extending in the X direction. The electrode 108 is provided on the upper surface facing the Z1 direction of the portion of the M1 interconnect layer 107 that extends in the X direction. In other words, a contact plug VB is provided on the upper surface facing the Z1 direction of the M1 interconnect layer 107. A bonding pad MB is provided on the upper surface facing the Z1 direction of the contact plug VB.

The length of the upper surface of the contact plug VB in the X direction is equal to the length of the lower surface facing the Z2 direction of the bonding pad MB in the X direction. The side surface facing the X direction of the contact plug VB and the side surface facing the X direction of the bonding pad MB are provided in the same plane. The length of the upper surface of the contact plug VB in the Y direction is shorter than the length of the lower surface of the bonding pad MB in the Y direction.

The D2 interconnect layer 209 of the circuit chip 20 has a portion extending in the Y direction. The electrode 210 is provided on the upper surface facing the Z2 direction of the portion of the D2 interconnect layer 209 that extends in the Y direction. In other words, a contact plug CB is provided on the upper surface of the D2 interconnect layer 209. Then, a bonding pad DB is provided on the upper surface facing the Z2 direction of the contact plug CB.

The length of the upper surface of the contact plug CB in the Y direction is equal to the length of the lower surface facing the Z1 direction of the bonding pad DB in the Y direction. The side surface facing the Y direction of the contact plug CB and the side surface facing the Y direction of the bonding pad MB are provided in the same plane. The length of the upper surface of the contact plug CB in the X direction is shorter than the length of the lower surface of the bonding pad DB in the X direction.

For example, if there is no position deviation between the bonding pad MB and the bonding pad DB, and the shapes of the bonding pads MB and DB at the bonding surface BS are both square and have the same size, the entire upper surface facing the Z1 direction of the bonding pad MB is in contact with the entire upper surface facing the Z2 direction of the bonding pad DB.

As shown in FIG. 9, in a plan view seen from the Z direction, the M1 interconnect layer 107, the contact plug VB, and part of the bonding pad MB overlap. The contact plug VB is provided on the upper surface of the M1 interconnect layer 107. The bonding pad MB is provided on the upper surface of the contact plug VB. The upper surface of the bonding pad MB, that is, the shape of the bonding pad MB at the bonding surface BS, is approximately square, for example. In this case, it is assumed that the length of one side of the upper surface of the bonding pad MB is Lmb. It is also assumed that the length of the upper surface of the M1 interconnect layer 107 in the Y direction, that is, the interconnect width, is Lm1y. The length Lmb is longer than the length Lm1y.

For example, the upper surface of the contact plug VB (the contact surface face with the bonding pad MB) has a substantially rectangular shape that is long in the X direction (in the extension direction of the M1 interconnect layer 107). The length Lvbx of the upper surface of the contact plug VB in the X direction is equal to the length of the lower surface of the bonding pad MB in the X direction. The length Lvby of the upper surface of the contact plug VB in the Y direction is shorter than the interconnect width Lm1y of the M1 interconnect layer 107.

In the present embodiment, the contact plug VB and the bonding pad MB are formed (processed) together by a dual damascene method using the insulating layer 127, which functions as an etching stopper VSP, as a mask. By using the insulating layer 127 as a mask, the contact plug VB is processed to be self-aligned with the bonding pad MB.

For example, the opening region ROvsp of the insulating layer 127 includes regions Rm1, Rmb1, and Rmb2. The region Rm1 overlaps the M1 interconnect layer 107, the contact plug VB, and part of the bonding pad MB in a plan view seen from the Z direction. In the plan view seen from the Z direction, the regions Rmb1 and Rmb2 overlap the bonding pad MB but do not overlap the contact plug VB. The regions Rmb1 and Rmb2 are provided adjacent to the region Rm1 in the Y direction. The region Rm1 is provided between the regions Rmb1 and Rmb2 in the Y direction. The region Rm1 corresponds to the contact plug VB. The region Rm1 is a region where the insulating layer 127 is removed when the insulating layer 127 is processed to form a mask pattern for the contact plug VB. The regions Rmb1 and Rmb2 are regions where the insulating layer 127 is removed when the insulating layers 125 to 128 are processed to form a hole pattern for the electrode 108.

It is assumed that the length of the region Rm1 in the X direction is Lvspx, and the length of the same region in the Y direction is Lvspy. The length Lvspx is longer than the length Lmb. In a plan view seen from the Z direction, the both ends of the region Rm1 in the X direction protrude in the X direction from the both ends of the bonding pad MB in the X direction. In other words, the both ends of the region Rm1 in the X direction protrude in the X direction from the both ends of the region Rmb1 and the region Rmb2 in the X direction. At the ends of the region Rm1 in the X direction (that is, the protruding regions), the insulating layer 127 is not in contact with the bonding pad MB. In contrast, in the regions Rmb1 and Rmb2, the insulating layer 127 is in contact with the bonding pad MB. For example, it is preferable that the difference between the length Lvspx and the length Lmb be equal to or longer than the misalignment between the photolithography corresponding to the processing of the region Rm1 of the insulating layer 127 and the photolithography corresponding to the processing of the electrode 108. Thus, even if a misalignment occurs between the region Rm1 of the opening region ROvsp and the electrode 108 (bonding pad MB), the length in the X direction of the contact plug VB formed by self-alignment does not vary. The length Lvbx of the upper surface of the contact plug VB in the X direction is approximately equal to the length Lmb of the upper surface of the bonding pad MB. The term “approximately equal” may include errors caused by processing shapes in the dual damascene method, such as a tapered shape.

The length Lvspy of the region Rm1 is shorter than the interconnect width Lm1y of the M1 interconnect layer 107. Furthermore, the length Lvspy is approximately equal to the length Lvby of the upper surface of the contact plug VB in the Y direction. For example, it is preferable that the length Lvspy be equal to or less than a length obtained by subtracting the photolithography alignment margin (e.g., 200 nm) associated with the processing of the insulating layer 127 from the interconnect width Lm1y of the M1 interconnect layer 107. This prevents the contact plug VB from deviating in the Y direction from the M1 interconnect layer 107, in a plan view seen from the Z direction.

In the present embodiment, in order to correct the position deviation between the bonding pad MB and the bonding pad DB in the X direction, the arrangement of the opening region ROvsp of the insulating layer 127 and the arrangement of the electrode 108 can be shifted in the X direction with respect to the M1 interconnect layer 107, which extends in the X direction. By shifting the opening region ROvsp of the insulating layer 127 and the electrode 108 in the X direction, the position deviation between the bonding pad MB and the bonding pad DB in the X direction can be corrected.

As shown in FIG. 10, in a plan view seen from the Z direction, the D2 interconnect layer 209, the contact plug CB, and the bonding pad DB overlap. The contact plug CB is provided on the upper surface of the D2 interconnect layer 209. The bonding pad DB is provided on the upper surface of the contact plug CB. The upper surface of the bonding pad DB, that is, the shape of the bonding pad DB at the bonding surface BS, is approximately square, for example. In this case, it is assumed that the length of one side of the upper surface of the bonding pad DB is Ldb. It is also assumed that the length of the upper surface of the D2 interconnect layer 209 in the X direction, that is, the interconnect width, is Ld2x. The length Ldb is longer than the interconnect width Ld2x.

For example, the upper surface of the contact plug CB (the contact surface with the bonding pad DB) has a substantially rectangular shape that is long in the Y direction (in the extension direction of the D2 interconnect layer 209). The length Lcby of the upper surface of the contact plug CB in the Y direction is equal to the length of the lower surface of the bonding pad DB in the Y direction. The length Lcbx of the upper surface of the contact plug CB in the X direction is shorter than the interconnect width Ld2x of the D2 interconnect layer 209.

In the present embodiment, the contact plug CB and the bonding pad DB are formed (processed) together by a dual damascene method using the insulating layer 214, which functions as an etching stopper CSP, as a mask. By using the insulating layer 214 as a mask, the contact plug CB is processed to be self-aligned with the bonding pad DB.

For example, the opening region ROcsp of the insulating layer 214 includes regions Rd2, Rdb1, and Rdb2. In a plan view seen from the Z direction, the region Rd2 overlaps the D2 interconnect layer 209, the contact plug CB, and part of the bonding pad DB. In the plan view seen from the Z direction, the regions Rdb1 and Rdb2 overlap the bonding pad DB but do not overlap the contact plug CB. The regions Rdb1 and Rdb2 are provided adjacent to the region Rd2 in the X direction. The region Rd2 is provided between the regions Rdb1 and the Rdb2 in the X direction. The region Rd2 corresponds to the contact plug CB. The region Rd2 is a region where the insulating layer 214 is removed when the insulating layer 214 is processed to form a mask pattern for the contact plug CB. The regions Rdb1 and Rdb2 are regions where the insulating layer 214 is removed when the insulating layers 212 to 215 are processed to form a hole pattern for the electrode 210.

It is assumed that the length of the region Rd2 in the X direction is Lcspx, and the length of the same region in the Y direction is Lcspy. The length Lcspy is longer than the length Ldb. In a plan view seen from the Z direction, the both ends of the region Rd2 in the Y direction protrude in the Y direction from the both ends of the bonding pad DB in the Y direction. In other words, the both ends of the region Rd2 in the Y direction protrude in the Y direction from the both ends of the regions Rdb1 and Rdb2 in the Y direction. At the ends of the region Rd2 in the Y direction (that is, the protruding regions), the insulating layer 214 is not in contact with the bonding pad DB. In contrast, in the regions Rdb1 and Rdb2, the insulating layer 214 is in contact with the bonding pad DB. For example, it is preferable that the difference between the length Lcspy and the length Ldb be equal to or longer than the misalignment between the photolithography corresponding to the processing of the region Rd2 of the insulating layer 214 and the photolithography corresponding to the processing of the electrode 210. Thus, even if a misalignment occurs between the region Rd2 of the opening region ROcsp and the electrode 210 (bonding pad DB), the length in the Y direction of the contact plug CB formed by self-alignment does not vary. The length Lcby of the upper surface of the contact plug CB in the Y direction is approximately equal to the length Ldb of the bonding pad DB.

The length Lcspx of the region Rd2 is shorter than the interconnect width Ld2x of the D2 interconnect layer 209. The length Lcspx is approximately equal to the length Lcbx of the upper surface of the contact plug CB in the X direction. For example, it is preferable that the length Lcspx be equal to or less than a length obtained by subtracting the photolithography alignment margin (e.g., 200 nm) corresponding to the processing of the insulating layer 214 from the interconnect width Ld2x of the D2 interconnect layer 209. This prevents the contact plug CB from deviating in the X direction from the D2 interconnect layer 209, in a plan view seen from the Z direction.

In the present embodiment, in order to correct the position deviation between the bonding pad MB and the bonding pad DB in the Y direction, the arrangement of the opening region ROcsp of the insulating layer 214 and the arrangement of the electrode 210 can be shifted in the Y direction with respect to the D2 interconnect layer 209, which extends in the Y direction. By shifting the opening region ROcsp of the insulating layer 214 and the electrode 210 in the Y direction, the position deviation between the bonding pad MB and the bonding pad DB in the Y direction can be corrected.

The M1 interconnect layer 107 may extend in the Y direction, and the D2 interconnect layer 209 may extend in the X direction. In this case, the opening region ROvsp and the electrode 108 are shifted in the Y direction, and the opening region ROcsp and the electrode 210 are shifted in the X direction. This enables correction of the position deviation between the bonding pad MB and the bonding pad DB.

Next, the cross-sectional shapes of the bonding pads MB and DB will be described.

As shown in FIGS. 11 and 12, the M1 interconnect layer 107 includes a barrier metal 107_1 and a conductor 107_2. The barrier metal 107_1 functions as an oxidation prevention layer, a diffusion prevention layer, and an adhesion layer for the conductor 107_2. The barrier metal 107_1 is formed such that it covers the side surface and the lower surface facing the Z2 direction of the M1 interconnect layer 107. The barrier metal 107_1 is in contact with the insulating layer 124. The conductor 107_2 is provided in the barrier metal 107_1 and in contact with the barrier metal 107_1. The conductor 107_2 is embedded in the barrier metal 107_1 such that it forms a core portion of the M1 interconnect layer 107. The barrier metal 107_1 contains, for example, titanium (Ti), titanium nitride (TiN), tantalum (Ta), or tantalum nitride (TaN). The barrier metal 107_1 may also be a multilayer film composed of these materials. The conductor 107_2 contains, for example, copper as a conductive material.

The electrode 108 includes a bonding pad MB and a contact plug VB.

As shown in FIG. 11, for example, the cross section taken along the X direction of the electrode 108 has a trapezoidal shape, in which the length Lmb in the X direction of the upper surface facing the Z1 direction (that is, the upper surface of the bonding pad MB) is longer than the length, in the X direction, of the lower surface facing the Z2 direction (that is, the lower surface of the contact plug VB) that is in contact with the M1 interconnect layer 107. The side surface facing the X direction of the electrode 108 has a tapered shape. The side surface facing the X direction of the bonding pad MB and the side surface facing the X direction of the contact plug VB are aligned in a straight line. The length Lvbx of the upper surface of the contact plug VB in the X direction is equal to the length of the lower surface of the bonding pad MB in the X direction.

As shown in FIG. 12, for example, in a cross-section taken along the Y direction of the electrode 108, a contact plug VB having a trapezoidal shape smaller than that of the bonding pad MB is provided so as to be coupled to the bonding pad MB in the Z2 direction. The side surfaces of the bonding pad MB and the contact plug VB each have a tapered shape. The side surface facing the Y direction of the bonding pad MB and the side surface facing the Y direction of the contact plug VB are not aligned in a straight line. The length Lmb of the upper surface of the bonding pad MB in the Y direction is longer than the length of the lower surface in the Y direction, which is in contact with the contact plug VB. The length Lvby of the upper surface of the contact plug VB in the Y direction is shorter than the length of the lower surface of the bonding pad MB in the Y direction and longer than the length of the lower surface thereof in the Y direction, which is in contact with the M1 interconnect layer 107.

As shown in FIGS. 11 and 12, the bonding pad MB is provided in the same layer as the insulating layers 127 and 128. The lower surface of the bonding pad MB reaches the insulating layer 126. The contact plug VB is provided in the insulating layers 125 and 126. That is, the bonding pad MB and the contact plug VB are in contact with each other at a same layer level as the insulating layer 126. The lower surface of the contact plug VB reaches the M1 interconnect layer 107.

The side surface facing the X direction of the electrode 108 is not in contact with the insulating layer 127 located at the end of the region Rm1 in the X direction. The side surface facing the X direction of the electrode 108 is in contact with the insulating layer 127 located at the ends of the regions Rmb1 and Rmb2 in the X direction. The side surface facing the Y direction of the electrode 108 is in contact with the insulating layer 127.

The electrode 108 includes a barrier metal (conductor) 108_1 and a conductor 108_2. The barrier metal 108_1 functions as an oxidation prevention layer, a diffusion prevention layer, and an adhesion layer for the conductor 108_2. The barrier metal 108_1 is formed such that it covers the side and lower surfaces of the electrode 108. The barrier metal 108_1 is in contact with the M1 interconnect layer 107 and the insulating layers 125 to 128. The conductor 108_2 is provided in the barrier metal 108_1 and in contact with the barrier metal 108_1. The conductor 108_2 is embedded in the barrier metal 108_1 such that it forms the core portion of the electrode 108 (the bonding pad MB and the contact plug VB). The barrier metal 108_1 contains, for example, titanium (Ti), titanium nitride (TiN), tantalum (Ta), or tantalum nitride (TaN). The barrier metal 108_1 may also be a multilayer film composed of these materials. The conductor 108_2 contains, for example, copper as a conductive material.

The electrode 210 includes a bonding pad DB and a contact plug CB.

As shown in FIG. 11, for example, in the cross section taken along the X direction of the electrode 210, a contact plug CB having a trapezoidal shape smaller than that of the bonding pad DB is provided so as to be coupled to the bonding pad DB in the Z1 direction. The side surfaces of the bonding pad DB and the contact plug CB each have a tapered shape. The side surface facing the X direction of the bonding pad DB and the side surface facing the X direction of the contact plug CB are not aligned in a straight line. The length Ldb of the upper surface of the bonding pad DB in the X direction is longer than the length of the lower surface thereof in the X direction, which is in contact with the contact plug CB. The length of the upper surface of the contact plug CB in the X direction is shorter than the length of the lower surface of the bonding pad DB in the X direction and longer than the length of the lower surface thereof in the X direction, which is in contact with the D2 interconnect layer 209.

As shown in FIG. 12, for example, the cross section taken along the Y direction of the electrode 210 has a trapezoidal shape, in which the length Ldb in the Y direction of the upper surface facing the Z2 direction of the electrode 210 (that is, the upper surface of the bonding pad DB) is longer than the length, in the Y direction, of the lower surface (that is, the lower surface of the contact plug CB) that is in contact with the D2 interconnect layer 209. The side surface facing the Y direction of the electrode 210 has a tapered shape. The side surface facing the Y direction of the bonding pad DB and the side surface facing the Y direction of the contact plug CB are aligned in a straight line. The length Lcby of the upper surface of the contact plug CB in the Y direction is equal to the length of the lower surface of the bonding pad DB in the Y direction.

As shown in FIGS. 11 and 12, the bonding pad DB is provided in the same layer as the insulating layers 214 and 215. The lower surface of the bonding pad DB reaches the insulating layer 213. The contact plug CB is provided in the insulating layers 212 and 213. That is, the bonding pad DB and the contact plug CB are in contact with each other at a same layer level as the insulating layer 213. The lower surface of the contact plug CB reaches the D2 interconnect layer 209.

The side surface facing the X direction of the electrode 210 is in contact with the insulating layer 214. The side surface facing the Y direction of the electrode 210 is not in contact with the insulating layer 214 located at the end of the region Rd2 in the Y direction. The side surface facing the Y direction of the electrode 210 is in contact with the insulating layer 214 located at the ends of the regions Rdb1 and Rdb2 in the Y direction.

The electrode 210 includes a barrier metal (conductor) 210_1 and a conductor 210_2. The barrier metal 210_1 functions as an oxidation prevention layer, a diffusion prevention layer, and an adhesion layer for the conductor 210_2. The barrier metal 210_1 is formed such that it covers the side and lower surfaces of the electrode 210. The barrier metal 210_1 is in contact with the D2 interconnect layer 209 and the insulating layers 212 to 215. The conductor 210_2 is provided in the barrier metal 210_1 and in contact with the barrier metal 210_1. The conductor 210_2 is embedded in the barrier metal 210_1 such that it forms a core portion of the electrode 210 (the bonding pad DB and the contact plug CB). The barrier metal 210_1 contains, for example, titanium (Ti), titanium nitride (TiN), tantalum (Ta), or tantalum nitride (TaN). The barrier metal 210_1 may also be a multilayer film composed of these materials. The conductor 210_2 contains, for example, copper as a conductive material.

The D2 interconnect layer 209 includes a barrier metal 209_1 and a conductor 209_2. The barrier metal 209_1 functions as an oxidation prevention layer, a diffusion prevention layer, and an adhesion layer for the conductor 209_2. The barrier metal 209_1 is formed such that it covers the side surface and the lower surface facing the Z1 direction of the D2 interconnect layer 209. The barrier metal 209_1 is in contact with the insulating layer 211. The conductor 209_2 is provided in the barrier metal 209_1 and in contact with the barrier metal 209_1. The conductor 209_2 is embedded in the barrier metal 209_1 such that it forms a core portion of the D2 interconnect layer 209. The barrier metal 209_1 contains, for example, titanium (Ti), titanium nitride (TiN), tantalum (Ta), or tantalum nitride (TaN). The barrier metal 209_1 may also be a multilayer film composed of these materials. The conductor 209_2 contains, for example, copper as a conductive material.

For example, if copper is used for the conductors 108_2 and 210_2, the copper in the conductor 108_2 and the copper in the conductor 210_2 may become integrated, making it difficult to identify the boundary between the two conductors. However, the bonding can be identified by the distortion of the bonded shape of the electrodes 108 and 210 due to the position deviation of the electrodes 108 and 210 when they are bonded together, and by the position deviation between the barrier metals 108_1 and 210_1 (the occurrence of discontinuous portions on the side surfaces).

In a case where the electrodes 108 and 210 are formed by the dual damascene method, each of their side surfaces has a tapered shape. Therefore, the cross-sectional shape taken along the Z direction of the portion where the electrodes 108 and 210 are bonded together does not have a straight sidewall but has a non-rectangular shape.

In a case where the electrodes 108 and 210 are bonded together, the barrier metals 108_1 and 210_1 cover the lower surface, side surface, and upper surface of the copper that forms the electrodes 108 and 210. In contrast, in a typical interconnect layer using copper, a cap insulating layer (such as SiN or SiCN) having a copper oxidation prevention function is provided on the upper surface of the copper, and no barrier metal is provided. For this reason, even if there is no position deviation during the bonding, it is possible to distinguish the bonding interface from a typical interconnect layer.

### 1.2 Specific Example of Misalignment Between Region Rd2 and Bonding Pad DB

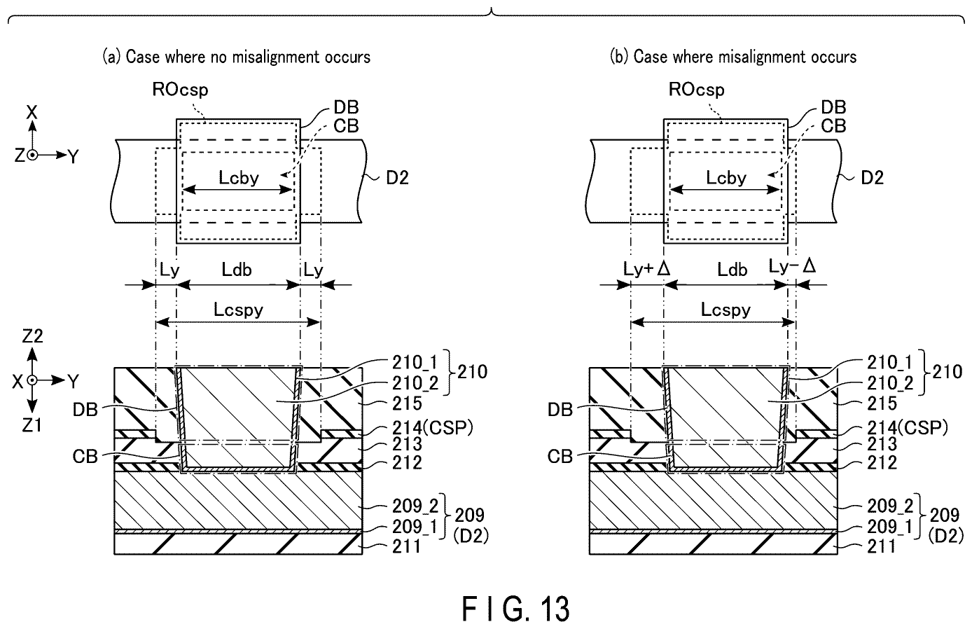

Next, a specific example of misalignment between the region Rd2 of the opening region ROcsp of the insulating layer 214 and the bonding pad DB will be described with reference to FIG. 13. FIG. 13 is a diagram showing an example of the positional relationship between the opening region ROcsp of the insulating layer 214 and the electrode 210 (bonding pad DB). In portion (a) of FIG. 13, an example of a plan view and a cross sectional view in the Y direction are shown for the case where no misalignment occurs between the photolithography corresponding to the processing of the region Rd2 of the insulating layer 214 and the photolithography corresponding to the processing of the electrode 210. In portion (b) of FIG. 13, an example of a plan view and a cross sectional view in the Y direction are shown for the case where misalignment occurs between the photolithography corresponding to the processing of the region Rd2 of the insulating layer 214 and the photolithography corresponding to the processing of the electrode 210. By exchanging the X and Y directions, the relationship between the region Rm1 of the opening ROvsp in the insulating layer 127 and the electrode 108 (bonding pad MB) becomes similar to the relationship between the region Rd2 of the opening ROcsp in the insulating layer 214 and electrode 210 (bonding pad DB).

The etching stopper CSP (insulating layer 214) functions as a mask when the contact plug CB (insulating layer 213) is processed. For example, in the photolithography for processing the region Rd2 included in the opening region ROcsp of the insulating layer 214 and corresponding to the contact plug CB, alignment is performed for the alignment pattern of the D2 interconnect layer 209. For example, in the photolithography for processing the electrode 210 (forming a hole pattern of the electrode 210), alignment is performed for the alignment pattern formed by processing the insulating layer 214 or for the alignment pattern of the D2 interconnect layer 209. At this time, a position deviation due to an alignment error may occur between the electrode 210 and the region Rd2 within the opening region ROcsp. In a case where the alignment pattern formed by processing the insulating layer 214 is used in the photolithography for processing the electrode 210, the hole pattern of the electrode 210 is directly aligned with the mask pattern (region Rd2) of the insulating layer 214. In contrast, in a case where the alignment pattern of the D2 interconnect layer 209 is used in the photolithography for processing the electrode 210, the hole pattern of the electrode 210 is indirectly aligned with the mask pattern of the insulating layer 214. For this reason, in a case where the alignment pattern of the D2 interconnect layer 209 is used in the photolithography for processing the electrode 210, the position deviation due to an alignment error between the region Rd2 of the opening region ROcsp and the electrode 210 tends to increase as compared with the case where the alignment pattern formed by processing the insulating layer 214 is used.

In the example shown in portion (a) of FIG. 13, no misalignment occurs between the photolithography for processing the region Rd2 of the opening region ROcsp of the insulating layer 214 and the photolithography for processing the electrode 210. In other words, no position deviation due to misalignment occurs between the region Rd2 of the opening region ROcsp and the electrode 210. In a plan view seen from the Z direction, the region Rd2 of the opening region ROcsp protrudes in the Y direction from the end of the bonding pad DB (electrode 210) in the Y direction. In a case where no misalignment occurs, the length in the Y direction of the protrusion of the region Rd2 on the right side of the drawing sheet is equal to the length in the Y direction of the protrusion on the left side of the drawing sheet. For example, this length is denoted by Ly. In this case, the length Lcspy of the region Rd2 of the opening region ROcsp in the Y direction can be expressed as Lcspy=2Ly+Ldb.

In the example shown in portion (b) of FIG. 13, misalignment occurs between the photolithography for processing the region Rd2 of the opening region ROcsp of the insulating layer 214 and the photolithography for processing the electrode 210. In other words, a position deviation due to misalignment occurs between the region Rd2 of the opening region ROcsp and the bonding pad DB. In the example shown in portion (b) of FIG. 13, the electrode 210 deviates toward the right side of the drawing sheet relative to the region Rd2 of the opening region ROcsp. The misalignment amount at this time is denoted by Δ. The protrusion of the region Rd2 on the right side of the drawing sheet has a length (Ly−Δ) in the Y direction. The protrusion of the region Rd2 on the left side of the drawing sheet has a length (Ly+Δ) in the Y direction. If the relationship between the length Ly of the protrusion and the misalignment amount Δ is Ly>Δ, the bonding pad DB does not protrude in the Y direction from the region Rd2. Therefore, the length Lcby of the upper surface of the contact plug CB in the Y direction is constant regardless of the misalignment amount Δ.

### 1.3 Specific Example of Position Deviation Correction Between Bonding Pad MB and Bonding Pad DB

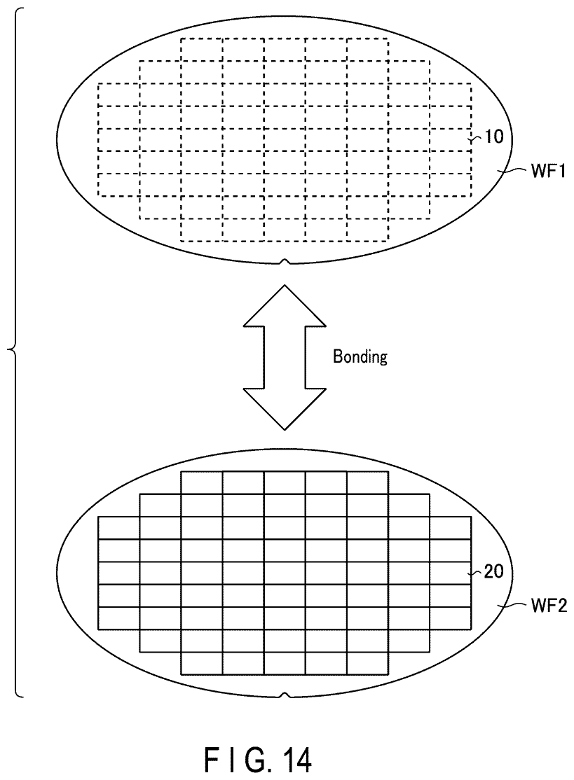

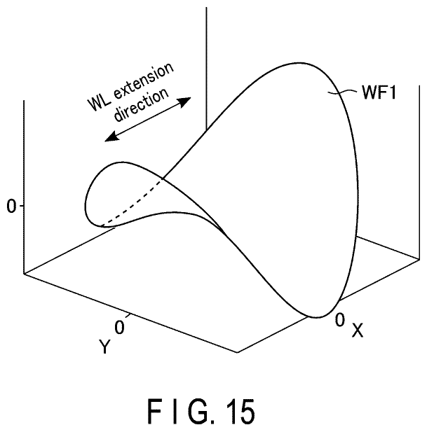

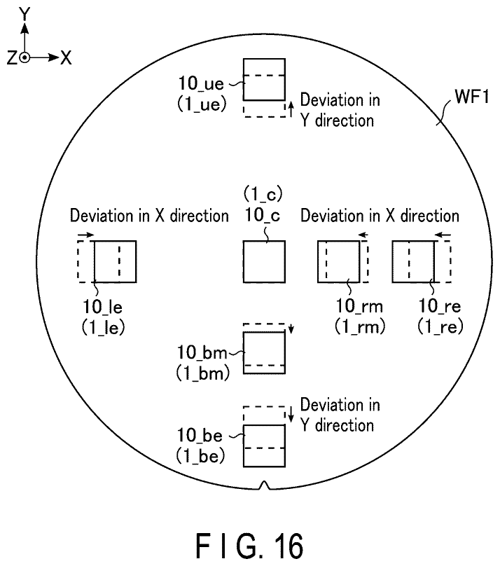

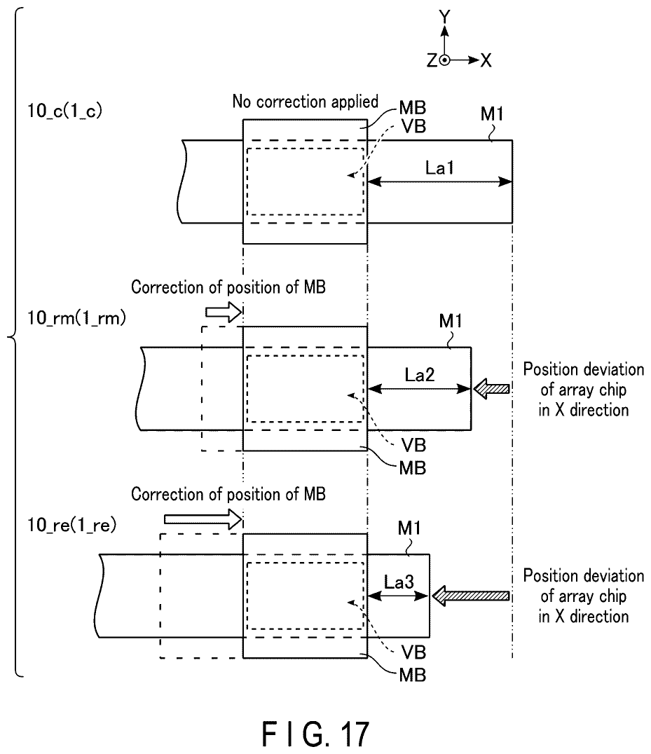

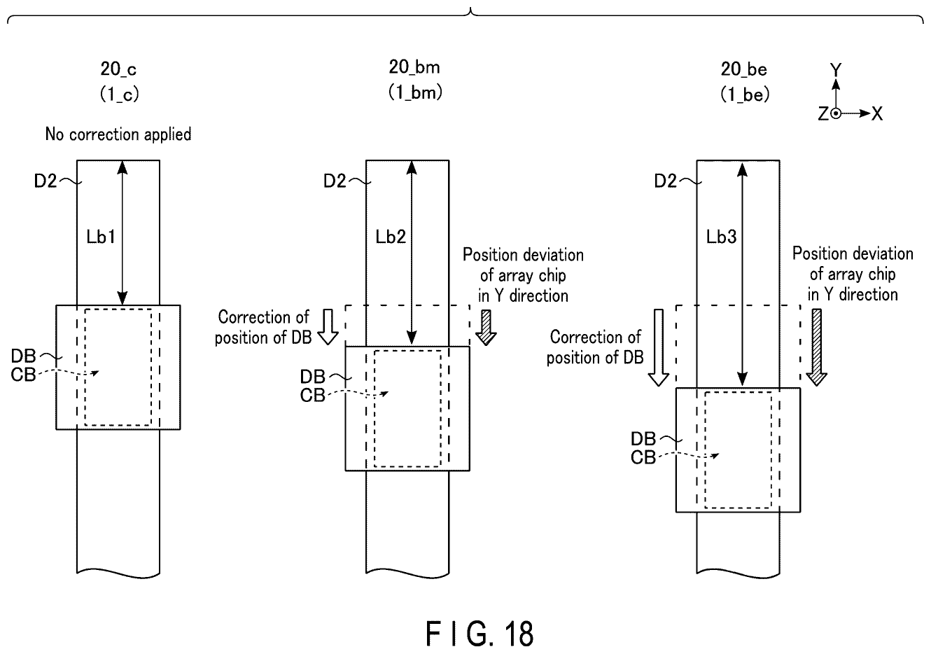

Next, a specific example of position deviation correction between the bonding pad MB and the bonding pad DB will be described with reference to FIGS. 14 to 18. FIG. 14 is a diagram showing the bonding between a wafer WF1 on which a plurality of array chips 10 are formed and a wafer WF2 on which a plurality of circuit chips 20 are formed. FIG. 15 is a perspective view schematically showing warpage of the wafer WF1 on which the plurality of array chips 10 are formed. FIG. 16 is a diagram schematically showing directions of position deviation of the array chips 10 on the wafer WF1. FIG. 17 is a plan view of the M1 interconnect layer 107 and the electrode 108 showing an example of how the position deviation of the electrode 108 is corrected in accordance with its position deviation in the X direction. FIG. 18 is a plan view of the D2 interconnect layer 209 and the electrode 210 showing an example of how the position deviation of the electrode 210 is corrected in accordance with its position deviation in the Y direction.

As shown in FIG. 14, a plurality of array chips 10 are formed on the wafer WF1. A plurality of circuit chips 20 are formed on the wafer WF2. In the assembly process of the semiconductor device 1, the wafer WF1 on which the plurality of array chips 10 are formed and the wafer WF2 on which the plurality of circuit chips 20 are formed are bonded together. Then, the bonded wafers WF1 and WF2 are diced into individual chips to form semiconductor devices 1 with a bonded structure.

As shown in FIG. 15, for example, the wafer WF1 on which the plurality of array chips 10 are formed may exhibit warpage in the X direction that differs from the warpage in the Y direction, due to the influence of film stress from the interconnect layers 102 (word lines WL and select gate lines SGD and SGS) extending in the X direction. In the example shown in FIG. 15, when viewing the cross section in the extension direction of the word line WL, that is, the X direction passing through the center of wafer WF1 (the cross section taken along the X direction at the position Y=0 in the figure), the wafer WF1 has a downwardly convex shape due to tensile stress. In contrast, when viewing the cross section in the Y direction passing through the center of wafer WF1 (the cross section taken along the Y direction at the position X=0 in the figure), the wafer WF1 has an upwardly convex shape due to compressive stress.

As shown in FIG. 16, for example, when warpage such as that described with reference to FIG. 15 occurs in the wafer WF1, the actual chip positions indicated by the solid lines deviate from the designed chip positions indicated by the dashed lines. Specifically, for example, the array chip 10_c located at the center of the wafer WF1 has an actual chip position coinciding with the designed chip position. In contrast, in a state where the notch of the wafer WF1 is positioned at the bottom, the array chip 10_ue located at the outer periphery of the wafer WF1 in the 12 o'clock direction (the upper side of the drawing sheet of FIG. 16) has an actual chip position that deviates in the Y direction from the designed chip position toward the outer periphery of the wafer WF1 (toward the upper side of the drawing sheet of FIG. 16).

The array chip 10_re located at the outer periphery of the wafer WF1 in the 3 o'clock direction (the right side of the drawing sheet of FIG. 16) has an actual chip position that deviates in the X direction from the designed chip position toward the center of the wafer WF1 (toward the left side of the drawing sheet of FIG. 16). Similarly, for example, the array chip 10_rm located midway between the array chips 10_c and 10_re has an actual chip position that deviates in the X direction from the designed chip position toward the center of the wafer WF1 (toward the left side of the drawing sheet of FIG. 16). For example, as shown in FIG. 15, the amount of warpage of the wafer WF1 in the X direction increases from the center of the wafer WF1 toward its outer periphery in the X direction. Therefore, the amount of position deviation of the array chip 10_re in the X direction is larger than the amount of position deviation of the array chip 10_rm in the X direction.

The array chip 10_be located at the outer periphery of the wafer WF1 in the 6 o'clock direction (the lower side of the drawing sheet of FIG. 16) has an actual chip position that deviates in the Y direction toward the outer periphery of the wafer WF1 (toward the lower side of the drawing sheet of FIG. 16) from the designed chip position. Similarly, for example, the array chip 10_bm located midway between the array chips 10_c and 10_be deviates in the Y direction from the designed chip position toward the outer periphery of the wafer WF1 (toward the lower side of the drawing sheet of FIG. 16). For example, as shown in FIG. 15, the amount of warpage of the wafer WF1 in the Y direction increases from the center of the wafer WF1 toward the outer periphery in the Y direction. Therefore, the amount of position deviation of the array chip 10_be in the Y direction is larger than the amount of position deviation of the array chip 10_bm in the Y direction.

The actual chip position of the array chip 10_le located at the outer periphery of the wafer WF1 in the 9 o'clock direction (the left side of the drawing sheet of FIG. 16) deviates in the X direction from the designed chip position toward the center of the wafer WF1 (toward the right side of the drawing sheet of FIG. 16). In this manner, the directions and amounts of position deviation of the array chips 10 differ depending on the positions on the wafer WF1.

The position deviation of the array chips 10 in the X direction is corrected by shifting the electrode 108 (bonding pads MB and contact plugs VB) of the array chip 10 in the X direction. The position deviation of the array chips 10 in the Y direction is corrected by shifting the electrode 210 (bonding pads DB and contact plugs CB) of the corresponding (bonded) circuit chip 20 in the Y direction. Therefore, the direction of position deviation correction and the amount of position deviation correction differ among the semiconductor device 1_c including the array chip 10_c, the semiconductor device 1_ue including the array chip 10_ue, the semiconductor device 1_rm including the array chip 10_rm, the semiconductor device 1_re including the array chip 10_re, the semiconductor device 1_bm including the array chip 10_bm, the semiconductor device 1_be including the array chip 10_be, and the semiconductor device 1_le including the array chip 10_le.

Next, a description will be given of the case where the position deviation in the X direction is corrected. The example in FIG. 17 shows a case where the position deviation in the X direction is corrected for the array chips 10_rm and 10_re arranged in the 3 o'clock direction from the center of the wafer WF1 (the right side of the drawing sheet of FIG. 16). It is noted that the array chip 10_le arranged in the 9 o'clock direction from the center of the wafer WF1 (the left side of the drawing sheet of FIG. 16) has a position deviation in the opposite direction to that of the array chip 10_re. Therefore, the position deviation of the array chip 10_le in the X direction is corrected in the opposite direction to that of the array chip 10_re.

As described with reference to FIG. 16, for example, the array chip 10_c of the semiconductor device 1_c does not deviate in the X direction. Therefore, in a case where the bonding pad MB and the bonding pad DB are bonded together, there is almost no position deviation in the X direction between the bonding pad MB and the bonding pad DB. It is noted that position deviation may occur due to manufacturing variations. In this case, as shown in FIG. 17, in the array chip 10_c, the electrode 108 (the bonding pad MB and the contact plug VB) is formed on the M1 interconnect layer 107 without the position deviation in the X direction being corrected. The array chips 10_ue and 10_be, which do not deviate in the X direction, are similar to the array chip 10_c.

For example, the array chip 10_rm of the semiconductor device 1_rm and the array chip 10_re of the semiconductor device 1_re deviate in the X direction toward the center of the wafer WF1 (toward the left side of the drawing sheet of FIG. 17), as described with reference to FIG. 16. Therefore, if the bonding pad MB and the bonding pad DB are bonded together without correcting the position deviation, the bonding pad MB deviates in the X direction toward the left side of the drawing sheet of FIG. 17 relative to the bonding pad DB. Therefore, in the array chips 10_rm and 10_re, the position of the bonding pad MB is corrected toward the outer periphery of the wafer WF1 (toward the right side of the drawing sheet of FIG. 17), which is opposite to the direction of the position deviation. This corrects the position deviation in the X direction.

The amount of warpage of the wafer WF1 in the X direction varies depending on the position of the wafer WF1 where the array chip 10 is formed. For this reason, the amount of position deviation of the bonding pad MB in the X direction differs depending on the position of the wafer WF1 where the array chip 10 is provided. Therefore, the amount of position deviation correction of the bonding pad MB in the X direction differs between the array chip 10_rm and the array chip 10_re. The amount of position deviation of the array chip 10_re in the X direction is larger than the amount of position deviation of the array chip 10_rm in the X direction. Therefore, the correction amount of the position deviation of the electrode 108 (bonding pad MB) of the array chip 10_re in the X direction is larger than the correction amount of the position deviation of the electrode 108 (bonding pad MB) of the array chip 10_rm in the X direction. For example, it is assumed that in the array chip 10_c, the distance from the end of the M1 interconnect layer 107 on the right side of the drawing sheet to the electrode 108 (bonding pad MB) is La1. It is also assumed that in the array chip 10_rm, the distance from the end of the M1 interconnect layer 107 on the right side of the drawing sheet to the electrode 108 is La2. It is further assumed that in the array chip 10_re, the distance from the end of the M1 interconnect layer 107 on the right side of the drawing sheet to the electrode 108 is La3. Due to the correction of the position deviation of the array chips 10_rm and 10_re in the X direction, the distances La1, La2, and La3 satisfy the relationship: La1>La2>La3.

Therefore, in order to correct the position deviation in the X direction, the positional relationship between the M1 interconnect layer 107 and the electrode 108 may vary from one array chip 10 to another.

Next, a description will be given of the case where the position deviation in the Y direction is corrected. The example in FIG. 18 shows the case where the position deviation in the Y direction is corrected in the circuit chips 20_bm and 20_be corresponding to the array chips 10_bm and 10_be arranged in the 6 o'clock direction from the center of the wafer WF1 (on the lower side of the drawing sheet of FIG. 16). It is noted that the array chip 10_ue arranged in the 12 o'clock direction from the center of the wafer WF1 (the upper side of the drawing sheet of FIG. 16) has a position deviation in the opposite direction to that of the array chip 10_be. Therefore, in the circuit chip 20 corresponding to the array chip 10_ue arranged in the 12 o'clock direction from the center of the wafer WF1 (upper side of the drawing sheet of FIG. 16), the position deviation in the Y direction is corrected in the opposite direction to that of the circuit chip 20_be.

As described with reference to FIG. 16, for example, the array chip 10_c of the semiconductor device 1_c does not deviate in the Y direction. Therefore, in a case where the bonding pad MB and the bonding pad DB are bonded together, there is almost no position deviation in the Y direction between the bonding pad MB and the bonding pad DB. It is noted that position deviation may occur due to manufacturing variations. In this case, as shown in FIG. 18, in the circuit chip 20_c corresponding to the array chip 10_c, an electrode 210 (the bonding pad DB and the contact plug CB) is formed on the D2 interconnect layer 209 without the position deviation in the Y direction being corrected. It is noted that the array chips 10_rm, 10_re, and 10_le do not deviate in the Y direction. Therefore, the circuit chips 20 corresponding to the array chips 10_rm, 10_re, and 10_le, respectively, are similar to the circuit chip 20_c.

For example, the array chip 10_bm of the semiconductor device 1_bm and the array chip 10_be of the semiconductor device 1_be deviate in the Y direction toward the outer periphery of the wafer WF1 (toward the lower side of the drawing sheet of FIG. 18) in the same manner as described with reference to FIG. 16. Therefore, if the bonding pad MB and the bonding pad DB are bonded together without correcting the position deviation, the bonding pad MB deviates in the Y direction toward the lower side of the drawing sheet of FIG. 18 relative to the bonding pad DB. For this reason, in the circuit chip 20_bm corresponding to the array chip 10_bm and the circuit chip 20_be corresponding to the array chip 10_be, the position of the bonding pad DB is corrected in the same direction as the position deviation of the bonding pad MB, that is, toward the outer periphery of the wafer WF2 (toward the lower side of the drawing sheet of FIG. 18). This corrects the position deviation in the Y direction.

The amount of position deviation of the bonding pad MB in the Y direction differs depending on the position of the wafer WF1 where the array chip 10 is provided. Therefore, the correction amount of the position deviation of the bonding pad DB in the Y direction differs depending on the circuit chip 20. The amount of position deviation of the array chip 10_be in the Y direction is larger than the amount of the position deviation of the array chip 10_bm in the Y direction. For this reason, the correction amount of the position deviation in the Y direction of the electrode 210 (bonding pad DB) of the circuit chip 20_be corresponding to the array chip 10_be is larger than the correction amount of the position deviation in the Y direction of the electrode 210 (bonding pad DB) of the circuit chip 20_bm corresponding to the array chip 10_bm. For example, it is assumed that in the circuit chip 20_c, the distance from the end of the D2 interconnect layer 209 on the upper side of the drawing sheet to the bonding pad DB is Lb1. It is also assumed that in the circuit chip 20_bm, the distance from the end of the D2 interconnect layer 209 on the upper side of the drawing sheet to the bonding pad DB is Lb2. It is further assumed that in the circuit chip 20_be, the distance from the end of the D2 interconnect layer 209 on the upper side of the drawing sheet to the bonding pad DB is Lb3. As a result of the position deviation correction of the circuit chips 20_bm and 20_be in the Y direction, the distances Lb1, Lb2, and Lb3 satisfy the relationship: Lb1<Lb2<Lb3.

Therefore, in order to correct the position deviation in the Y direction, the positional relationship between the D2 interconnect layer 209 and the electrode 210 may vary from one circuit chip 20 to another.

In a case where an array chip 10 and a circuit chip 20 (neither is shown) are arranged in directions other than the 12, 3, 6, and 9 o'clock directions from the centers of wafers WF1 and WF2, the electrode 108 of the array chip 10 may be shifted in the X direction, and the electrode 210 of the circuit chip 20 may be shifted in the Y direction. Thus, in the semiconductor device 1 in which the corresponding array chip 10 and circuit chip 20 are bonded together, the position deviation between the bonding pad MB and the bonding pad DB can be corrected.

### 1.4 Manufacturing Method of Electrode

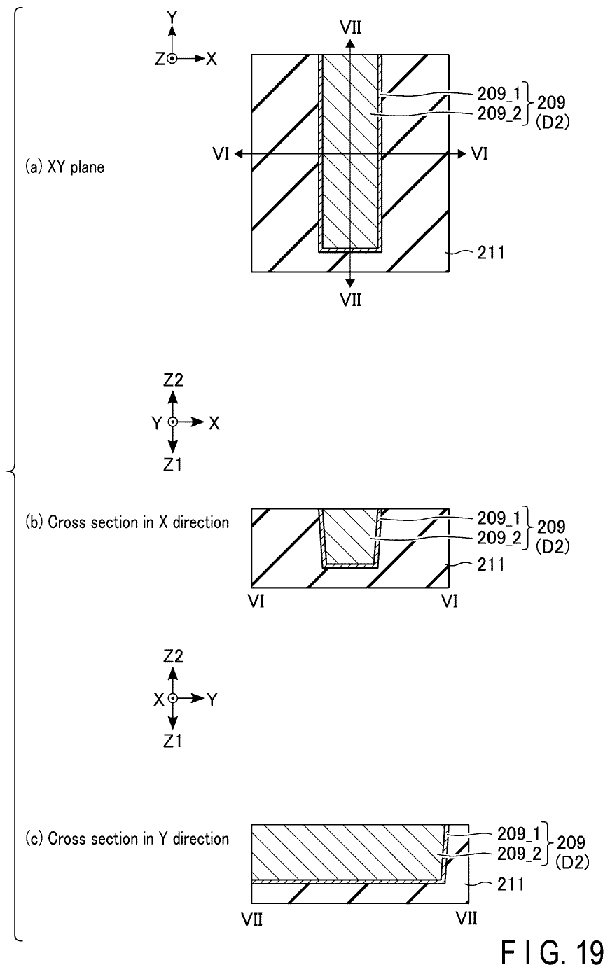

Next, an example of a manufacturing method of the electrode 210 will be described with reference to FIGS. 19 to 24. FIGS. 19 to 24 are diagrams illustrating manufacturing processes of the electrode 210. In each of FIGS. 19 to 24, (a) an XY plane, (b) a cross section in the X direction, and (c) a cross section in the Y direction are shown. The manufacturing method of the electrode 108 is similar to the manufacturing method of the electrode 210.

As shown in FIG. 19, an insulating layer 211 is first formed above a semiconductor substrate 201 (not shown). Then, a D2 interconnect layer 209 is formed. More specifically, a groove pattern of the D2 interconnect layer 209 is formed in the insulating layer 211. In a case where the contact plug C1 and the D2 interconnect layer 209 are formed by the dual damascene method, a groove pattern of the D2 interconnect layer 209 and a hole pattern (not shown) of the contact plug C1 are formed. Next, a barrier metal 209_1 and a conductor 209_2 are deposited in this order to fill the groove pattern of the D2 interconnect layer 209. Next, excess barrier metal 209_1 and excess conductor 209_2 on the insulating layer 211 are removed, for example, by a chemical mechanical polishing (CMP). This forms the D2 interconnect layer 209.

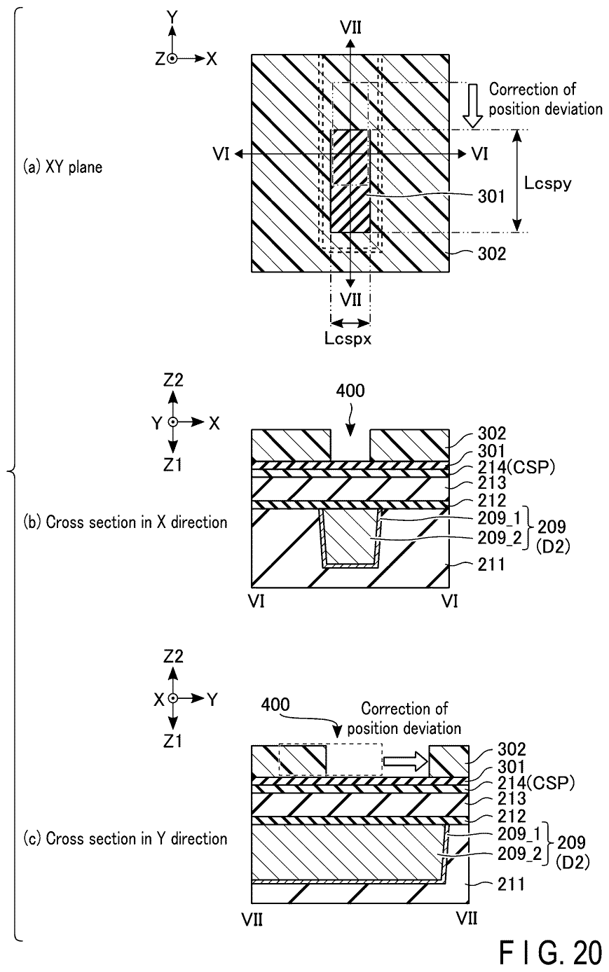

As shown in FIG. 20, an insulating layer 212 is deposited on the insulating layer 211 and the D2 interconnect layer 209. An insulating layer 213 and an insulating layer 214 (an etching stopper CSP) are deposited on the insulating layer 212 in this order. Next, an opening pattern 400 of a resist 302 corresponding to a region Rd2 (a contact plug CB) is formed above the D2 interconnect layer 209 by photolithography. The pattern 400 has a substantially rectangular shape with a length Lcspx in the X direction and a length Lcspy in the Y direction. More specifically, a member 301 is first formed on the insulating layer 214. For example, the member 301 functions as an anti-reflection film for photolithography. The resist 302 is coated onto the member 301, and then the pattern 400 is formed by photolithography. In order to correct the position deviation in the Y direction between the bonding pad MB and the bonding pad DB, the pattern 400 may be shifted in the Y direction from the reference position (the design position in a state where no position deviation occurs).

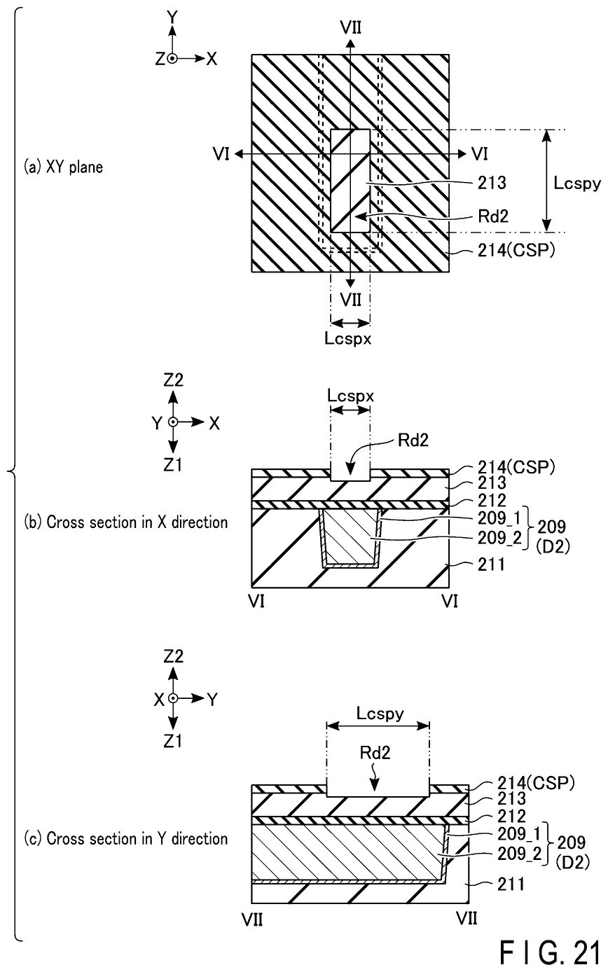

As shown in FIG. 21, the insulating layer 214 is processed using the resist 302 as a mask. As a result, a region Rd2 of the opening region ROcsp is formed. After the insulating layer 214 is processed, the resist 302 and the member 301 are removed.

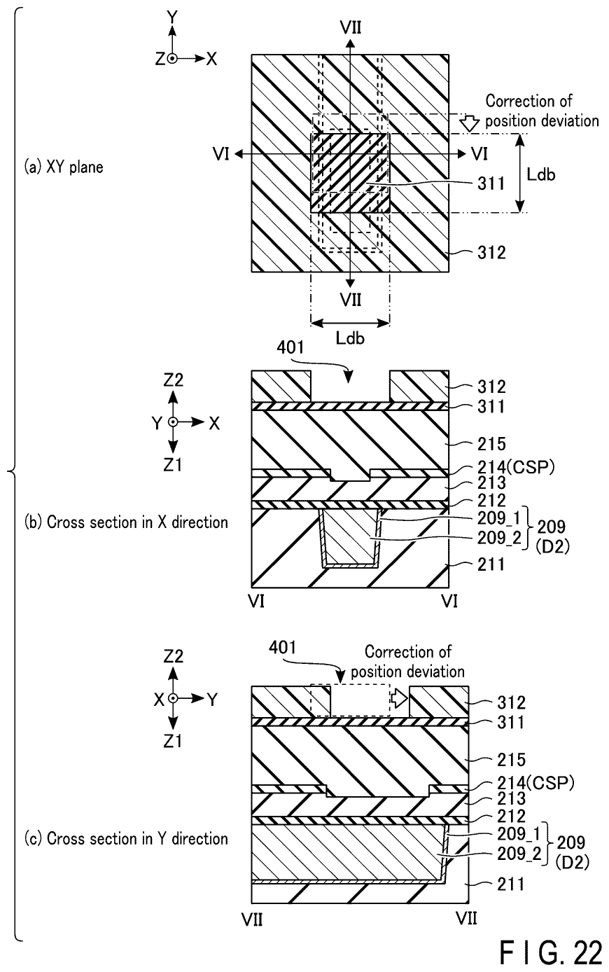

As shown in FIG. 22, an insulating layer 215 is deposited on the insulating layers 213 and 214. Next, an opening pattern 401 of a resist 312 corresponding to the bonding pad DB (electrode 210) is formed above the region Rd2 of the opening region ROcsp by photolithography. The pattern 401 has a substantially square shape with a side length of Ldb. More specifically, a member 311 is first formed on the insulating layer 215. For example, the member 311 functions as an anti-reflection film for photolithography. The resist 312 is coated onto the member 311, and then the pattern 401 is formed by photolithography. In a case where the pattern 400 is shifted in the Y direction, the pattern 401 is shifted in the Y direction in the same manner as the pattern 400.

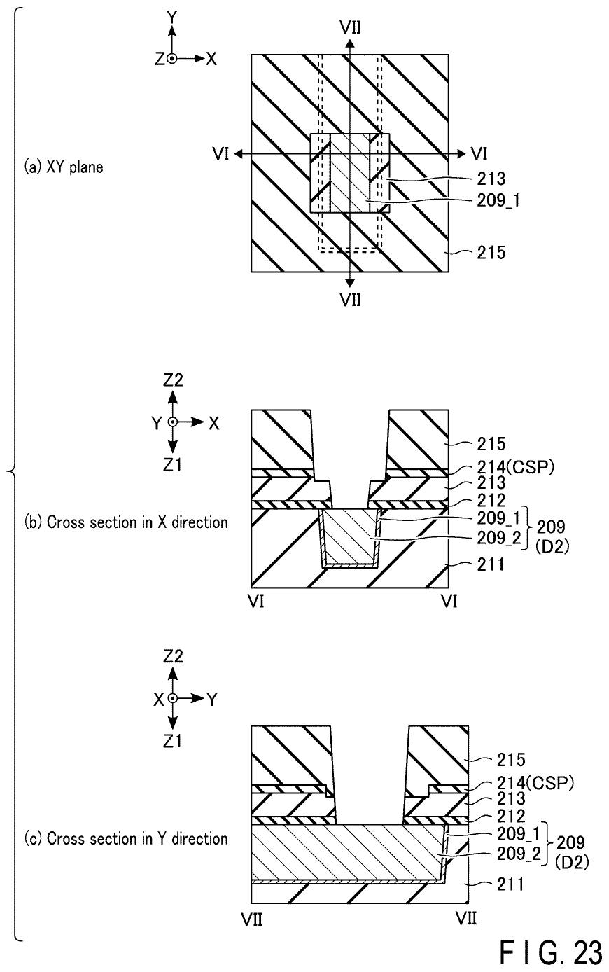

As shown in FIG. 23, the insulating layers 212 to 215 are processed using the resist 312 as a mask to form a hole pattern for the electrode 210. That is, hole patterns corresponding to the bonding pad DB and the contact plug CB are formed together. More specifically, the insulating layer 215 is first processed using the resist 312 as a mask. When the insulating layer 215 is processed and the insulating layer 214 is exposed, the insulating layer 213 is processed using the resist 312 and the insulating layer 214 as masks. That is, the pattern for the contact plug CB is formed in a self-aligned manner using the insulating layer 214 as a mask. Next, the exposed insulating layer 214 (the insulating layer 214 in the regions Rdb1 and Rdb2) and the insulating layer 212 exposed at the bottom of the pattern of the contact plug CB are removed to form a hole pattern of the electrode 210. At this time, the opening region ROcsp of the insulating layer 214 has such a shape as described with reference to FIG. 10.

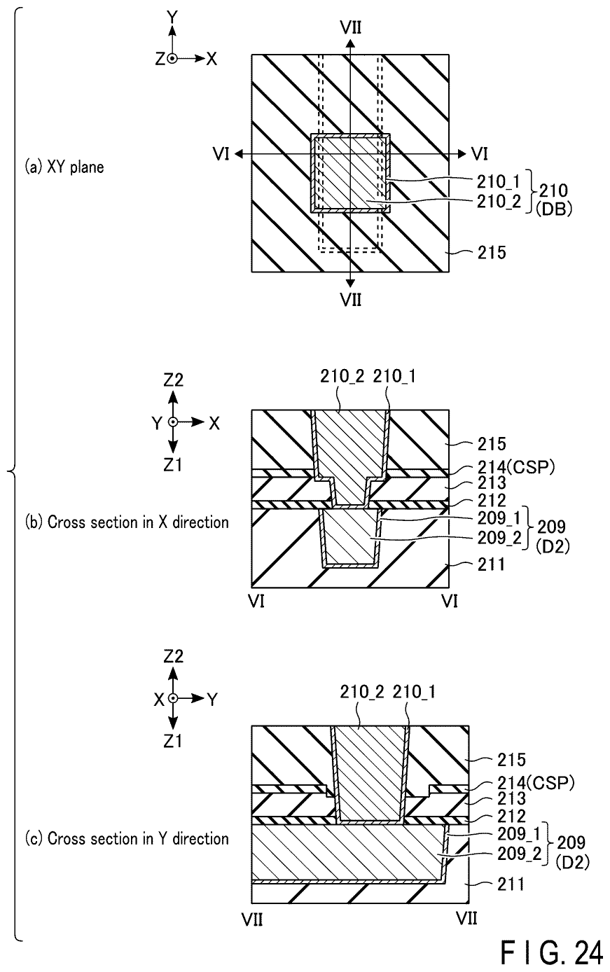

As shown in FIG. 24, an electrode 210 (a bonding pad DB and a contact plug CB) is formed. More specifically, a barrier metal 210_1 and a conductor 210_2 are deposited in this order to fill the hole pattern of the electrode 210. Next, excess barrier metal 210_1 and excess conductor 210_2 on the insulating layer 215 are removed, for example, by CMP. In this manner, the electrode 210 is formed.

### 1.5 Advantages of Present Embodiment

In the configuration according to the present embodiment, the semiconductor device 1 includes an array chip 10 and a circuit chip 20 that are bonded together. The array chip 10 and the circuit chip 20 are electrically coupled by bonding the bonding pad MB of the array chip 10 and the bonding pad DB of the circuit chip 20 to each other. In order to correct the position deviation in the X direction between the bonding pad MB and the bonding pad DB, the semiconductor device 1 can shift the arrangements of the opening region ROvsp of the insulating layer 127 and the electrode 108 in the X direction with respect to the M1 interconnect layer 107, which extends in the X direction. By shifting the opening region ROvsp of the insulating layer 127 and the electrode 108 in the X direction, the semiconductor device 1 can correct the position deviation in the X direction between the bonding pad MB and the bonding pad DB. In addition, in order to correct the position deviation in the Y direction between the bonding pad MB and the bonding pad DB, the semiconductor device 1 can shift the arrangements of the opening region ROcsp of the insulating layer 214 and the electrode 210 in the Y direction with respect to the D2 interconnect layer 209, which extends in the Y direction. By shifting the opening region ROcsp of the insulating layer 214 and the electrode 210 in the Y direction, the semiconductor device 1 can correct the position deviation in the Y direction between the bonding pad MB and the bonding pad DB. Thus, the semiconductor device 1 can reduce defective coupling between the bonding pad MB and the bonding pad DB due to position deviation. Therefore, the yield of the semiconductor device 1 can be improved.

Furthermore, in the configuration according to the present embodiment, the semiconductor device 1 allows the length Lvspx in the X direction of the region Rm1 within the opening region ROvsp of the insulating layer 127, which functions as the etching stopper VSP, to be longer than the length Lmb of the upper surface of the bonding pad MB. That is, in the semiconductor device 1, the length Lvspx in the X direction of the mask pattern corresponding to the contact plug VB can be made longer than the length Lmb in the X direction of the upper surface of the bonding pad MB. Thus, even if a misalignment occurs between the region Rm1 of the opening region ROvsp and the bonding pad MB, the semiconductor device 1 does not exhibit variation in the length in the X direction of the contact plug VB formed by self-alignment. That is, the semiconductor device 1 can make the resistance value of the contact plug VB approximately constant. By making the resistance value of the contact plug VB approximately constant, the semiconductor device 1 can reduce defective coupling between the M1 interconnect layer 107 and the bonding pad MB. Similarly, the semiconductor device 1 allows the length Lcspy in the Y direction of the region Rd2 of the opening region ROcsp of the insulating layer 214, which functions as the etching stopper CSP, to be longer than the length Ldb of the upper surface of the bonding pad DB. That is, in the semiconductor device 1, the length Lcspy in the Y direction of the mask pattern corresponding to the contact plug CB can be made longer than the length Ldb in the Y direction of the upper surface of the bonding pad DB. Thus, even if a misalignment occurs between the region R2d of the opening region ROcsp and the bonding pad DB, the length in the Y direction of the contact plug CB formed by self-alignment does not vary in the semiconductor device 1. That is, the semiconductor device 1 can make the resistance value of the contact plug CB approximately constant. By making the resistance value of the contact plug CB approximately constant, the semiconductor device 1 can reduce defective coupling between the D2 interconnect layer 209 and the bonding pad DB. Therefore, the yield of the semiconductor device 1 can be improved.

### 2. Second Embodiment

Next, the second embodiment will be described. In the second embodiment, the shape of the etching stopper different from that of the first embodiment will be described. The description below will focus on the differences from the first embodiment.

### 2.1 Structure of Bonding Pad

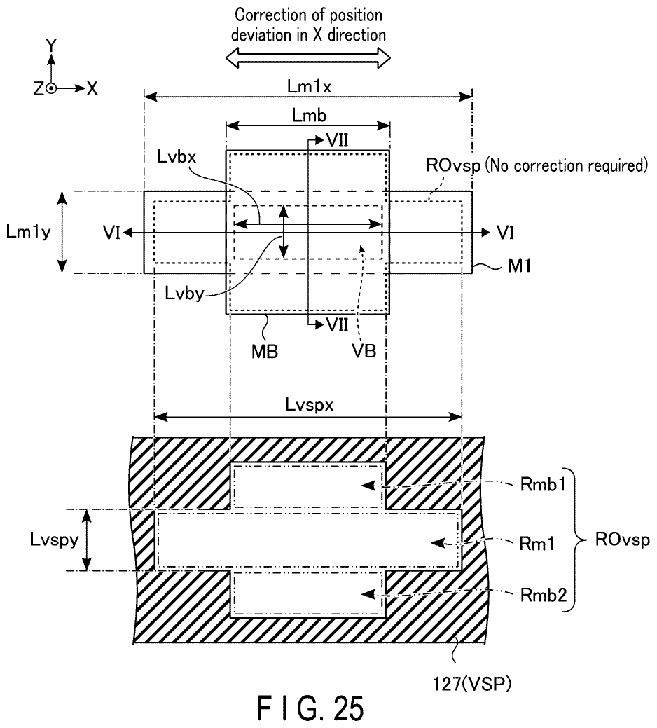

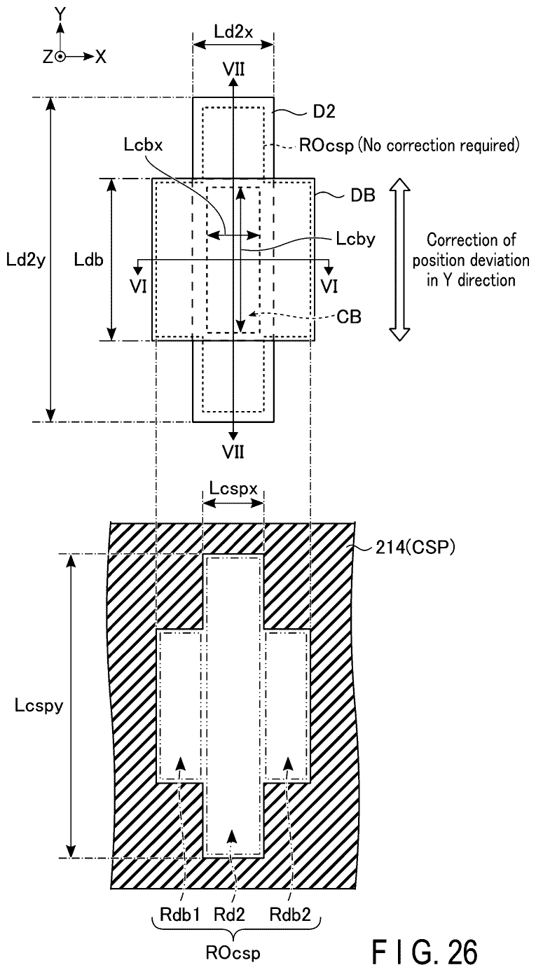

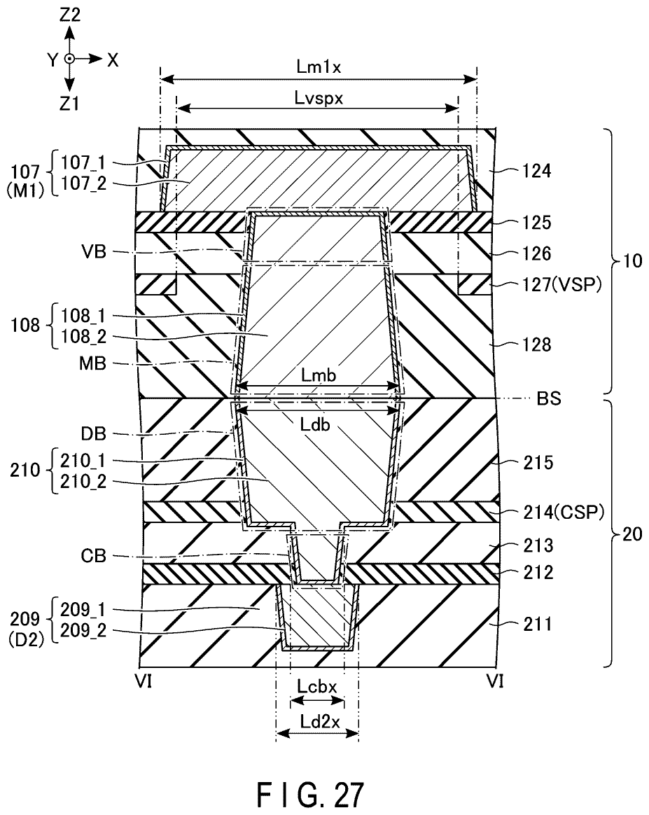

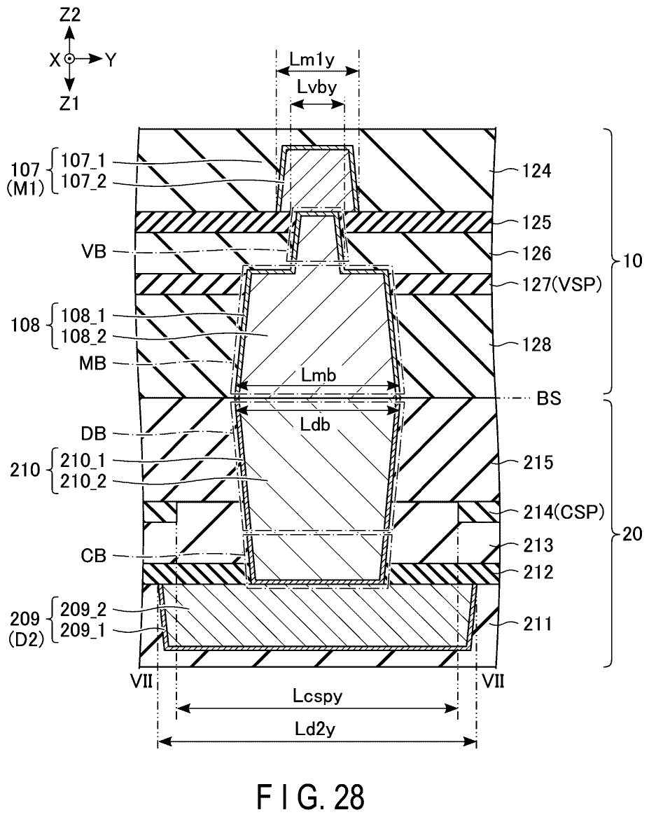

First, the structure of the bonding pad BP will be described with reference to FIGS. 25 to 28. FIG. 25 is a view showing an example of a plan view of the electrode 108 and the M1 interconnect layer 107 and a plan view of the insulating layer 127. FIG. 26 is a view showing an example of a plan view of the electrode 210 and the D2 interconnect layer 209 and a plan view of the insulating layer 214. FIG. 27 is a cross-sectional view taken along line VI-VI in FIGS. 25 and 26. FIG. 28 is a cross-sectional view taken along line VII-VII in FIGS. 25 and 26.

It is noted that insulating layers are omitted in the plan view showing the electrode 108 and the M1 interconnect layer 107 in FIG. 25 and in the plan view showing the electrode 210 and the D2 interconnect layer 209 in FIG. 26. In the plan view showing the insulating layer 127 in FIG. 25 and the plan view showing the insulating layer 214 in FIG. 26, other conductors and insulating layers are omitted.

In the present embodiment, the shapes of the contact plug VB, the bonding pad MB, the bonding pad DB, and the contact plug CB are similar to those shown in FIG. 8 of the first embodiment. The shapes of the opening region ROvsp of the insulating layer 127 and the opening region ROcsp of the insulating layer 214 are different from those in the first embodiment. The description below will focus on the insulating layers 127 and 214.

As shown in FIG. 25, for example, the opening region ROvsp of the insulating layer 127 includes regions Rm1, Rmb1, and Rmb2. In the present embodiment, the length Lvspx of the region Rm1 in the X direction is different from that of the first embodiment. In the present embodiment, in a plan view seen from the Z direction, the region Rm1 overlaps almost the entire surface of the M1 interconnect layer 107. That is, the size of the upper surface of the M1 interconnect layer 107 and the size of the region Rm1 are approximately the same. The length Lvspx of the region Rm1 in the X direction is approximately equal to the length Lm1x of the M1 interconnect layer 107 in the X direction. For example, the distance in the X direction between the end of the M1 interconnect layer 107 and the end of the region Rm1 of the opening region ROvsp of the insulating layer 127 is 200 nm or less. More specifically, for example, it is preferable that the length Lvspx be equal to a length obtained by subtracting a photolithography alignment margin corresponding to the processing of the opening region ROvsp of the insulating layer 127 from the length Lm1x. This prevents the region Rm1 from deviating in the X direction from the M1 interconnect layer 107, in a plan view seen from the Z direction.

By making the length Lvspx of the region Rm1 in the X direction approximately equal to the length Lm1x of the M1 interconnect layer 107 in the X direction, the length in the X direction of the contact plug VB formed by self-alignment does not vary even if the position of the electrode 108 (bonding pad MB) is shifted in the X direction. The length Lvbx in the X direction of the upper surface of the contact plug VB is approximately equal to the length Lmb of the upper surface of the bonding pad MB.

In the present embodiment, in order to correct the position deviation in the X direction between the bonding pad MB and the bonding pad DB, the arrangement of the electrode 108 can be shifted in the X direction, without shifting the region Rm1 of the opening region ROvsp with respect to the M1 interconnect layer 107, which extends in the X-direction. This enables correction of the position deviation in the X direction between the bonding pad MB and the bonding pad DB.

As shown in FIG. 26, for example, the opening region ROcsp of the insulating layer 214 includes regions Rd2, Rdb1, and Rdb2. In the present embodiment, the length Lcspy of the region Rd2 in the Y direction differs from that in the first embodiment. In the present embodiment, in a plan view seen from the Z direction, the region Rd2 overlaps almost the entire surface of the D2 interconnect layer 209. That is, the size of the upper surface of the D2 interconnect layer 209 and the size of the region Rd2 are approximately the same. The length Lcspy of the region Rd2 in the Y direction is approximately equal to the length Ld2y of the D2 interconnect layer 209 in the Y direction. For example, the distance in the Y direction between the end of the D2 interconnect layer 209 and the end of the region Rd2 of the opening region ROcsp of the insulating layer 214 is 200 nm or less. More specifically, for example, it is preferable that the length Lcspy be equal to a length obtained by subtracting the photolithography alignment margin corresponding to the processing of the opening region ROcsp of the insulating layer 214 from the length Ld2y. This prevents the region Rd2 from deviating in the Y direction from the D2 interconnect layer 209, in a plan view seen from the Z direction.

By making the length Lcspy of the region Rd2 in the Y direction approximately equal to the length Ld2y of the D2 interconnect layer 209 in the Y direction, the length in the Y direction of the contact plug CB formed by self-alignment does not vary even if the position of the electrode 210 (bonding pad DB) is shifted in the Y direction. The length Lcby of the upper surface of the contact plug CB in the Y direction is approximately equal to the length Ldb of the upper surface of the bonding pad DB.

In the present embodiment, in order to correct the position deviation in the Y direction between the bonding pad MB and the bonding pad DB, the arrangement of the electrode 210 can be shifted in the Y direction, without shifting the region Rd2 of the opening region ROcsp with respect to the D2 interconnect layer 209, which extends in the Y direction. This enables correction of the position deviation in the Y direction between the bonding pad MB and the bonding pad DB.

As shown in FIGS. 27 and 28, the shapes of the electrodes 108 and 210, that is, the shapes of the bonding pads MB and DB, are similar to those described in the first embodiment with reference to FIGS. 11 and 12. In the present embodiment, the length Lvspx of the opening region ROvsp of the insulating layer 127 in the X direction and the length Lcspy of the opening region ROcsp of the insulating layer 214 in the Y direction are longer than the lengths Lvspx and Lcspy described in the first embodiment.

### 2.2 Manufacturing Method of Electrode

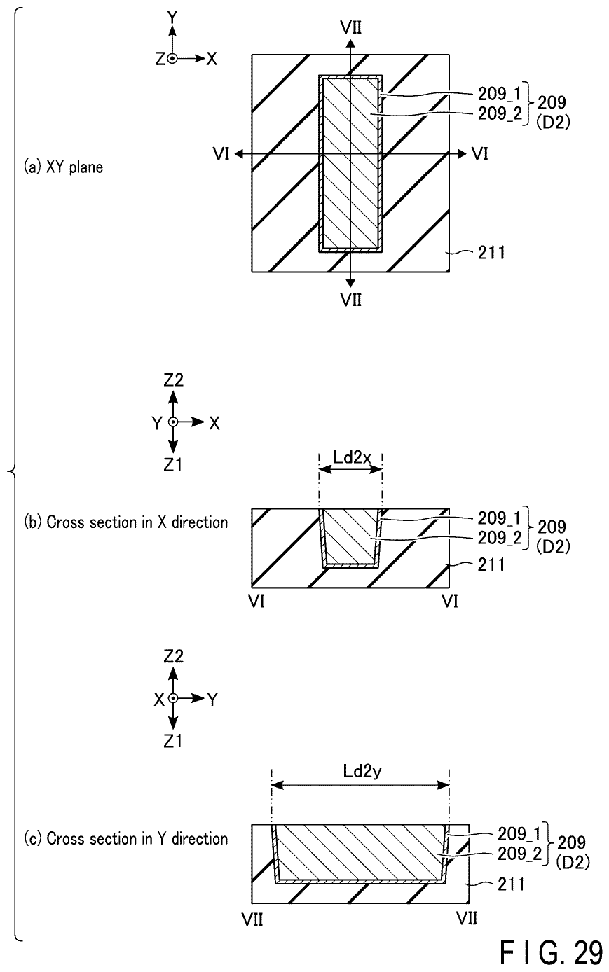

Next, an example of a manufacturing method of the electrode 210 will be described with reference to FIGS. 29 to 34. FIGS. 29 to 34 are diagrams illustrating manufacturing processes of the electrode 210. In each of FIGS. 29 to 34, (a) an XY plane, (b) a cross section in the X direction, and (c) a cross section in the Y direction are shown. The manufacturing method of the electrode 108 is similar to the manufacturing method of the electrode 210.

As shown in FIG. 29, an insulating layer 211 is first formed above a semiconductor substrate 201 (not shown), as described with reference to FIG. 19 of the first embodiment. Then, a D2 interconnect layer 209 is formed.

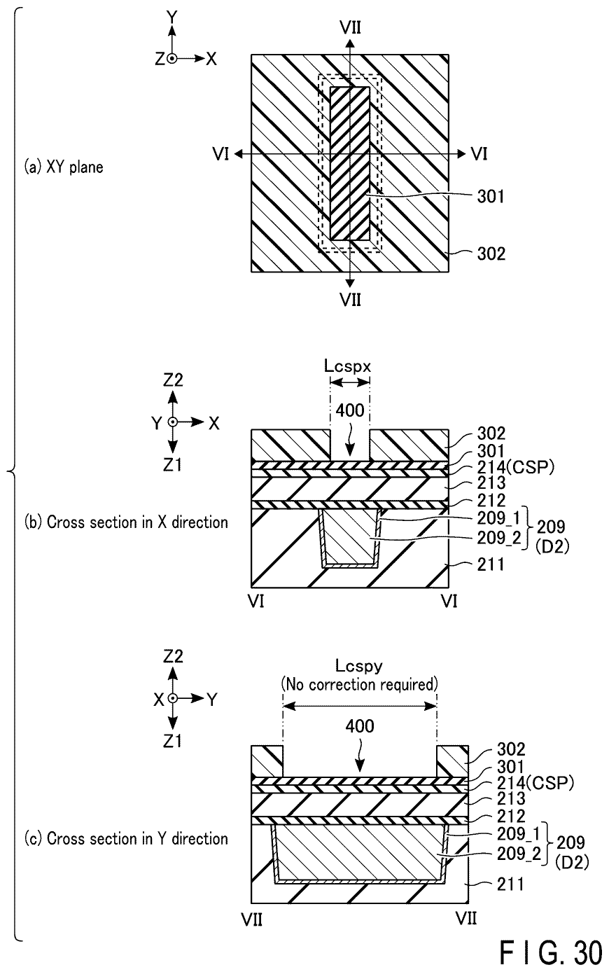

As shown in FIG. 30, an insulating layer 212 is deposited on the insulating layer 211 and the D2 interconnect layer 209, as described with reference to FIG. 20 of the first embodiment. An insulating layer 213 and an insulating layer 214 (an etching stopper CSP) are deposited on the insulating layer 212 in this order. Next, an opening pattern 400 of a resist 302 corresponding to a region Rd2 is formed above the D2 interconnect layer 209 by photolithography. The pattern 400 has a substantially rectangular shape with a length Lcspx in the X direction and a length Lcspy in the Y direction. In the present embodiment, the pattern 400 is not shifted in the Y direction from the reference position (the design position in a state where no position deviation occurs).

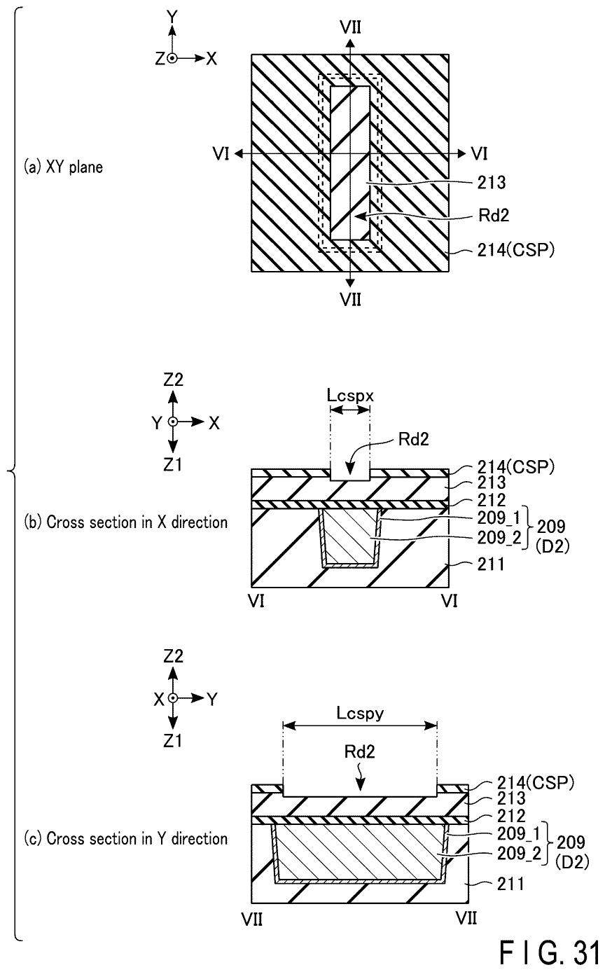

As shown in FIG. 31, similarly to the description using FIG. 21 of the first embodiment, the insulating layer 214 is processed using the resist 302 as a mask. As a result, the region Rd2 of the opening region ROcsp is formed. After the insulating layer 214 is processed, the resist 302 and the member 301 are removed.

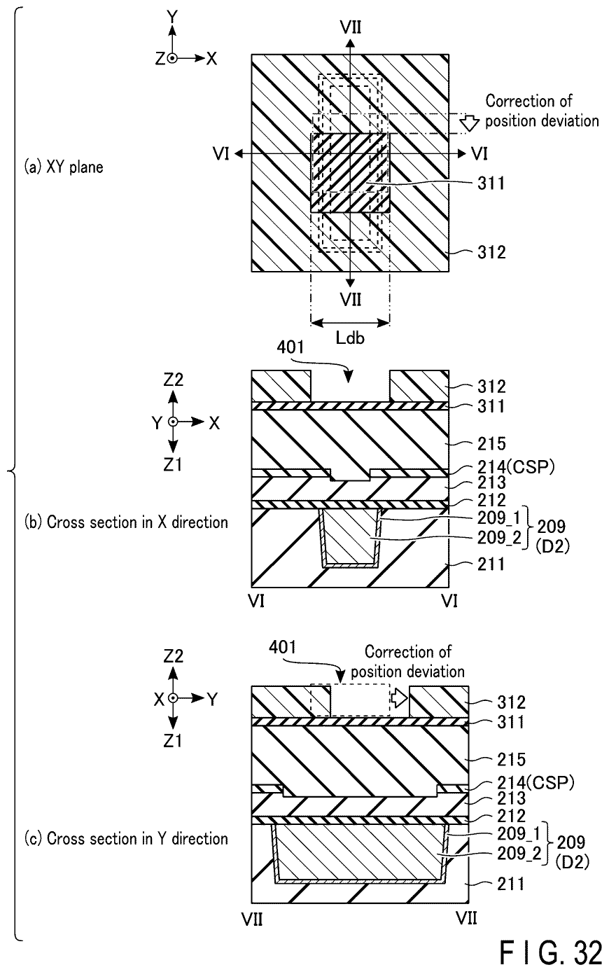

As shown in FIG. 32, similarly to the description using FIG. 22 of the first embodiment, an insulating layer 215 is deposited on the insulating layers 213 and 214. Next, an opening pattern 401 of a resist 312 corresponding to the bonding pad DB is formed above the region Rd2 of the opening region ROcsp by photolithography. The pattern 401 has a substantially square shape with a side length of Ldb. In order to correct the position deviation in the Y direction between the bonding pad MB and the bonding pad DB, the pattern 401 may be shifted in the Y direction with respect to the reference position.

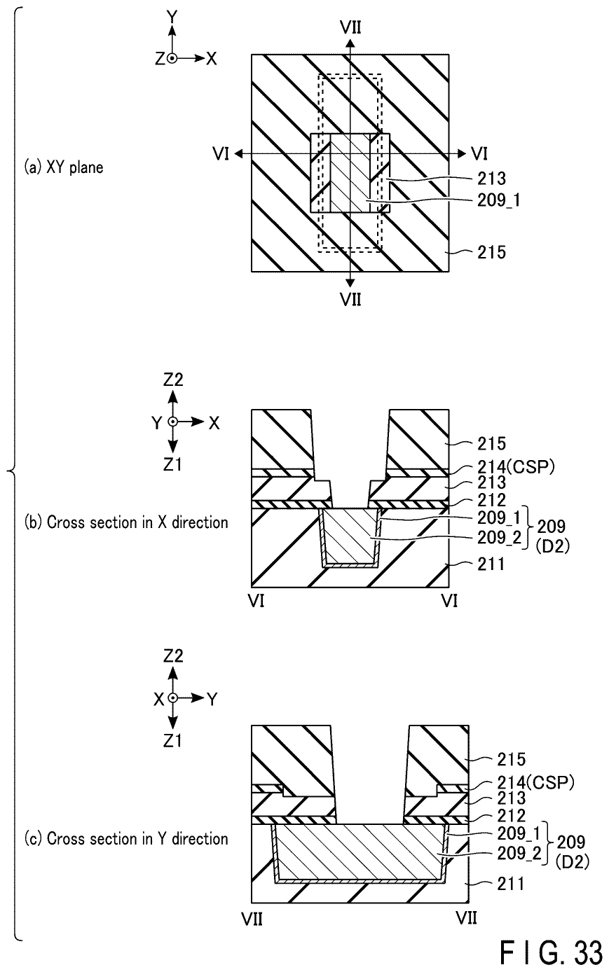

As shown in FIG. 33, similarly to the description using FIG. 23 of the first embodiment, the insulating layers 213 to 215 are processed using the resist 312 as a mask to form a hole pattern of the electrode 210. That is, hole patterns corresponding to the bonding pad DB and the contact plug CB are formed together. At this time, the opening region ROcsp of the insulating layer 214 has such a shape as described with reference to FIG. 26.

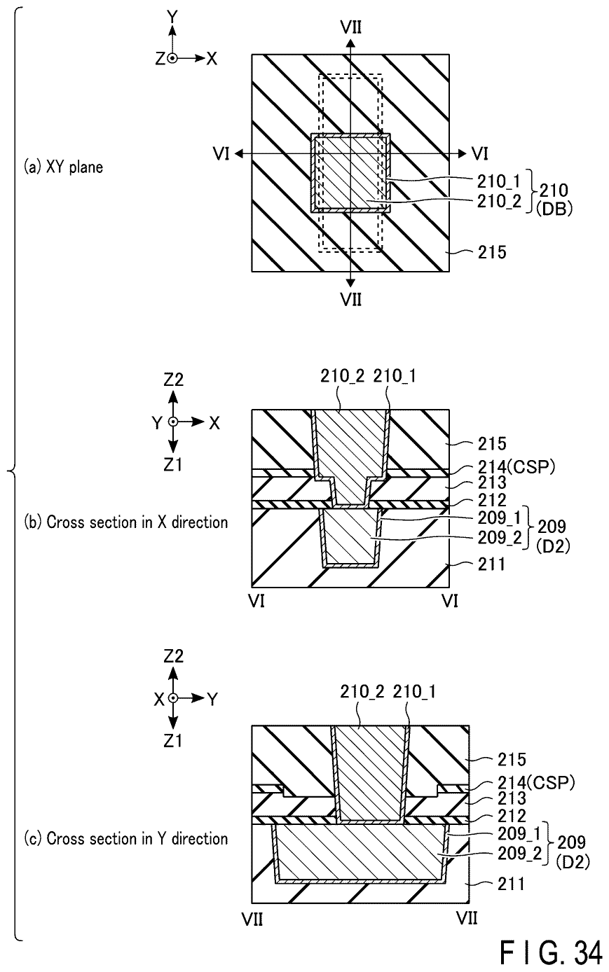

As shown in FIG. 34, similarly to the description using FIG. 24 of the first embodiment, an electrode 210 (the bonding pad DB and the contact plug CB) is formed.

### 2.3 Advantages of Present Embodiment

In the configuration according to the present embodiment, the advantages similar to those of the first embodiment can be obtained. More specifically, the semiconductor device 1 can make the size of the upper surface of the M1 interconnect layer 107 and the size of the region Rm1 approximately the same. Thus, the semiconductor device 1 can shift the arrangement of the electrode 108 in the X direction, without shifting the region Rm1 of the opening region ROvsp with respect to the M1 interconnect layer 107, which extends in the X direction. As a result, the semiconductor device 1 can correct the position deviation in the X direction between the bonding pad MB and the bonding pad DB. In addition, the semiconductor device 1 can make the size of the upper surface of the D2 interconnect layer 209 and the size of the region Rd2 approximately the same. As a result, the semiconductor device 1 can shift the arrangement of the electrode 210 in the Y direction, without shifting the region Rd2 of the opening region ROcsp with respect to the D2 interconnect layer 209, which extends in the Y direction. Thus, the semiconductor device 1 can correct the position deviation in the Y direction between the bonding pad MB and the bonding pad DB.

Furthermore, in the configuration according to the present embodiment, the semiconductor device 1 does not exhibit variation in the length in the X direction of the contact plug VB formed by self-alignment, as in the first embodiment. That is, the semiconductor device 1 can make the resistance value of the contact plug VB approximately constant. Furthermore, in the semiconductor device 1, the contact plug CB formed by self-alignment does not vary in the length in the Y direction. That is, the semiconductor device 1 can make the resistance value of the contact plug CB approximately constant. Therefore, the yield of the semiconductor device 1 can be improved.

### 3. Third Embodiment

Next, the third embodiment will be described. In the third embodiment, the shape of the bonding pad BP and the dual damascene method that are different from those in the first and second embodiments, will be described. The description below will focus on the differences from the first and second embodiments.

### 3.1 Cross-Sectional Structure of Semiconductor Device

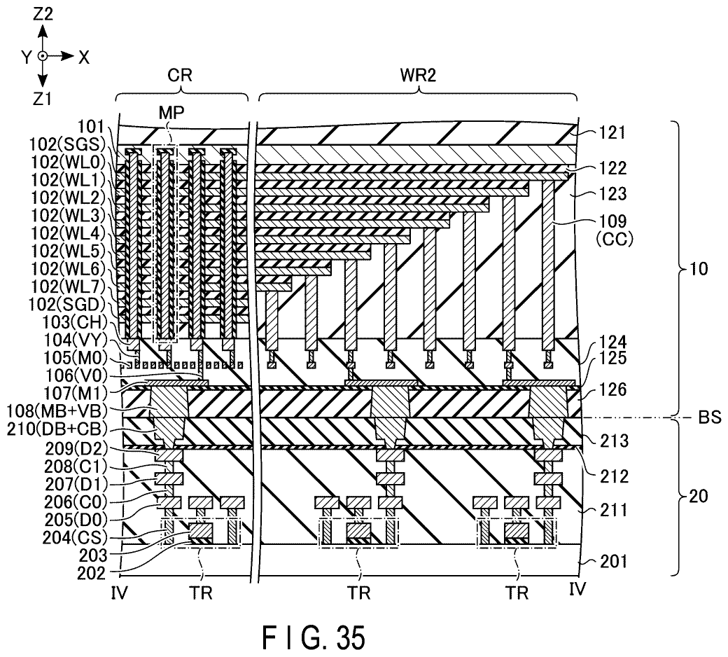

First, an example of the cross-sectional structure of the semiconductor device 1 will be described with reference to FIG. 35. FIG. 35 is a cross-sectional view taken along the line IV-IV in FIG. 4 showing an example of the cross-sectional structure of the semiconductor device 1 according to the third embodiment.

As shown in FIG. 35, the semiconductor device 1 of the present embodiment has a structure in which the insulating layers 127 and 128 of the array chip 10 and the insulating layers 214 and 215 of the circuit chip 20 are omitted from the semiconductor device 1 shown in FIG. 5 of the first embodiment. That is, in the present embodiment, the insulating layer 127 functioning as the etching stopper VSP and the insulating layer 214 functioning as the etching stopper CSP are omitted.

An electrode 108 is provided in an insulating layer 126. An electrode 210 is provided in an insulating layer 213. The length of the electrode 108 in the X direction is longer than the length of the electrode 210 in the X direction. Furthermore, the length of the electrode 210 in the Y direction, described later, is longer than the length of the electrode 108 in the Y direction.

The surface where the insulating layer 126 and the insulating layer 213 are in contact with each other is the bonding surface BS. The other configurations are similar to those shown in FIG. 5 of the first embodiment.

### 3.2 Structure of Bonding Pad

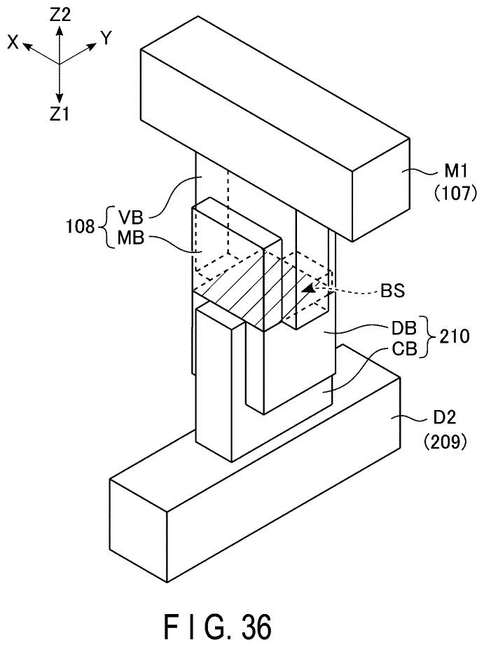

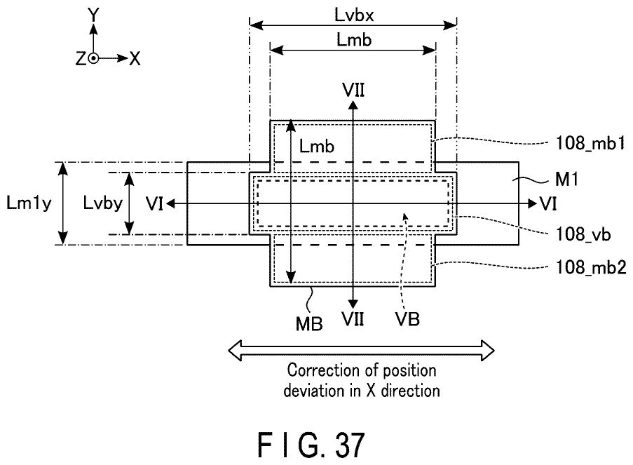

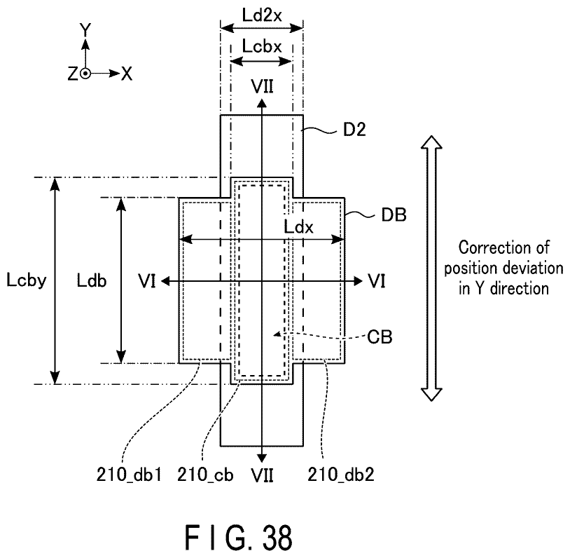

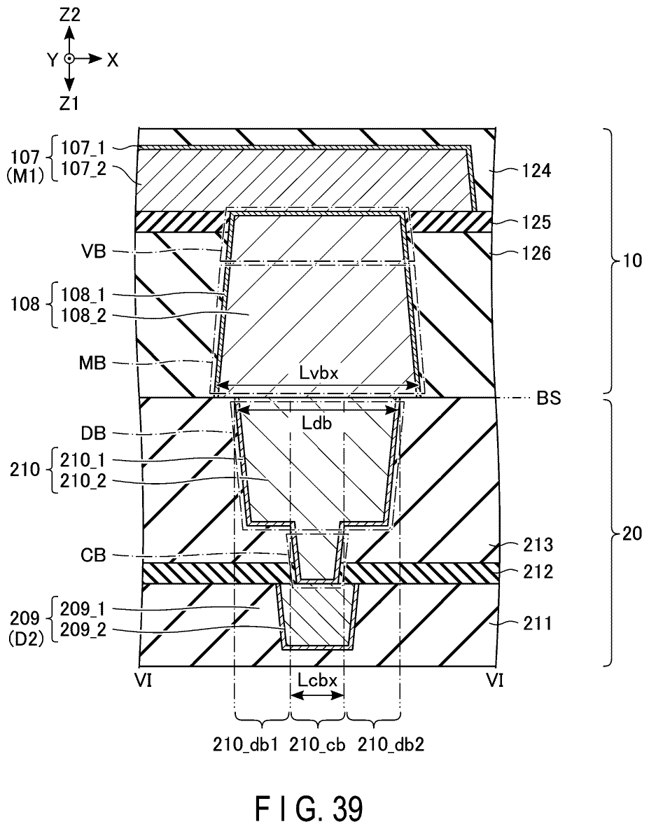

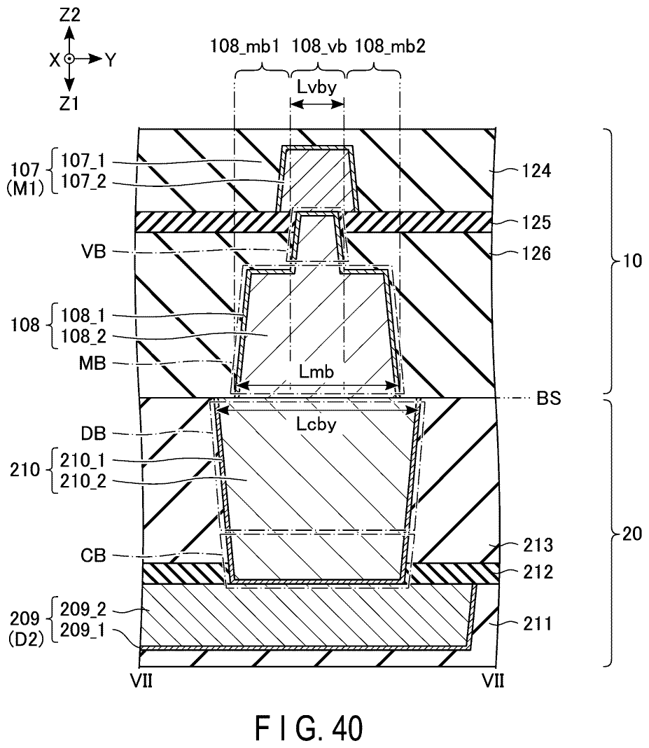

First, the structure of the bonding pad BP will be described with reference to FIGS. 36 to 40. FIG. 36 is a perspective view showing an example of the structure of an M1 interconnect layer 107, electrodes 108 and 210, and a D2 interconnect layer 209. FIG. 37 is a view showing an example of a plan view of the electrode 108 and the M1 interconnect layer 107. FIG. 38 is a view showing an example of a plan view of the electrode 210 and the D2 interconnect layer 209. FIG. 39 is a cross-sectional view taken along line VI-VI in FIGS. 37 and 38. FIG. 40 is a cross-sectional view taken along line VII-VII in FIGS. 37 and 38.

It is noted that illustration of insulating layers is omitted in FIGS. 36 to 38. In FIG. 36, the contact surface between the bonding pad MB and the bonding pad DB is indicated by hatching to enhance visibility.

As shown in FIG. 36, the electrode 108 of the present embodiment differs from the electrode 108 shown in FIG. 8 of the first embodiment in that a portion of the electrode 108 located on the M1 interlayer layer 107 extends (protrudes) in the X direction.

The electrode 210 of the present embodiment differs from the electrode 210 shown in FIG. 8 of the first embodiment in that a portion of the electrode 210 located on the D2 interconnect layer 209 extends (protrudes) in the Y direction.

For example, in a case where there is no position deviation between the bonding pad MB and the bonding pad DB, and where the length Lmb of the upper surface of the bonding pad MB in the Y direction and the length Ldb of the upper surface of the bonding pad DB in the X direction are approximately equal, the shape of the contact surface between the bonding pad MB and the bonding pad DB is approximately square, as in the case shown in FIG. 8.

As shown in FIG. 37, the electrode 108 includes a first portion 108_vb, a second portion 108_mb1, and a third portion 108_mb2.

In the present embodiment, the electrode 108 is processed using a dual damascene method in which a hole pattern corresponding to a contact plug VB is processed first, and then a hole pattern corresponding to the bonding pad MB is processed. The electrode 108 may be processed using a dual damascene method in which the hole pattern corresponding to the bonding pad MB is processed first, and then the hole pattern corresponding to the contact plug VB is processed.

The first portion 108_vb is a region where the insulating layer 126 is processed when the hole pattern corresponding to the contact plug VB is processed. The second portion 108_mb1 and the third portion 108_mb2 are regions where the insulating layer 126 is processed when the hole pattern corresponding to the bonding pad MB is processed.

The first portion 108_vb overlaps the M1 interconnect layer 107 in a plan view seen from the Z direction. The first portion 108_vb has a substantially rectangular shape that is longer in the X direction than in the Y direction. The first portion 108_vb includes the contact plug VB and a first sub-portion of the bonding pad MB located on the contact plug VB.

The second portion 108_mb1 is in contact with one side surface facing the Y direction of the first portion 108_vb. The second portion 108_mb1 has a substantially rectangular shape that is longer in the X direction than in the Y direction. The second portion 108_mb1 includes a second sub-portion of the bonding pad MB and does not include the contact plug VB.

The third portion 108_mb2 is in contact with the other side surface facing the Y direction of the first portion 108_vb. The first portion 108_vb is provided between the second portion 108_mb1 and the third portion 108_mb2 in the Y direction. That is, the second portion 108_mb1 and the third portion 108_mb2 are adjacent to each other in the Y direction, with the first portion 108_vb interposed therebetween. The third portion 108_mb2 has a substantially rectangular shape that is longer in the X direction than in the Y direction. The third portion 108_mb2 includes a third sub-portion of the bonding pad MB and does not include the contact plug VB.

The length of the first portion 108_vb in the X direction is approximately equal to the length Lvbx of the upper surface of the contact plug VB in the X direction. The length of the first portion 108_vb in the Y direction is approximately equal to the length Lvby of the upper surface of the contact plug VB in the Y direction. The length Lvbx of the first portion 108_vb in the X direction is longer than the length Lmb of the second portion 108_mb1 and the third portion 108_mb2 in the same direction.

In a plan view seen from the Z direction, the first portion 108_vb includes a central region interposed between the second portion 108_mb1 and the third portion 108_mb2, and two protruding regions that protrude in the X direction from the respective ends of the second portion 108_mb1 and the third portion 108_mb2 in the X direction. That is, the central region is provided between the two protruding regions. For example, in a plan view seen from the Z direction, the shape of the combination of the central region of the first portion 108_vb, the second portion 108_mb1, and the third portion 108_mb2 is substantially a square. In this case, the length in the Y direction of the combination of the central region of the first portion 108_vb, the second portion 108_mb1, and the third portion 108_mb2 is approximately equal to the length Lmb of the second portion 108_mb1 and the third portion 108_mb2 in the X direction. This length is also the length Lmb of the upper surface of the electrode 108 in the Y direction. The protruding regions of the first portion 108_vb are portions that are not in contact with the electrode 210. In a case where there is no position deviation between the electrode 108 and the electrode 210, the upper surfaces of the central region of the first portion 108_vb, the second portion 108_mb1, and the third portion 108_mb2 are in contact with the electrode 210. For example, it is preferable that the difference between the length Lvbx and the length Lmb be equal to or longer than the misalignment amount between the photolithography corresponding to the processing of the contact plug VB and the photolithography corresponding to the processing of the bonding pad MB. Thus, even if a misalignment occurs between the first portion 108_vb (the contact plug VB) and the second portion 108_mb1 and the third portion 108_mb2 (the bonding pad MB), the length Lvbx of the upper surface of the contact plug VB in the X direction does not change.

In the present embodiment, in order to correct the position deviation in the X direction between the bonding pad MB and the bonding pad DB, the arrangements of the contact plug VB and the bonding pad MB can be shifted in the X direction with respect to the M1 interconnect layer 107, which extends in the X direction. By shifting the contact plug VB and the bonding pad MB in the X direction, the position deviation in the X direction between the bonding pad MB and the bonding pad DB can be corrected.

As shown in FIG. 38, the electrode 210 includes a first portion 210_cb, a second portion 210_db, and a third portion 210_db2.

In the present embodiment, the electrode 210 is processed using a dual damascene method in which a hole pattern corresponding to the contact plug CB is processed first, and then a hole pattern corresponding to the bonding pad DB is processed. The electrode 210 may be processed using a dual damascene method in which the hole pattern corresponding to the bonding pad DB is processed first, and then the hole pattern corresponding to the contact plug CB is processed.

The first portion 210_cb is a region where the insulating layer 213 is processed when the hole pattern corresponding to the contact plug CB is processed. The second portion 210_db1 and the third portion 210_db2 are regions where the insulating layer 213 is processed when the hole pattern corresponding to the bonding pad DB is processed.

The first portion 210_cb overlaps the D2 interconnect layer 209 in a plan view seen from the Z direction. The first portion 210_cb has a substantially rectangular shape that is longer in the Y direction than in the X direction. The first portion 210_cb includes the contact plug CB and a first sub-portion of the bonding pad DB located on the contact plug CB.

The second portion 210_db1 is in contact with one side surface facing the X direction of the first portion 210_cb. The second portion 210_db1 has a substantially rectangular shape that is longer in the Y direction than in the X direction. The second portion 210_db1 includes a second sub-portion of the bonding pad DB and does not include the contact plug CB.

The third portion 210_db2 is in contact with the other side surface facing the X direction of the first portion 210_cb. The first portion 210_cb is provided between the second portion 210_db1 and the third portion 210_db2 in the X direction. That is, the second portion 210_db1 and the third portion 210_db2 are adjacent to each other in the X direction, with the first portion 210_cb interposed therebetween. The third portion 210_db2 has a substantially rectangular shape that is longer in the Y direction than in the X direction. The third portion 210_db2 includes a third sub-portion of the bonding pad DB and does not include the contact plug CB.

The length of the first portion 210_cd in the X direction is approximately equal to the length Lcbx of the upper surface of the contact plug CB in the X direction. The length of the first portion 210_cb in the Y direction is approximately equal to the length Lcby of the upper surface of the contact plug CB in the Y direction. The length Lcby of the first portion 210_cb in the Y direction is longer than the length Ldb of the second portion 210_db1 and the third portion 210_db2 in the Y direction.

In a plan view seen from the Z direction, the first portion 210_cb includes a central region interposed between the second portion 210_db1 and the third portion 210_db2, and two protruding regions that extend in the Y direction from the respective ends of the second portion 210_db1 and the third portion 210_db2 in the Y direction. That is, the central region is provided between the two protruding regions. For example, in a plan view seen from the Z direction, the shape of the combination of the central region of the first portion 210_cb, the second portion 210_db1, and third portion 210_db2 is substantially a square. In this case, the length in the X direction of the combination of the central region of the first portion 210_cb, the second portion 210_db1, and the third portion 210_db2 is approximately equal to the length Ldb of the second portion 210_db1 and the third portion 210_db2 in the Y direction. This length is also the length Ldb of the upper surface of the electrode 210 in the X direction. The protruding regions of the first portion 210_cb are portions that are not in contact with the electrode 108. In a case where there is no position deviation between the electrode 108 and the electrode 210, the upper surfaces of the central region of the first portion 210_cb, the second portion 210_db1, and the third portion 210_db2 are in contact with the electrode 108. For example, it is preferable that the difference between the length Lcby and the length Ldb be equal to or longer than the misalignment amount between the photolithography corresponding to the processing of the contact plug CB and the photolithography corresponding to the processing of the bonding pad DB. Thus, even if a misalignment occurs between the first portion 210_cb (the contact plug CB) and the second portion 210_db1 and the third portion 210_db2 (the bonding pad DB), the length Lcby of the contact plug CB in the Y direction does not change.

In the present embodiment, in order to correct the position deviation in the Y direction between the bonding pad MB and the bonding pad DB, the arrangements of the contact plug CB and the bonding pad DB can be shifted in the Y direction with respect to the D2 interconnect layer 209, which extends in the Y direction. By shifting the contact plug CB and the bonding pad DB in the Y direction, the position deviation in the Y direction between the bonding pad MB and the bonding pad DB can be corrected.

Next, the cross-sectional shapes of the bonding pads MB and DB will be described.

As shown in FIG. 39, for example, the cross section taken along the X direction of the first portion 108_vb of the electrode 108 has a trapezoidal shape, in which the length Lvbx in the X direction of the upper surface facing the Z1 direction of the first portion 108_vb of the electrode 108 is longer than the length, in the X direction, of the lower surface facing the Z2 direction that is in contact with the M1 interconnect layer 107. The length Lvbx of the upper surface of the first portion 108_vb in the X direction is longer than the length Ldb of the upper surface of the bonding pad DB in the X direction. In the first portion 108_vb, the surface facing the X direction of the contact plug VB is provided in the same plane as the surface facing the X direction of the bonding pad MB.

The cross section taken along the X direction of the electrode 210 is similar to that shown in FIG. 11 of the first embodiment. The length of the first portion 210_cb in the Z direction is longer than the length of the second portion 210_db1 and the third portion 210_db2 in the Z direction.

As shown in FIG. 40, for example, the cross section taken along the Y direction of the first portion 210_cb of the electrode 210 has a trapezoidal shape, in which the length Lcby in the Y direction of the upper surface facing the Z2 direction of the first portion 210_cb of the electrode 210 is longer than the length, in the Y direction, of the lower surface facing the Z1 direction that is in contact with the D2 interconnect layer 209. The length Lcby of the upper surface of the first portion 210_cb in the Y direction is longer than the length Lmb of the upper surface of the bonding pad MB in the Y direction. In the first portion 210_cb, the surface facing the Y direction of the contact plug CB is provided in the same plane as the surface facing the Y direction of the bonding pad DB.

The cross section taken along the Y direction of the electrode 108 is similar to that shown FIG. 12 of the first embodiment. The length of the first portion 108_vb in the Z direction is longer than the respective lengths of the second portion 108_mb1 and the third portion 108_mb2 in the Z direction.

In the bonding pads MB and DB according to the present embodiment, the barrier metal 108_1 and the barrier metal 210_1 are discontinuous at the bonding position, so that the bonding can be identified.

### 3.3. Manufacturing Method of Electrode

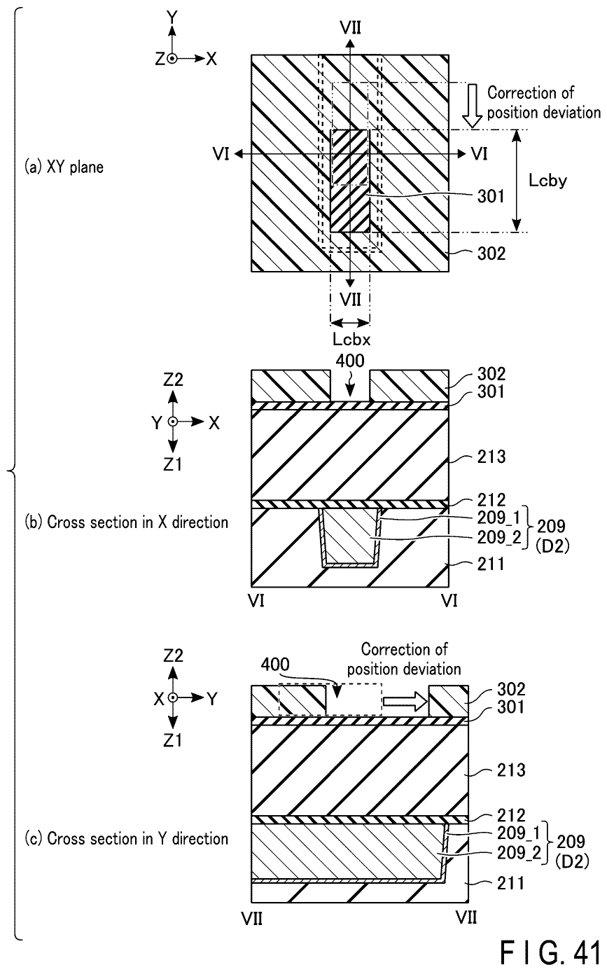

Next, an example of a manufacturing method of the electrode 210 will be described with reference to FIGS. 41 to 45. FIG. 41 to FIG. 45 are diagrams illustrating manufacturing processes of the electrode 210. In each of FIGS. 41 to 45, (a) an XY plane, (b) a cross section in the X direction, and (c) a cross section in the Y direction are shown. The manufacturing method of the electrode 108 is similar to the manufacturing method of the electrode 210.

As shown in FIG. 41, an insulating layer 211 is first formed above a semiconductor substrate 201 (not shown). Next, a D2 interconnect layer 209 is formed in the same manner as described with reference to FIG. 19 of the first embodiment. Next, an insulating layer 212 is deposited on the insulating layer 211 and the D2 interconnect layer 209. An insulating layer 213 is deposited on the insulating layer 212. Next, an opening pattern 400 of a resist 302 corresponding to the contact plug CB (the first portion 210_cb of the electrode 210) is formed above the D2 interconnect layer 209 by photolithography. More specifically, a member 301 is first formed on the insulating layer 213. The resist 302 is coated onto the member 301, and then a pattern 400 is formed by photolithography. In order to correct the position deviation in the Y direction between the bonding pad MB and the bonding pad DB, the pattern 400 may be shifted in the Y direction from the reference position (the design position in a state where no position deviation occurs).

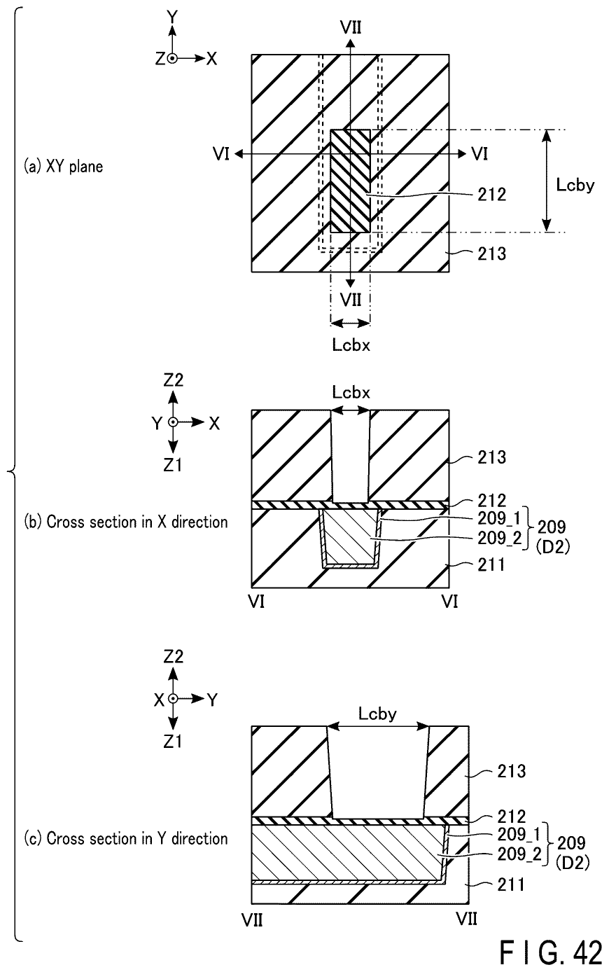

As shown in FIG. 42, the insulating layer 213 is processed using the resist 302 as a mask. Thus, a hole pattern of the contact plug CB is formed. After the insulating layer 213 is processed, the resist 302 and the member 301 are removed.

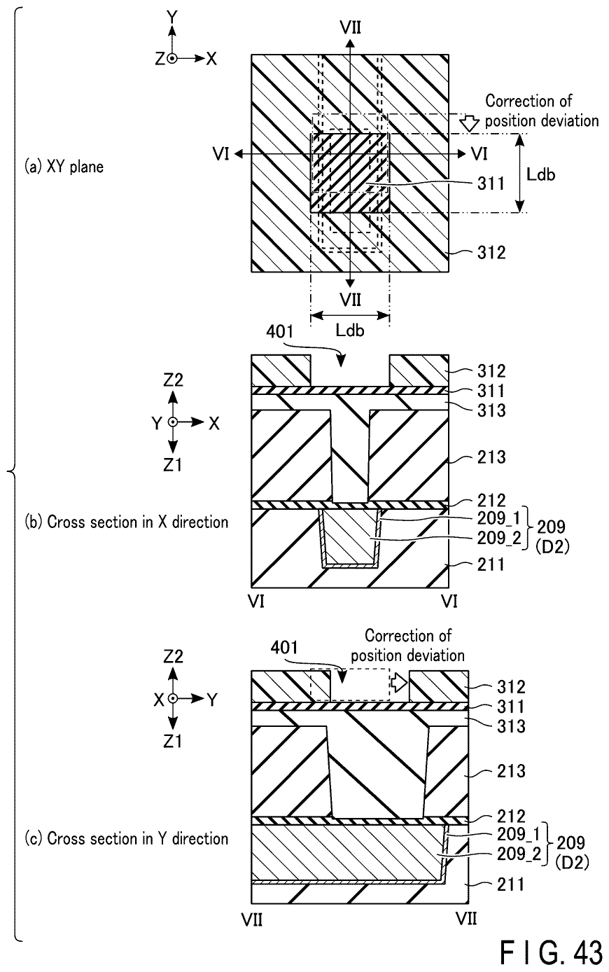

As shown in FIG. 43, a sacrificial material 313 is embedded in the hole pattern of the contact plug CB. Next, an opening pattern 401 of a resist 312 corresponding to the bonding pad DB is formed by photolithography. The pattern 401 has a substantially square shape with a side length of Ldb. More specifically, a member 311 is first formed on the sacrificial material 313. After the resist 312 is coated onto the member 311, the pattern 401 is formed by photolithography. In a case where the pattern 400 is shifted in the Y direction, the pattern 401 is shifted in the Y direction in the same manner as the pattern 400.

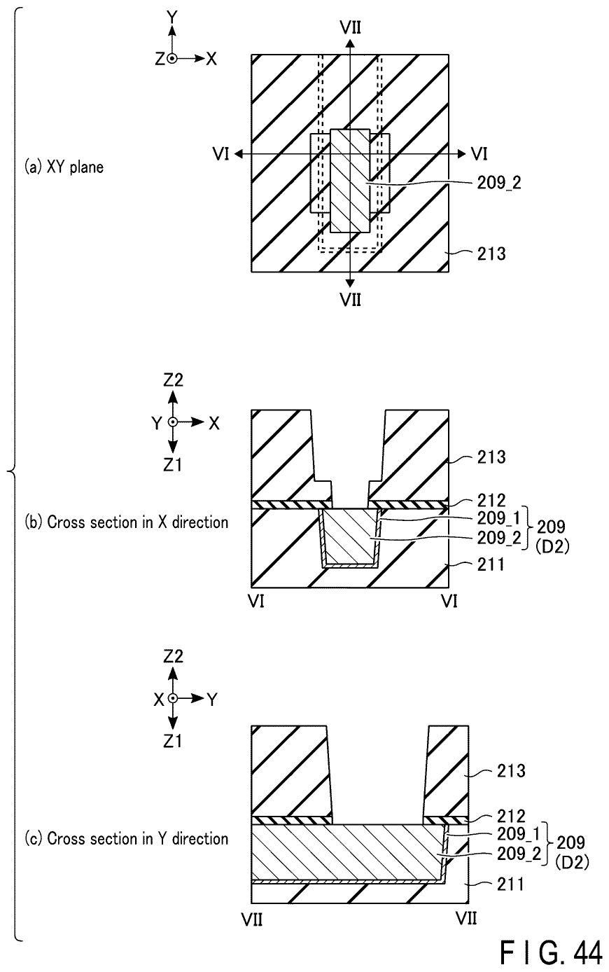

As shown in FIG. 44, the insulating layer 213 is processed using the resist 312 as a mask to form a hole pattern of the bonding pad DB. After removing the resist 312, the member 311, and the sacrificial material 313, the exposed insulating layer 212 is removed. In this manner, a hole pattern of the electrode 210 is formed.

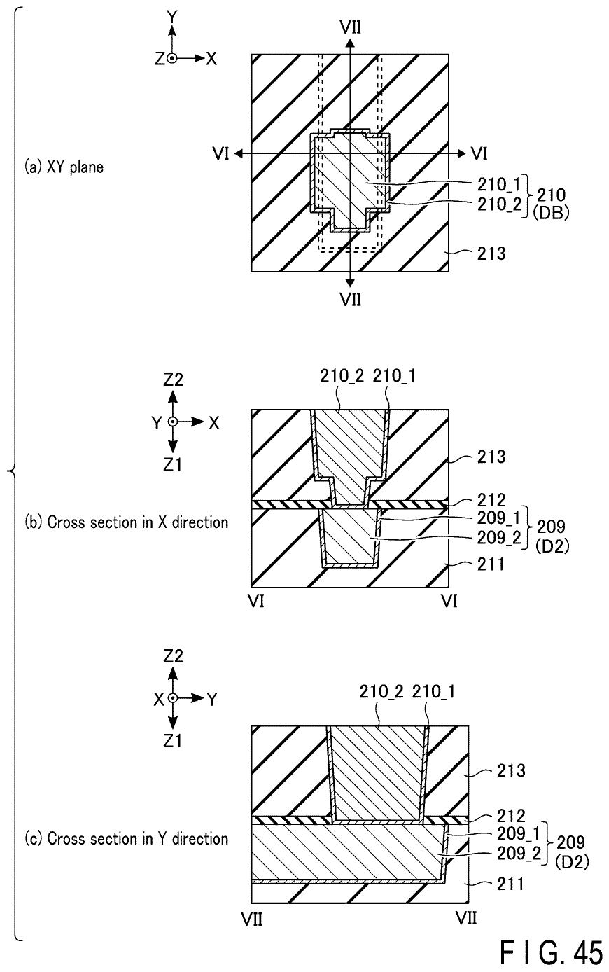

As shown in FIG. 45, similarly to the description using FIG. 24 of the first embodiment, the electrode 210 (the bonding pad DB and the contact plug CB) is formed.

### 3.4 Advantages of Present Embodiment

In the configuration according to the present embodiment, the advantages similar to those of the first embodiment can be obtained. More specifically, in order to correct the position deviation in the X direction between the bonding pad MB and the bonding pad DB, the semiconductor device 1 can shift the arrangements of the contact plug VB and the bonding pad MB in the X direction with respect to the M1 interconnect layer 107, which extends in the X direction. By shifting the contact plug VB and the bonding pad MB in the X direction, the semiconductor device 1 can correct the position deviation in the X direction between the bonding pad MB and the bonding pad DB. In addition, in order to correct the position deviation in the Y direction between the bonding pad MB and the bonding pad DB, the semiconductor device 1 can shift the arrangements of the contact plug CB and the bonding pad DB in the Y direction with respect to the D2 interconnect layer 209, which extends in the Y direction. By shifting the contact plug CB and the bonding pad DB in the Y direction, the semiconductor device 1 can correct the position deviation in the Y direction between the bonding pad MB and the bonding pad DB. Thus, the semiconductor device 1 can reduce defective coupling between the bonding pad MB and the bonding pad DB due to the position deviation. Therefore, the yield of the semiconductor device 1 can be improved.

Furthermore, in the configuration according to the present embodiment, the semiconductor device 1 can make the length Lvbx of the first portion 108_vb of the electrode 108 in the X direction longer than the length Lmb of the second portion 108_mb1 and the third portion 108_mb2 in the X direction. That is, the contact plug VB can be formed longer in the X-direction than the hole pattern for processing the bonding pad MB. Thus, even if a misalignment occurs between the contact plug VB and the bonding pad MB, the semiconductor device 1 does not exhibit variation in the length Lvbx of the upper surface of the contact plug VB in the X direction. That is, the semiconductor device 1 can make the resistance value of the contact plug VB approximately constant. By making the resistance value of the contact plug VB approximately constant, the semiconductor device 1 can reduce defective coupling between the M1 interconnect layer 107 and the bonding pad MB. Similarly, the semiconductor device 1 can make the length Lcby of the first portion 210_cb of the electrode 210 in the Y direction longer than the respective length Ldb of the second portion 210_db1 and the third portion 210_db2 in the Y direction. That is, the contact plug CB can be formed longer in the Y direction than the hole pattern for processing the bonding pad DB. Thus, even if a misalignment occurs between the contact plug CB and the bonding pad DB, the semiconductor device 1 does not exhibit variation in the length Lcby of the upper surface of the contact plug CB in the Y direction. That is, the semiconductor device 1 can make the resistance value of the contact plug CB approximately constant. By making the resistance value of the contact plug CB approximately constant, the semiconductor device 1 can reduce defective coupling between the D2 interconnect layer 209 and the bonding pad DB. Therefore, the yield of the semiconductor device 1 can be improved.

Furthermore, in the configuration according to the present embodiment, the semiconductor device 1 can form the contact plug VB to have a long length in the X direction. This enables a reduction in the contact resistance between the M1 interconnect layer 107 and the contact plug VB. Similarly, the semiconductor device 1 can form the contact plug CB to have a long length in the Y direction. This enables a reduction in the contact resistance between the D2 interconnect layer 209 and the contact plug CB.

### 4. Fourth Embodiment

Next, the fourth embodiment will be described. In the fourth embodiment, the shapes of the electrodes 108 and 210, which are different from those in the third embodiment, will be described. The description below will focus on the differences from the third embodiment.

### 4.1 Cross-Sectional Structure of Semiconductor Device

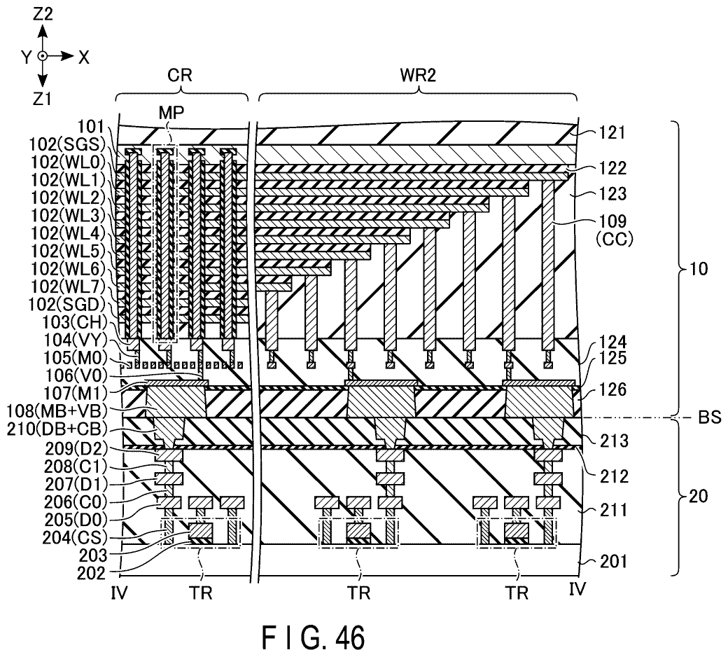

First, an example of the cross-sectional structure of the semiconductor device 1 will be described with reference to FIG. 46. FIG. 46 is a cross-sectional view taken along line IV-IV in FIG. 4 showing an example of the cross-sectional structure of the semiconductor device 1 according to the fourth embodiment.

As shown in FIG. 46, the semiconductor device 1 of the present embodiment has a structure in which the insulating layers 127 and 128 of the array chip 10 and the insulating layers 214 and 215 of the circuit chip 20 are omitted, as in the third embodiment. In the present embodiment, the length of the electrode 108 in the X direction is approximately equal to the length of the M1 interconnect layer 107 in the X direction. The length of the electrode 210 in the Y direction (described later) is approximately equal to the length of the D2 interconnect layer 209 in the Y direction. The other structures are similar to those shown in FIG. 35 of the third embodiment.

### 4.2 Structure of Bonding Pad

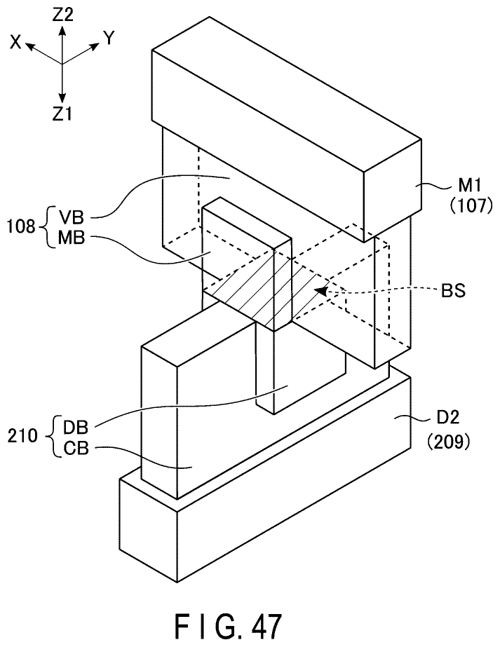

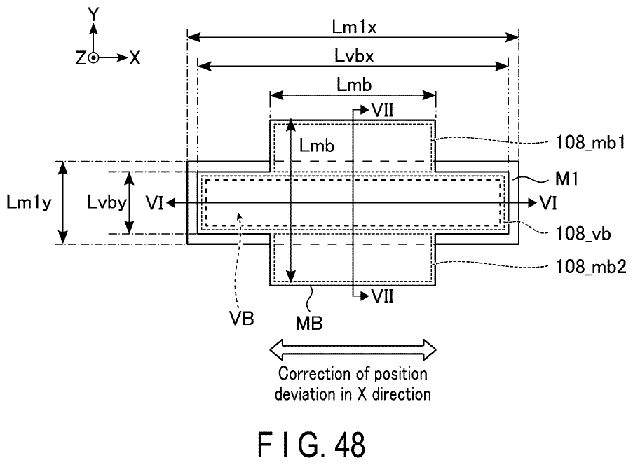

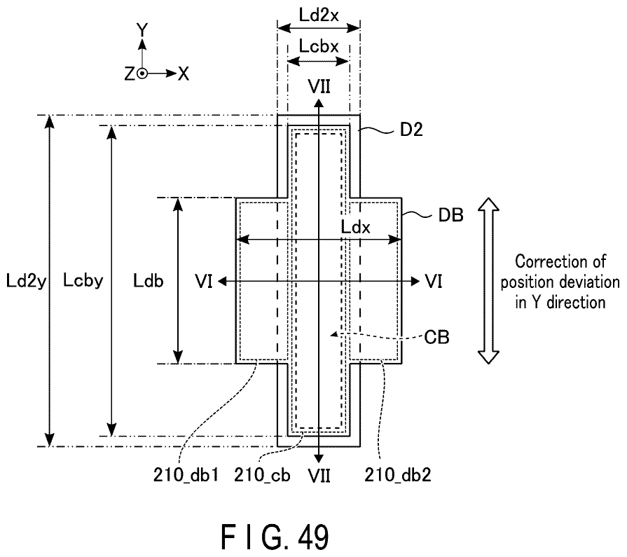

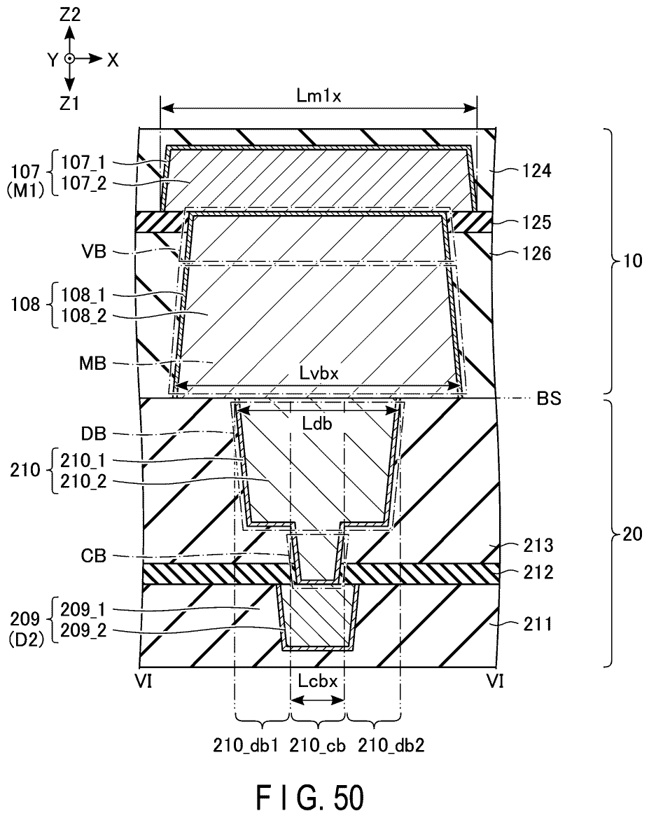

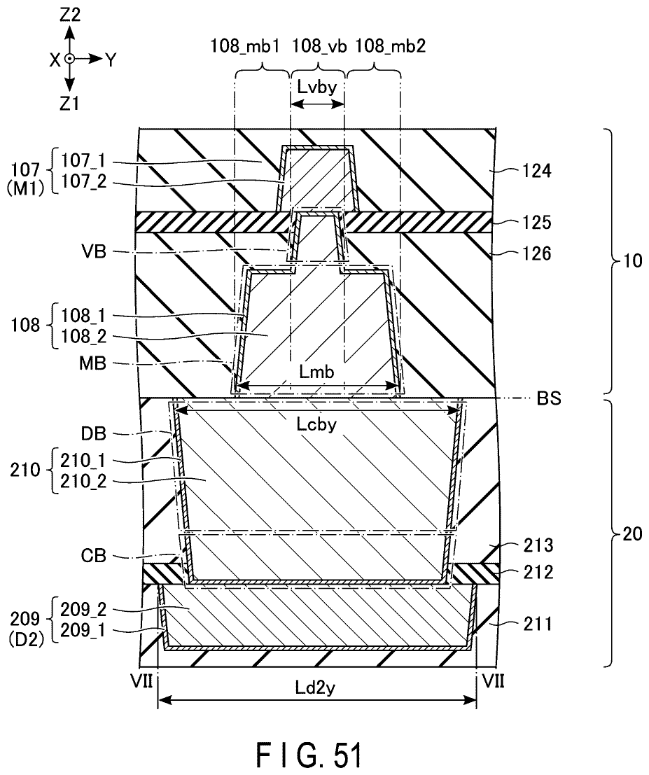

The structure of the bonding pad BP will be described with reference to FIGS. 47 to 51. FIG. 47 is a perspective view showing an example of the structure of the M1 interconnect layer 107, the electrodes 108 and 210, and the D2 interconnect layer 209. FIG. 48 is a view showing an example of a plan view of the electrode 108 and the M1 interconnect layer 107. FIG. 49 is a view showing an example of a plan view of the electrode 210 and the D2 interconnect layer 209. FIG. 50 is a cross-sectional view taken along line VI-VI in FIGS. 48 and 49. FIG. 51 is a cross-sectional view taken along line VII-VII in FIGS. 48 and 49.

It is noted that illustration of insulating layers is omitted in FIGS. 47 to 49. In FIG. 47, the contact surface between the bonding pad MB and the bonding pad DB is indicated by hatching to enhance visibility.

As shown in FIGS. 47 and 48, in the present embodiment, the length Lvbx of the first portion 108_vb of the electrode 108 in the X direction is approximately equal to the length Lm1x of the M1 interconnect layer 107 in the X direction. That is, the size of the upper surface of the first portion 108_vb is approximately the same as the size of the upper surface of the M1 interconnect layer 107. For example, the distance in the X direction between the end of the M1 interconnect layer 107 and the end of the first portion 108_vb is 200 nm or less. More specifically, it is preferable that the length Lvbx be a length obtained by subtracting the photolithography alignment margin corresponding to the processing of the contact plug VB (first portion 108_vb) from the length Lm1x. The shapes of the second portion 108_mb1 and the third portion 108_mb2 of the electrode 108 are similar to those of the third embodiment.

In the present embodiment, in order to correct the position deviation in the X direction between the bonding pad MB and the bonding pad DB, the arrangement of the bonding pad MB (the second portion 108_mb1 and the third portion 108_mb2 of the electrode 108) can be shifted in the X direction, without shifting the contact plug VB with respect to the M1 interconnect layer 107, which extends in the X direction. This enables correction of the position deviation in the X direction between the bonding pad MB and the bonding pad DB.

As shown in FIGS. 47 and 49, in the present embodiment, the length Lcby of the first portion 210_cb of the electrode 210 in the Y direction is approximately equal to the length Ld2y of the D2 interconnect layer 209 in the Y direction. That is, the size of the upper surface of the first portion 210_cb is approximately the same as the size of the upper surface of the D2 interconnect layer 209. For example, the distance in the Y direction between the end of the D2 interconnect layer 209 and the end of the first portion 210_cb is 200 nm or less. More specifically, it is preferable that the length Lcby be a length obtained by subtracting the photolithography alignment margin corresponding to the processing of the contact plug CB (first portion 210_cb) from the length Ld2y. The shapes of the second portion 210_db1 and the third portion 210_db2 of the electrode 210 are similar to those of the third embodiment.

In the present embodiment, in order to correct the position deviation in the Y direction between the bonding pad MB and the bonding pad DB, the arrangement of the bonding pad DB (the second portion 210_db1 and the third portion 210_db2 of the electrode 210) can be shifted in the Y direction, without shifting the contact plug CB with respect to the D2 interconnect layer 209, which extends in the Y direction. This enables correction of the position deviation in the Y direction between the bonding pad MB and the bonding pad DB.

For example, in a case where there is no position deviation between the bonding pad MB and the bonding pad DB, and where the length Lmb of the upper surface of the bonding pad MB in the Y direction and the length Ldb of the upper surface of the bonding pad DB in the X direction are approximately equal, the shape of the contact surface between the upper surface of the bonding pad MB and the upper surface of the bonding pad DB is approximately square, as in the case shown in FIG. 8.

Next, the cross-sectional shapes of the bonding pads MB and DB will be described.

As shown in FIG. 50, for example, the cross section taken along the X direction of the first portion 108_vb of the electrode 108 has a trapezoidal shape, in which the length Lvbx in the X direction of the upper surface facing the Z1 direction of the first portion 108_vb of the electrode 108 is longer than the length, in the X direction, of the lower surface facing the Z2 direction of the first portion 108_vb. The length Lvbx of the upper surface of the first portion 108_vb in the X direction is approximately equal to the length Lm1x of the M1 interconnect layer 107 in the X direction. The cross section taken along the X direction of the electrode 210 is similar to that shown in FIG. 11 of the first embodiment.

As shown in FIG. 51, for example, the cross section taken along the Y direction of the first portion 210_cb of the electrode 210 has a trapezoidal shape, in which the length Lcby in the Y direction of the upper surface facing the Z2 direction of the first portion 210_cb of the electrode 210 is longer than the length, in the Y direction, of the lower surface facing the Z1 direction of the first portion 210_cb. The length Lcby of the upper surface of the first portion 210_cb in the Y direction is approximately equal to the length Ld2y of the D2 interconnect layer 209 in the Y direction. The cross section taken along the Y direction of the electrode 108 is similar to that shown in FIG. 12 of the first embodiment.

In the bonding pads MB and DB according to the present embodiment, the barrier metal 108_1 and the barrier metal 210_1 are discontinuous at the bonding position, so that the bonding can be identified.

### 4.3 Advantages of Present Embodiment

In the configuration according to the present embodiment, the advantages similar to those of the second embodiment can be obtained. More specifically, the semiconductor device 1 can make the size of the upper surface of the M1 interconnect layer 107 and the size of the upper surface of the contact plug VB (first portion 108_vb) approximately the same. Thus, the semiconductor device 1 can shift the arrangement of the bonding pad MB (the second portion 108_mb1 and the third portion 108_mb2 of the electrode 108) in the X direction, without shifting the contact plug VB with respect to the M1 interconnect layer 107, which extends in the X direction. Thus, the semiconductor device 1 can correct the position deviation in the X direction between the bonding pad MB and the bonding pad DB. In addition, the semiconductor device 1 can make the size of the upper surface of the D2 interconnect layer 209 and the size of the upper surface of the contact plug CB (first portion 210_cb) approximately the same. As a result, the semiconductor device 1 can shift the arrangement of the bonding pad DB (the second portion 210_db1 and the third portion 210_db2 of the electrode 210) in the Y direction, without shifting the contact plug CB with respect to the D2 interconnect layer 209, which extends in the Y direction. Therefore, the semiconductor device 1 can correct the position deviation in the Y direction between the bonding pad MB and the bonding pad DB.

Furthermore, in the configuration according to the present embodiment, the semiconductor device 1 can form the contact plug VB to have a longer length in the X direction than the hole pattern for processing the bonding pad MB, as in the third embodiment. Thus, even if a misalignment occurs between the contact plug VB and the bonding pad MB, the semiconductor device 1 does not exhibit variation in the length Lvbx of the upper surface of the contact plug VB in the X direction. That is, the semiconductor device 1 can make the resistance value of the contact plug VB approximately constant. By making the resistance value of the contact plug VB approximately constant, the semiconductor device 1 can reduce defective coupling between the M1 interconnect layer 107 and the bonding pad MB. In addition, the semiconductor device 1 can form the contact plug CB to have a longer length in the Y direction than the hole pattern for processing the bonding pad DB. Thus, even if a misalignment occurs between the contact plug CB and the bonding pad DB, the semiconductor device 1 does not exhibit variation in the length Lcby of the upper surface of the contact plug CB in the Y direction. That is, the semiconductor device 1 can make the resistance value of the contact plug CB approximately constant. By making the resistance value of the contact plug CB approximately constant, the semiconductor device 1 can reduce defective coupling between the D2 interconnect layer 209 and the bonding pad DB. Therefore, the yield of the semiconductor device 1 can be improved.

Furthermore, in the configuration according to the present embodiment, the semiconductor device 1 can form the contact plug VB to have a long length in the X direction. This enables a reduction in the contact resistance between the M1 interconnect layer 107 and the contact plug VB. Similarly, the semiconductor device 1 can form the contact plug CB to have a long length in the Y direction. This enables a reduction in the contact resistance between the D2 interconnect layer 209 and the contact plug CB.

### 5. Modifications, etc.

A semiconductor device according to the above embodiments includes a first chip (10) and a second chip (20). The first chip includes a first interconnect layer (M1) extending in a first direction (X direction) and a first electrode (108) including a first contact plug (VB) provided on the first interconnect layer and a first pad (MB) provided on the first contact plug. The second chip includes a second interconnect layer (D2) extending in a second direction (Y direction) intersecting the first direction and a second electrode (210) including a second contact plug (CB) provided on the second interconnect layer and a second pad (DB) provided on the second contact plug and bonded to the first pad. A first length (Lvbx) of an upper surface of the first contact plug in the first direction is longer than a second length (Lvby) of the upper surface of the first contact plug in the second direction. A third length (Lcby) of an upper surface of the second contact plug in the second direction is longer than a fourth length (Lcbx) of the upper surface of the second contact plug in the first direction.

In the configurations according to the above embodiments, the semiconductor device 1 can improve the yield.

In addition, the above-described embodiments are not intended to be limiting, and various modifications may be made. For example, if wafer warpage occurs in only one of the X or Y directions, the arrangement of the bonding pads on one of the wafers to be bonded may be shifted from the designed position to correct the resulting position deviation in that direction.

The “coupling” as used in the above embodiments includes a state where a transistor, a resistor or the like is interposed between the coupled elements.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first chip including:
a first interconnect layer extending in a first direction; and
a first electrode including a first contact plug provided on the first interconnect layer and a first pad provided on the first contact plug; and
a second chip including:
a second interconnect layer extending in a second direction intersecting the first direction; and
a second electrode including a second contact plug provided on the second interconnect layer and a second pad provided on the second contact plug and bonded to the first pad,
wherein
a first length of an upper surface of the first contact plug in the first direction is longer than a second length of the upper surface of the first contact plug in the second direction, and
a third length of an upper surface of the second contact plug in the second direction is longer than a fourth length of the upper surface of the second contact plug in the first direction.

2. The semiconductor device according to claim 1, wherein
the first length of the upper surface of the first contact plug in the first direction is equal to a fifth length of a lower surface of the first pad in the first direction, the lower surface of the first pad being in contact with the first contact plug; and
the third length of the upper surface of the second contact plug in the second direction is equal to a sixth length of a lower surface of the second pad in the second direction, the lower surface of the second pad being in contact with the second contact plug.

3. The semiconductor device according to claim 2, wherein
the second length of the upper surface of the first contact plug in the second direction is shorter than a seventh length of the lower surface of the first pad in the second direction, and
the fourth length of the upper surface of the second contact plug in the first direction is shorter than an eighth length of the lower surface of the second pad in the first direction.

4. The semiconductor device according to claim 1, wherein
a side surface facing the first direction of the first contact plug and a side surface facing the first direction of the first pad are provided on an identical plane; and
a side surface facing the second direction of the second contact plug and a side surface facing the second direction of the second pad are provided on an identical plane.

5. The semiconductor device according to claim 1, wherein
the second length of the upper surface of the first contact plug in the second direction is shorter than a ninth length of the first interconnect layer in the second direction, and
the fourth length of the upper surface of the second contact plug in the first direction is shorter than a tenth length of the second interconnect layer in the first direction.

6. The semiconductor device according to claim 1, wherein
an eleventh length of the first pad in the first direction is longer than a twelfth length of the first pad in the second direction, and
a thirteenth length of the second pad in the second direction is longer than a fourteenth length of the second pad in the first direction.

7. The semiconductor device according to claim 6, wherein
the eleventh length of the first pad in the first direction is shorter than a fifteenth length of the first interconnect layer in the first direction, and
the thirteenth length of the second pad in the second direction is shorter than a sixteenth length of the second interconnect layer in the second direction.

8. The semiconductor device according to claim 1, wherein the first electrode includes:
a barrier metal provided on side and lower surfaces of the first contact plug and on side and lower surfaces of the first pad; and
a conductor that is in contact with the barrier metal and forms a core portion of the first electrode.

9. The semiconductor device according to claim 1, wherein the first electrode includes:
a first portion that is provided on the first interconnect layer, and includes the first contact plug and a first sub-portion of the first pad provided on the first contact plug;
a second portion that is in contact with one side surface facing the second direction of the first portion, includes a second sub-portion of the first pad not included in the first portion, and does not include the first contact plug; and
a third portion that is in contact with another side surface facing the second direction of the first portion, includes a third sub-portion of the first pad not included in the first portion and the second portion, and does not include the first contact plug.

10. The semiconductor device according to claim 9, wherein a seventeenth length of an upper surface of the first portion in the first direction is longer than an eighteenth length of an upper surface of the second portion in the first direction.

11. The semiconductor device according to claim 9, wherein
the first portion includes a central region interposed between the second portion and the third portion, and a protruding region that protrudes in the first direction from respective ends of the second portion and the third portion in the first direction, and
the central region of the first portion, the second portion, and the third portion are in contact with the second electrode, and the protruding region of the first portion is not in contact with the second electrode.

12. The semiconductor device according to claim 9, wherein, in the first portion, the first length of the upper surface of the first contact plug in the first direction is equal to a nineteenth length of a lower surface of the first sub-portion of the first pad provided on the first contact plug in the first direction, the first sub-portion of the first pad provided on the first contact plug being in contact with the first contact plug.

13. The semiconductor device according to claim 9, wherein, in the first portion, a side surface facing the first direction of the first contact plug and a side surface facing the first direction of the first sub-portion of the first pad provided on the first contact plug are provided on an identical plane.

14. The semiconductor device according to claim 9, wherein a twentieth length of the first portion in a third direction intersecting the first direction and the second direction is longer than a twenty-first length of the second portion in the third direction.

15. The semiconductor device according to claim 1, wherein
the first chip further includes:
a first insulating layer provided on the first interconnect layer, the first contact plug passing through the first insulating layer;
a second insulating layer provided on the first insulating layer and being made of a material different from that of the first insulating layer, the first contact plug and the first pad being coupled to each other in a same layer level as the second insulating layer;
a third insulating layer provided on the second insulating layer, including an opening region, and being made of a material different from that of the second insulating layer, the first pad passing through the opening region; and
a fourth insulating layer provided on the third insulating layer, being in contact with the second chip, and being made of a material different from that of the third insulating layer, the first pad passing through the fourth insulating layer, and
one and another side surfaces facing the second direction of the first pad are in contact with the third insulating layer, and at least one of one and another side surfaces facing the first direction is not in contact with the third insulating layer.

16. The semiconductor device according to claim 15, wherein the opening region of the third insulating layer includes:
a first region which has a twenty-second length in the first direction longer than a twenty-third length of the first pad in the first direction, at least one of two sides of the first region in the first direction not being in contact with the first pad;
a second region provided adjacent to the first region on one side of the first region in the second direction, two sides of the second region in the first direction being in contact with the first pad; and
a third region provided adjacent to the first region on another side of the first region in the second direction, two sides of the third region in the first direction being in contact with the first pad.

17. The semiconductor device according to claim 15, wherein the third insulating layer contains at least one of SiC, SiN, and SiCN.

18. A semiconductor device comprising:
a first chip including:
a first interconnect layer extending in a first direction; and
a first electrode including a first contact plug provided on the first interconnect layer, and a first pad provided on the first contact plug; and
a second chip including:
a second interconnect layer extending in a second direction intersecting the first direction; and
a second electrode including a second contact plug provided on the second interconnect layer, and a second pad provided on the second contact plug and bonded to the first pad,
wherein the first electrode includes:
a first portion that is provided on the first interconnect layer, and includes the first contact plug and a first sub-portion of the first pad provided on the first contact plug;
a second portion that is in contact with one side surface facing the second direction of the first portion, includes a second sub-portion of the first pad not included in the first portion, and does not include the first contact plug; and
a third portion that is in contact with another side surface facing the second direction of the first portion, includes a third sub-portion of the first pad not included in the first portion and the second portion, and does not include the first contact plug, and
the first portion includes a first central region interposed between the second portion and the third portion, a first protruding region that protrudes in one direction along the first direction from respective first ends of the second portion and the third portion in the first direction, and a second protruding region that protrudes in another direction along the first direction from respective second ends of the second portion and the third portion in the first direction.

19. The semiconductor device according to claim 18, wherein the second electrode includes:
a fourth portion that is provided on the second interconnect layer, and includes the second contact plug and a fourth sub-portion of the second pad provided on the second contact plug;
a fifth portion that is in contact with one side surface facing the first direction of the fourth portion, includes a fifth sub-portion of the second pad not included in the fourth portion, and does not include the second contact plug; and
a sixth portion that is in contact with another side surface facing the first direction of the fourth portion, includes a sixth sub-portion of the second pad not included in the fourth portion and the fifth portion, and does not include the second contact plug.

20. The semiconductor device according to claim 19, wherein the fourth portion includes a second central region interposed between the fifth portion and the sixth portion, a third protruding region that protrudes in one direction along the second direction from respective third ends of the fifth portion and the sixth portion in the second direction, and a fourth protruding region that protrudes in another direction along the second direction from respective fourth ends of the fifth portion and the sixth portion in the second direction.
